(19) United States
(12) Patent Application Publication
(10) Pub. No.: US 2016/0380227 A1
(43) Pub. Date: Dec. 29, 2016

(54) ORGANIC ELECTROLUMINESCENT ELEMENT

(71) Applicant: KONICA MINOLTA, INC., Tokyo (JP)

(72) Inventors: Shigeru KOJIMA, Tokyo (JP); Takeshi HAKII, Tokyo (JP); Toshiyuki KINOSHITA, Tokyo (JP); Kazuhiro YOSHIDA, Tokyo (JP); Shun FURUKAWA, Tokyo (JP)

(21) Appl. No.: 15/038,876

(22) PCT Filed: Jan. 29, 2015
(86) PCT No.: PCT/JP2015/052504

§ 371 Date: May 24, 2016

(30) Foreign Application Priority Data
Feb. 24, 2014 (JP) 2014-032722

(51) Int. Cl. H01L 51/52; H01L 51/50

(52) U.S. Cl. CPC H01L 51/5234; H01L 51/5218; H01L 51/5044; H01L 51/5268; H01L 2251/301; H01L 2251/558

(57) ABSTRACT

This organic electroluminescent element is provided with: a transparent electrode that is mainly composed of silver (Ag); a reflective electrode that is formed of a metal; and at least one light emitting layer that is provided between the transparent electrode and the reflective electrode. This organic electroluminescent element is configured such that the difference between the maximum value and the minimum value of element reflectance of light having a wavelength of 450-750 nm is 30% or less.

### TECHNICAL FIELD

The present invention relates to an organic electroluminescent element.

### BACKGROUND ART

An organic electroluminescent element (referred to as “organic EL element”) obtained by utilizing electroluminescence (hereinafter, referred to as “EL”) of an organic material can emit light at a low voltage of approximately several volts to several ten volts, is a thin-film type completely-solid state element, and has many excellent advantages such as high luminance, high light-emission efficiency, small thickness and light weight. Accordingly, the element recently has attracted attention, as surface emitting bodies which are used as backlights for various kinds of displays, display boards such as signboards and emergency lights, light sources for lighting fixtures, and the like.

Such an organic EL element has a configuration obtained by sandwiching a light emitting layer constituted using an organic material between two electrodes, and the emitted light generated in the light emitting layer is extracted to the outside by passing through the electrode. Therefore, at least one of the two electrodes is constituted as a transparent electrode.

As the transparent electrode, there is used generally a material of an oxide semiconductor type such as indium tin oxide (SnO₂—In₂O₃: Indium Tin Oxide: ITO), and has been studied in order to lower electric resistance by laminating ITO and silver (e.g. refer to Patent Literature 1). However, ITO has a high raw cost because of using a rare metal indium, and is necessary to be subjected to annealing treatment at approximately 300° C. after film formation in order to lower its electric resistance. Accordingly, there have been proposed transparent electrodes of metal layers having configurations such as a configuration in which a metallic material such as silver having a high electrical conductivity is processed to be thin, and a configuration in which blending of aluminum with silver ensures an electrical conductivity even at a film thickness smaller than that of silver alone (e.g. refer to Patent Literature 2), and further, a configuration in which an light transmission property is ensured by employing a lamination structure in which a silver thin film layer is provided on an underlayer made of a metal other than silver (e.g. refer to Patent Literature 3).

In addition, when using the metal layer as the transparent electrode of the organic EL element as described above, a multiple reflection is generated between a reflective electrode. There is proposed that light of a specific wavelength is strengthened by utilizing the multiple reflection between the transparent electrode and the reflective electrode (e.g. refer to Patent Literature 4).

### CITATION LIST

### Patent Literature

PTL 1: Japanese Patent Laid-Open No. 2002-15623

PTL 2: Japanese Patent Laid-Open No. 2009-151963

PTL 3: Japanese Patent Laid-Open No. 2008-171637

PTL 4: Japanese Patent Laid-Open No. 2013-157226

### SUMMARY OF INVENTION

### Technical Problem

As described above, in the organic EL element where the multiple reflection between the transparent electrode and the reflective electrode occurs, the specific wavelength is strengthened. Namely, in the light taken out from the organic EL element, the specific wavelength can be strengthened by the multiple reflection. Therefore, the specific wavelength is strengthened by generation of the multiple reflection between the transparent electrode and the reflective electrode, and thus deviation occurs in the wavelength of light cable of being taken out from the organic EL element.

However, in a case where the organic EL element is used for backlight of wide view angle liquid crystal, or the like, the view angle dependency is required to be decreased. For example, in the organic EL element in which a metal layer is used for the transparent electrode and the specific wavelength is strengthened by the multiple reflection, since the wavelength of light to be extracted is deviated, the emitted light is low in uniformity and has a high wavelength dependency, and thus the view angle dependency is generated. Suppression of the view angle dependency is required in the organic EL element in which the metal layer is used for such a transparent electrode.

In order to solve the above problem, the present invention provides an organic electroluminescent element having less view angle dependency.

### Solution to Problem

The organic electroluminescent element of the present invention includes a transparent electrode that is mainly composed of silver (Ag), a reflective electrode that is formed of a metal, and at least one light emitting layer that is provided between the transparent electrode and the reflective electrode. Then, a difference between the maximum value and the minimum value of element reflectance of the organic electroluminescent element at light having a wavelength of 450 nm to 750 nm is 30% or less.

According to the organic electroluminescent element of the present invention, a reflectance of each wavelength in the organic electroluminescent element can be made uniform by setting a difference between the maximum value and the minimum value of element reflectance of the organic electroluminescent element at light having a wavelength of 450 nm to 750 nm to be 30% or less. Accordingly, the light extracted from the organic electroluminescent element has no deviation due to strengthening of the specific wavelength, and becomes light having uniformity of each wavelength. Therefore, it is possible to suppress the wavelength dependency due to the multiple reflection, and to provide the organic electroluminescent element having less view angle dependency.

### Advantageous Effects of Invention

According to the present invention, an organic electroluminescent element having less view angle dependency can be provided.

### BRIEF DESCRIPTION OF DRAWINGS

FIG. 1 is a schematic cross-sectional view of an organic electroluminescent element (organic EL element) of a first embodiment.

FIG. 2 is a graph obtained by simulating the relation between the reflectance of the transparent electrode and the difference between the maximum value and the minimum value of the elementary reflectance (difference of elementary reflectance), at light having a wavelength of 450 nm to 750 nm.

FIG. 3 is an explanatory view of the structure of the element for obtaining the reflectance of the transparent electrode.

FIG. 4 is a graph obtained by simulating the relation between the reflectance of the reflective electrode and the difference between the maximum value and the minimum value of the elementary reflectance (difference of elementary reflectance), at light having a wavelength of 450 nm to 750 nm.

FIG. 5 is an explanatory view of the structure of the element for obtaining the reflectance of the reflective electrode.

FIG. 6 is a graph obtained by simulating the relation between the thickness of the light emitting unit and the difference between the maximum value and the minimum value of the elementary reflectance (difference of elementary reflectance), at light having a wavelength of 450 nm to 750 nm.

FIG. 7 is a drawing of the structural formulae of TBAC and Ir(ppy)₃ for explaining the manner of bonding of the nitrogen atom.

FIG. 8 is a drawing of the structural formula and molecular orbital of the pyridine ring.

FIG. 9 is a drawing of the structural formula and molecular orbital of the pyrrole ring.

FIG. 10 is a drawing of the structural formula and molecular orbital of the imidazole ring.

FIG. 11 is a drawing of the structural formula and molecular orbital of the δ-carboline ring.

FIG. 12 is a schematic cross-sectional diagram of the structure of the organic electroluminescent element (organic EL element) of a second embodiment.

FIG. 13 is a schematic cross-sectional diagram of the structure of the organic electroluminescent element (organic EL element) of a modification of the second embodiment.

### DESCRIPTION OF EMBODIMENTS

Hereinafter, embodiments of the present invention will be explained, but the present invention is not limited thereto.

The explanation is done in the following order.

1. First embodiment of the organic electroluminescent element
2. Second embodiment of the organic electroluminescent element

### 1. First Embodiment of the Organic Electroluminescent Element

Hereinafter, the first embodiment of the organic electroluminescent element will be explained.

FIG. 1 shows the schematic cross-sectional view of the organic electroluminescent element (organic EL element) of the present embodiment. As shown in FIG. 1, the organic EL element 10 includes a substrate 11, a nitrogen-containing layer 12 provided on the substrate 11, a transparent electrode 13 formed in contact with the nitrogen-containing layer 12, a reflective electrode 15 provided so as to face the transparent electrode 13, and a light emitting unit 14 sandwiched between the transparent electrode 13 and the reflective electrode 15. The light emitting unit 14 has at least one or more light emitting layers. Detailed respective configurations of the substrate 11, the nitrogen-containing layer 12, the transparent electrode 13, the light emitting unit 14, and the reflective electrode 15 will be explained later.

Here, the organic EL element 10 is designed so that a difference between the maximum value and the minimum value of element reflectance at light having a wavelength of 450 nm to 750 nm is 30% or less.

The element reflectance means a reflectance of the organic EL element 10 with respect to light which enters from the front side (0 to 10°) of the substrate 11 side when the organic EL element 10 is not light-emitted, and can be obtained using a spectrophotometer, a reflectance measuring device, and the like. Note that, when the organic EL element has a light scattering structure and the like, a reflectance obtained by a configuration excluding the light scattering structure is assumed to be an element reflectance of the organic EL element.

[Configuration and Element Reflectance of Organic EL Element]

In order to set a difference between the maximum value and the minimum value of element reflectance of the organic EL element 10 at light having a wavelength of 450 nm to 750 nm to be 30% or less, for example, the following configuration is required.

(1) Decreasing the reflectance of the transparent electrode 13.
(2) Increasing the reflectance of the reflective electrode 15.
(3) The light emitting unit 14 of the organic EL element 10 is designed to have a thickness which is difficult to interfere with the specific wavelength.

Hereinafter, there will be explained the relation between each structure of the above organic EL element 10 and the difference between the maximum value and the minimum value of element reflectance, at light having a wavelength of 450 nm to 750 nm.

[Relation Between Transparent Electrode and Element Reflectance]

At first, the relation between the transparent electrode 13 and the element reflectance will be explained.

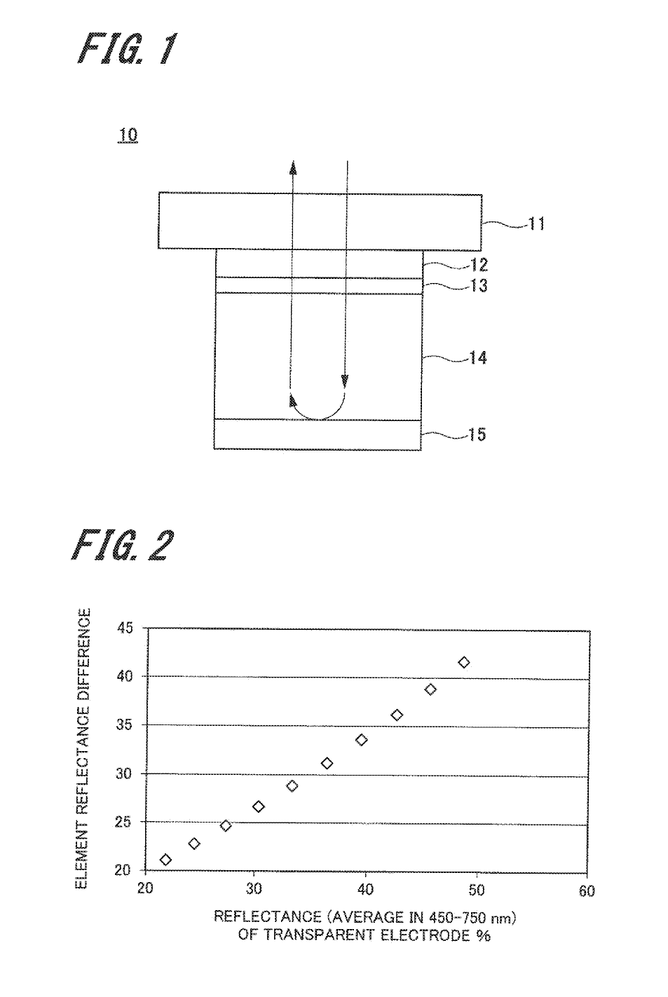

FIG. 2 shows a graph obtained by simulating the relation between the reflectance of the transparent electrode 13 and the difference between the maximum value and the minimum value of the elementary reflectance (difference of elementary reflectance), at light having a wavelength of 450 nm to 750 nm.

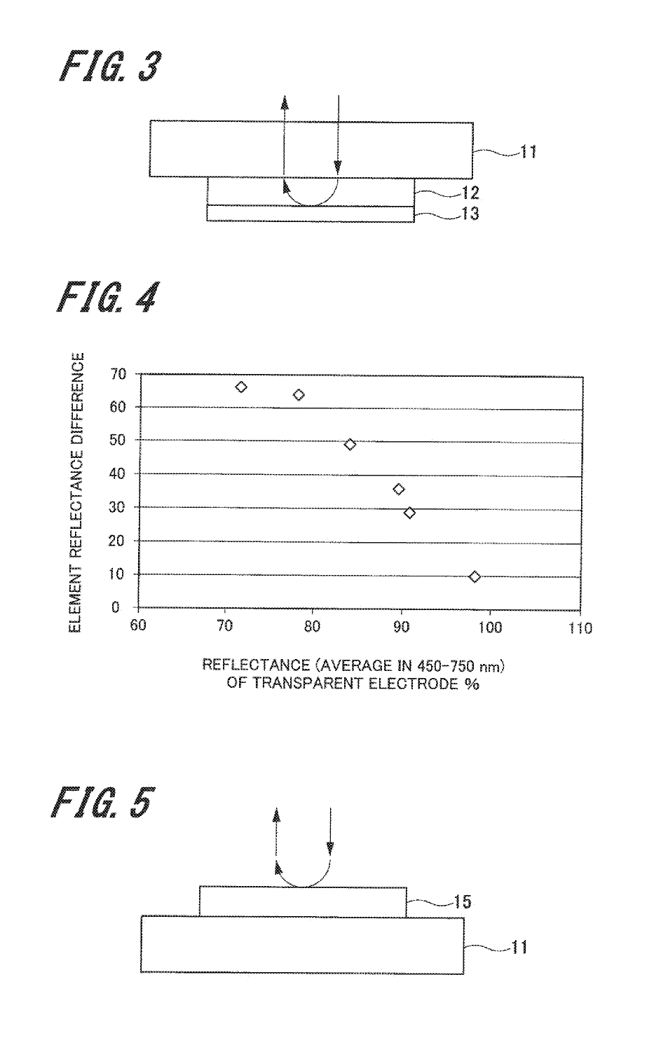

In the graph shown in FIG. 2, the horizontal axis shows the reflectance of the transparent electrode 13. As shown in FIG. 3, the reflectance of the transparent electrode 13 is determined with respect to an element obtained by forming the nitrogen-containing layer 12 on the glass substrate 11 in a thickness of 75 nm, and then by forming the transparent electrode 13 made of silver (Ag) in contact with the nitrogen-containing layer 12. In the transparent electrode 13, the reflectance of the transparent electrode 13 is set as a mean value of the reflectance obtained by changing the thickness of (Ag) in units of 1 nm between 6 to 15 nm, and by measuring the reflectance of the light having the wavelength of 450 nm to 750 nm with which irradiation from the substrate 11 side is performed at each thickness.

In the graph shown in FIG. 2, the vertical axis shows the difference between the maximum value and the minimum value of element reflectance at light having a wavelength of 450 nm to 750 nm.

The maximum value and the minimum value of the element reflectance is obtained by the organic EL element 10 having the configuration shown in the above FIG. 1. The organic EL element 10 is composed of 75 nm of the nitrogen-containing layer 12, 220 nm of an organic material for the light emitting unit 14, and 100 nm of aluminum for the reflective electrode 15. Then, in the organic EL element 10 in which the transparent electrode 13 is composed of a silver having the above predetermined thickness (6 to 15 nm), the element reflectance at each wavelength in units of 1 nm between the wavelength of 450 nm to 750 nm is obtained. Furthermore, a difference of the maximum value and the minimum value in the element reflectance of each wavelength (Maximum reflectance %−Minimum reflectance %=Element reflectance difference %) is obtained.

As can be seen from the graph shown in FIG. 2, when the reflectance of the transparent electrode 13 becomes high, the difference between the maximum value and the minimum value of the element reflectance becomes large. For example, in order to set a difference between the maximum value and the minimum value of element reflectance at light having a wavelength of 450 nm to 750 nm to be 30% or less, it is necessary to make the reflectance of the transparent electrode 13 to be 35% or less.

According to the simulation of this configuration, the mean value of the reflectance of the light having a wavelength of 450 nm to 750 nm of the transparent electrode 13 is about 33% at a thickness of 10 nm, about 36% at a thickness of 11 nm. Therefore, it is necessary that the thickness of the transparent electrode 13 is less than 11 nm, preferably 10 nm or less.

As described above, when lowering the reflectance of the transparent electrode 13, the multiple reflection in the organic EL element 10 can be suppressed. Accordingly, the effect of strengthening the specific wavelength by the multiple reflection, so-called micro cavity effect can be suppressed. Therefore, since the influence on the specific wavelength due to the multiple reflection in the organic EL element 10 can be suppressed to give light having a high uniformity, the wavelength dependency and the view angle dependency of the light extracted from the organic EL element 10 can be suppressed.

(Light Transmission Property of Transparent Electrode)

In order to lower the reflectance of the transparent electrode 13, there is required a configuration in which the transparent electrode 13 is made to be thin and furthermore, the light transmission property is not lowered even by forming the electrode to be thin. The light transmission property is influenced by a material and a thickness of the transparent electrode 13, and a surface shape of the transparent electrode 13. Namely, in order to lower the reflectance of the transparent electrode 13, it is necessary to form a metal layer having a high uniformity and flatness even by forming the electrode to be thin.

In a case where the transparent electrode 13 is made by a metal, when the electrode is formed to be thin for enhancing the light transmission property, the metal atoms are easily agglomerated and thus the uniformity of the metal layer is easily lowered. Accordingly, the view angle dependency is generated due to interference with the specific wavelength. For example, in a case where concavity and convexity are present at a specific interval on the surface, when light is transmitted or reflected at the transparent electrode 13, the light is interfered by an interval of concavity and convexity, and thus the specific wavelength is made strong or weak. In that case, the particular wavelength dependency is generated in the light passing through the transparent electrode 13, and thus the light transmission property of the transparent electrode 13 is lowered.

Therefore, the transparent electrode 13 has preferably a high surface uniformity and a high flatness in terms of its surface shape. The interference with the specific wavelength can be suppressed due to a high flatness. In addition, the interference with the specific wavelength can be suppressed by enhancing the surface uniformity, and thus the wavelength dependency can be suppressed.

In order to form the transparent electrode 13 having a good light transmission property, the transparent electrode 13 is made of silver or an alloy containing silver as a main component. Furthermore, it is preferable to form, as an underlayer that forms the transparent electrode 13, the nitrogen-containing layer 12 having a compound in which an effective unshared electron pair content [n/M] is 2.0×10⁻³ [n/M], in a case where n is the number of unshared electron pairs which are not involved in aromaticity and which are not coordinated with a metal in the unshared electron pairs of nitrogen atom (N), and M is a molecular weight.

Even in a case of forming the metal layer in a thickness of approximately 4 nm, it is possible to form the transparent electrode 13 having a high uniformity by forming the metal layer containing silver as a main component on the above nitrogen-containing layer 12. The layer containing silver constituting the transparent electrode 13 as a main component and the nitrogen-containing layer 12 serving as a underlayer will be explained later in detail.

[Relation Between Reflective Electrode and Element Reflectance]

Next, the relation between the reflective electrode 15 and the element reflectance will be explained.

FIG. 4 shows a graph obtained by simulating the relation between the reflectance of the reflective electrode and the difference between the maximum value and the minimum value of the elementary reflectance (difference of elementary reflectance), at light having a wavelength of 450 nm to 750 nm.

In the graph shown in FIG. 4, the horizontal axis shows a reflectance of the reflective electrode 15. The reflectance of the reflective electrode 15 is determined, as shown in FIG. 5, with respect to an element obtained by forming the reflective electrode 15 on the glass substrate 11 in a thickness of 100 nm. The material for forming the reflective electrode 15 is changed, and the reflectance of the reflective electrode 15 is a mean value of the reflectance obtained by irradiating the reflective electrode 15 with the light having the wavelength of 450 nm to 750 nm in each material. The material used and an approximate value of the average reflectance R of the reflective electrode 15 in the light having the wavelength of 450 nm to 750 nm are as follows: Palladium (Pd: R=71), Rhodium (Rh: R=78), Calcium (Ca: R=84), Lithium (Li: R=89), Aluminum (Al: R=90), Silver (Ag: R=98).

In the graph shown in FIG. 4, the vertical axis indicates the difference between the maximum value and the minimum value of element reflectance at light having a wavelength of 450 nm to 750 nm.

The maximum value and the minimum value of the element reflectance are obtained by the organic EL element 10 having the configuration shown in the above FIG. 1. The organic EL element 10 is made of the nitrogen-containing layer 12 of 75 nm, silver for the transparent electrode 13 of 10 nm, and an organic material for the light emitting unit 14 of 220 nm. Then, in the organic EL element 10 made by applying the above respective materials as the reflective electrode 15, the reflectances of respective wavelengths in units of 1 nm between the wavelength of 450 nm to 750 nm are obtained. Furthermore, a difference between the maximum value and the minimum value in the element reflectances of respective wavelengths (Maximum reflectance %−Minimum reflectance %=Element reflectance difference %) is obtained.

As can be seen from the graph shown in FIG. 4, when the reflectance of the reflective electrode 15 becomes high, the difference between the maximum value and the minimum value of the element reflectance becomes small. For example, in order to set a difference between the maximum value and the minimum value of element reflectance at light having a wavelength of 450 nm to 750 nm to be 30% or less, it is necessary to make the reflectance of the reflective electrode 15 to be 90% or more.

As described above, it is possible to perform reflection with a high uniformity over the whole wavelength by increasing the reflectance of the reflective electrode 15. In addition, by increasing the reflectance, the absorption at the specific wavelength can be suppressed by increasing the reflectance, and thus the attenuation of the reflected light having the specific wavelength can be suppressed. Namely, it is possible to suppress the effect of strengthening or weakening the specific wavelength of the reflected light due to the micro cavity effect.

Therefore, it is possible to suppress the influence on the specific wavelength due to the reflective electrode 15 in the organic EL element 10 by increasing the reflectance of the reflective electrode 15 and to obtain light having a high uniformity. Accordingly, the wavelength dependency and the view angle dependency of the light extracted from the organic EL element 10 can be suppressed.

(Reflectance of Reflective Electrode)

In order to increase the reflectance of the reflective electrode 15, a material having a high reflectance is used. For example it is preferable to use silver, aluminum or the like having a reflectance of 90% or more in the above simulation.

In a case where the reflective electrode 15 is used as a cathode of the organic EL element 10, it is preferable to use aluminum having a high electron injection property.

When using silver as the cathode, in order to increase the electron injection property, for example, it is possible that an aluminum of approximately 1 nm thickness is formed between the silver and the light emitting unit 14 and the cathode is constituted by a laminated structure of silver and aluminum. According to this configuration, although there is a risk that the reflectance of the reflective electrode 15 may be decreased by sandwiching the aluminum, it is possible to enhance the electron injection property while suppressing the optical influence at a low level, since the thickness of the aluminum is as very thin as approximately 1 nm.

Furthermore, it is also possible to have a configuration in which the silver is directly brought in contact with the light emitting unit 14 by enhancing the electron injection property by the configuration of the light emitting unit 14. For example, a mixture of an organic material and an inorganic salt/complex is used for the layer which is in contact with the silver, and thus the electron injection property to the light emitting unit 14 can be improved. Accordingly, the reflective electrode 15 using silver can be formed without lowering the reflectance.

(Surface Shape of Reflective Electrode)

The reflective electrode 15 preferably has a high surface uniformity and a high flatness in terms of its surface shape. Because of having a high flatness, a configuration is such that the interference with the wavelength is a little. For example, in a case where concavity and convexity are present at a specific interval on the surface, when light is reflected at the reflective electrode 15, the light is interfered by an interval of concavity and convexity, and thus the specific wavelength is made strong or weak. Accordingly, the particular wavelength dependency is generated. the interference with the specific wavelength can be suppressed by enhancing the surface uniformity, and thus the wavelength dependency can be suppressed.

For example, in a case where the reflective electrode 15 is made of silver or an alloy containing silver as a main component, in the same way as that in the transparent electrode 13, it is preferable to form, as an underlayer, the nitrogen-containing layer 12 having a compound in which an effective unshared electron pair content [n/M] is 2.0×10⁻³[n/M], in a case where n is the number of unshared electron pairs which are not involved in aromaticity and which are not coordinated with a metal in the unshared electron pairs of nitrogen atom (N), and M is a molecular weight. In a case where the reflective electrode 15 is used as a cathode, it is particularly preferable to use a material having a high electron transport property among the above nitrogen-containing compounds.

[Relation Between Thickness of Light Emitting Unit and Element Reflectance]

Next, the relation between the thickness of the light emitting unit 14 and the element reflectance will be explained.

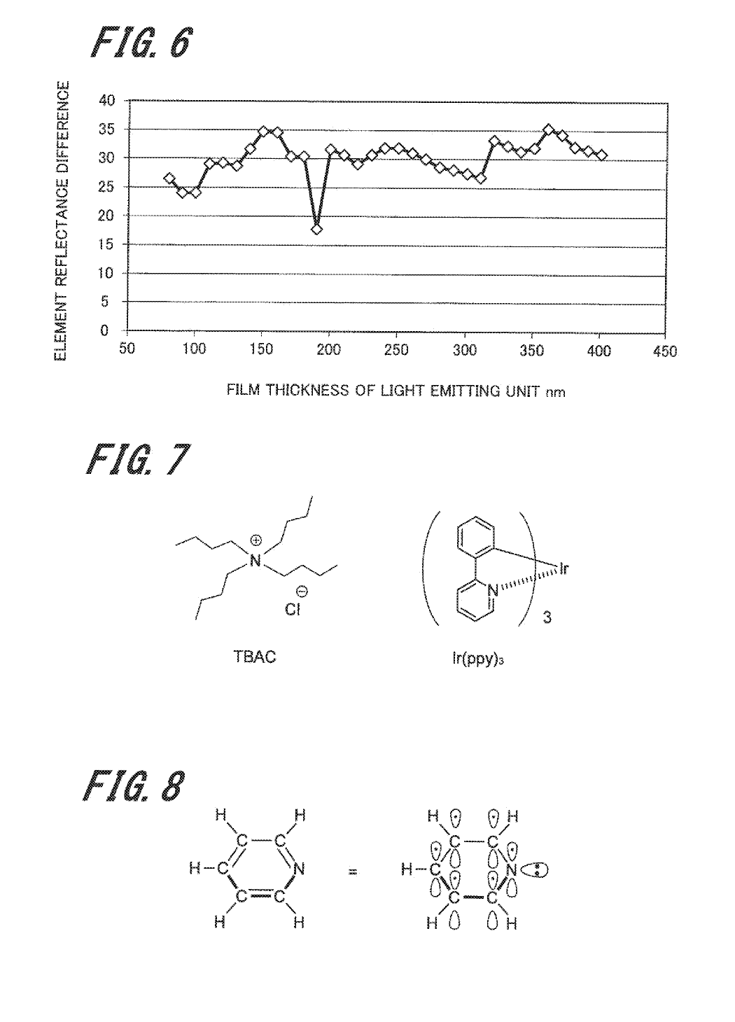

FIG. 6 shows a graph obtained by simulating the relation between the thickness of the light emitting unit and the difference between the maximum value and the minimum value of the elementary reflectance (difference of elementary reflectance), at light having a wavelength of 450 nm to 750 nm.

In the graph shown in FIG. 6, the horizontal axis shows the thickness of the light emitting unit 14. The thickness of the light emitting unit 14 is, as shown in FIG. 1, the thickness of the light emitting unit 14 formed between the transparent electrode 13 and the reflective electrode 15 is changed in units of 10 nm between 80 nm to 400 nm, and thus the organic material layer is formed.

In addition, in the graph shown in FIG. 6, the vertical axis indicates the difference between the maximum value and the minimum value of element reflectance at light having a wavelength of 450 nm to 750 nm.

The maximum value and the minimum value of the element reflectance are determined by the organic EL element 10 having the configuration shown in the above FIG. 1. The organic EL element 10 is made of the nitrogen-containing layer 12 of 75 nm, silver for the transparent electrode 13 of 10 nm, and aluminum for the reflective electrode 15 of 100 nm. Then, in the organic EL element 10 in which the thickness of the light emitting unit 14 is changed between 80 nm to 400 nm, the element reflectances of respective wavelengths in units of 1 nm between the wavelength of 450 nm to 750 nm are obtained. Furthermore, a difference between the maximum value and the minimum value in the element reflectances of respective wavelengths (Maximum reflectance %−Minimum reflectance %=Element reflectance difference %) is obtained.

As is clear from the graph shown in FIG. 6, the difference between the maximum value and the minimum value of the element reflectance at light having a wavelength of 450 nm to 750 nm is changed depending on the thickness of the light emitting unit 14. This is caused by the fact that even if the thickness of the light emitting unit 14 is the same, the element reflectance is changed in complicated manner by each wavelength, and the element reflectance of each wavelength is changed depending on the thickness of the light emitting unit 14. Namely, this proves that, in the organic EL element 10, the thickness of the light emitting unit 14 provided between the transparent electrode 13 and the reflective electrode 15 exerts an influence on the element reflectance of each wavelength.

For example, with respect to the light which performs multiple reflection between the transparent electrode 13 and the reflective electrode 15, when the thickness of the light emitting unit 14 is set so as to easily interfere with the specific wavelength, amplification or attenuation of the specific wavelength receiving an interference takes place to thereby strengthen or weaken the specific wavelength of the reflected light.

Furthermore, the element reflectance of each wavelength exhibits various behaviors, with respect to the thickness of the light emitting unit 14, such as a case where the reflectance is lowered on a short wavelength side at a certain thickness and the reflectance is lowered in an intermediate wavelength at a different thickness, or a case where the element reflectance is high on a short wavelength side and the reflectance is lowered gradually to a long wavelength side, or a case where the reflectance is high on a short wavelength side and a long wavelength side and the element reflectance is lowered in an intermediate area, and the like.

Therefore, since the thickness that easily receives interference is different depending on the wavelength, the wavelength dependency of the element reflectance in accordance with the thickness of the light emitting unit 14 is generated.

(Thickness of Light Emitting Unit)

In order to make a difference between the maximum value and the minimum value of element reflectance at light having a wavelength of 450 nm to 750 nm to be 30% or less in the organic EL element 10, it is necessary that the thickness of the light emitting unit 14 is designed so that the difference between the maximum value and the minimum value of the element reflectance is 30% or less. Namely, the thickness of the light emitting unit 14 of the organic EL element 10 is designed so as to be difficult to interfered with the specific wavelength.

The difference between the maximum value and the minimum value of the element reflectance at light having a wavelength of 450 nm to 750 nm is obtained by subjecting the light emitting unit 14 to the above simulation, and thus the thickness can be set so that the difference is 30% or less. For example, from the graph shown in FIG. 6, the configuration of the organic EL element may be such that the thickness at which the difference between the maximum value and the minimum value of the element reflectance at light having a wavelength of 450 nm to 750 nm is 30% or less, i.e. any of 130 nm or less, 190 nm, 220 nm or 270 to 310 nm is set as the thickness of the light emitting unit 14.

The thickness of the light emitting unit 14 of the organic EL element 10 corresponds to the layers formed between the layers from the transparent electrode 13 to the reflective electrode 15, which include at least one light emitting layer. The light emitting unit 14 may be a sole layer or a laminated layer of a plurality of layers, and furthermore, may be a so-called tandem structure in which a plurality of emitting layers is laminated. Also in these cases, the total thickness of all layers formed between the layers from the transparent electrode 13 to the reflective electrode 15 is the thickness of the above light emitting unit 14 of the organic EL element 10.

(Influence of Thickness of Light Emitting Unit on Other Configuration)

When changing the thickness of the light emitting unit 14, the graph representing the difference (element reflectance difference) between the maximum value and the minimum value of element reflectance at light having a wavelength of 450 nm to 750 nm tends to exhibit the above complicated behavior. On the other hand, when changing the transparent electrode 13 and the reflective electrode 15 while making the thickness of the light emitting unit 14 constant, the graph representing the element reflectance difference at light having a wavelength of 450 nm to 750 nm tends to exhibit periodical and stable behavior.

In the above simulation in which the reflectance of the transparent electrode 13 is a parameter, and in the above simulation in which the reflectance of the reflective electrode 15 is a parameter, the thickness of the light emitting unit 14 is 220 nm.

From the graph shown in FIG. 6, when the thickness of the light emitting unit 14 is 220 nm, the element reflectance difference at light having a wavelength of 450 nm to 750 nm is 30% or less, but is about 29% which is slightly lower than 30%. Therefore, when the thickness of the light emitting unit 14 is 220 nm, there is no flexibility with respect to the reflectances of the transparent electrode 13 and the reflective electrode 15 in order to make the element reflectance difference at light having a wavelength of 450 nm to 750 nm to be 30% or less, thereby resulting in low freedom for designing these configurations. Accordingly, it is difficult to employ the configuration in which the reflectance of the transparent electrode 13 is increased by making the thickness of the transparent electrode 13 large, and to change the material of the reflective electrode 15 to a material having a reflectance lower than that of aluminum.

Furthermore, from the graph shown in FIG. 6, when the thickness of the light emitting unit 14 is 190 nm, the element reflectance difference at light having a wavelength of 450 nm to 750 nm becomes largely lower than 30%, and is lowered up to about 18%. Therefore, it is possible to realize a configuration in which the element reflectance difference at light having a wavelength of 450 nm to 750 nm is within the range of 30% or less, even if there is employed a configuration in which the reflectance is increased by making the thickness of the transparent electrode 13 large, or the reflectance of the reflective electrode 15 is lowered.

Namely, the freedom of design of the organic EL element 10 is enhanced.

For example, when changing the thickness of the light emitting unit 14 from 220 nm to 190 nm, even if the thickness of the transparent electrode 13 is 10 nm, the difference between the maximum value and the minimum value of the element reflectance is lowered from about 29% to about 18%, i.e. lowered by 11 points or more. Considering this, in the graph showing the relation between the reflectances of the transparent electrode 13 and the element reflectance difference shown in FIG. 2, even when the element reflectance difference is approximately 41%, it is considered possible to lower the element reflectance difference by adjusting the thickness of the light emitting unit 14. Accordingly, it is possible to make the element reflectance difference at light having a wavelength of 450 nm to 750 nm to be 30%. Therefore, when the thickness of the transparent electrode 13 is 10 nm or more, it also becomes possible to make the element reflectance difference at light having a wavelength of 450 nm to 750 nm to be 30% by adjusting the thickness of the light emitting unit 14. Furthermore, it is possible to make the element reflectance difference at light having a wavelength of 450 nm to 750 nm to be 30% by increasing the reflectance of the reflective electrode 15 together with the above adjustment of the thickness of the light emitting unit 14, even when making the thickness of the transparent electrode 13 large to around 15 nm.

Alternatively, in the graph shown in FIG. 6, even if the light emitting unit 14 has a thickness having an element reflectance difference at light having a wavelength of 450 nm to 750 nm of more than 30%, it becomes possible to realize a configuration in which the difference between the maximum value and the minimum value of the element reflectance is 30% or less, by making the thickness of the transparent electrode 13 small to thereby decrease the reflectance, or by increasing the reflectance of the reflective electrode 15.

Furthermore, even when the element reflectance difference is slightly lower than 30% like in the case where the thickness of the light emitting unit 14 is 220 nm, it becomes possible to realize a configuration in which the difference of the element reflectance at light having a wavelength of 450 nm to 750 nm is 30% or less, even by employing a configuration of decreasing the reflectance of the reflective electrode 15 by making the thickness of the transparent electrode 13 small to thereby decrease the reflectance.

Similarly, even if the thickness of the transparent electrode 13 is made large to increase the reflectance, by using silver or the like to thereby increase the reflectance of the reflective electrode 15, it becomes possible to realize a configuration in which the difference of the element reflectance at light having a wavelength of 450 nm to 750 nm is 30% or less.

[Other Factors Relating to Element Reflectance]

(Intermediate Layer of Light Emitting Unit)

When the light emitting unit 14 has a plurality of the light emitting layers, so-called a tandem structure, a stacking structure or the like, it is preferable that the total thickness of the light emitting units formed between the transparent electrode 13 and the reflective electrode 15 is designed so as to be difficult to interfere with the specific wavelength.

Furthermore, in the above structure, it is preferable that the intermediate layer provided between the light emitting units is a layer having a low reflectance and an excellent light transmission property as in the above transparent electrode 13. When the reflectance is low and the transmission property is high, it is possible to suppress the multiple reflection generated between the intermediate layer and the reflective electrode 15 and between the intermediate layer and the transparent electrode 13 and to thereby suppress the wavelength dependency and the view angle dependency of the light extracted from the organic EL element 10.

It becomes possible to decrease the reflectance and to enhance the light transmission property by using, for example, aluminum, calcium, lithium, or the like for the intermediate layer and by having a thickness of approximately 1 nm. Particularly, it becomes possible to decrease the reflectance and to enhance the light transmission property by using calcium, lithium or the like.

Moreover, for example, even in the tandem structure, when employing a configuration in which an intermediate layer of metal is not provided, the multiple reflection in the organic EL element 10 can be suppressed. For example, between a plurality of the laminated light emitting layers, the configuration of not providing the intermediate layer of metal can be employed by providing an electric charge generating layer in which an n-type electron transport layer and a p-type positive hole transport layer are laminated. When employing the configuration, it is possible to suppress the multiple reflection generated between the intermediate layer and the reflective electrode 15 and between the intermediate layer and the transparent electrode 13 and to thereby suppress the wavelength dependency and the view angle dependency of the light extracted from the organic EL element 10.

(Material of Light Emitting Unit)

In the organic EL element 10, the light emitting unit 14 is formed mainly of organic materials, and the light emitting unit 14 is preferably constituted of a material having low optical absorption and having less interference with the specific wavelength.

When using a material having absorption in the specific wavelength, a colored material or the like, the wavelength dependency of the organic EL element 10 becomes large. Therefore, the light emitting unit 14 itself preferably has low optical attenuation and low optical absorption.

Especially, in the configuration in which the thickness of the light emitting unit 14 becomes easily large as in the case of the tandem structure, it is preferable that the attenuation and absorption in the light emitting unit 14 are particularly low, and it is more preferable that the attenuation and absorption in the specific wavelength are not almost present.

(Light Scattering Layer)

It is possible to increase light extraction efficiency and to lower the view angle dependency, by introducing a light scattering layer.

In this case, particularly, when forming the light scattering layer in the organic EL element in which the element reflectance difference at light having a wavelength of 450 nm to 750 nm is 30% or less, an enhancement width of the efficiency becomes larger, and a decrease width of the view angle dependency is also larger than the organic EL element in which the element reflectance difference is more than 30%.

Other than the light scattering layer, an optical member may be provided on the light extraction side of the organic EL element in order to increase alight extraction efficiency. In this case, when forming the optical member in the organic EL element in which the element reflectance difference at light having a wavelength of 450 nm to 750 nm is 30% or less, the enhancement width of the efficiency becomes larger, and the decrease width of the view angle dependency is also larger than the organic EL element in which the element reflectance difference is more than 30%.

Note that, when introducing the light scattering layer, the optical member and the like, appearance is changed, and thus optional selection depending on application is required.

[Configuration of Organic EL Element]

A substrate 11, a nitrogen-containing layer 12, a transparent electrode 13, a light emitting layer 14, and a reflective electrode 15 which configures the organic EL element 10 shown in the above FIG. 1 will be explained in detail.

[Substrate]

The substrate 11 which can be used for the organic EL element 10 is not particularly limited and is, for example, of glass, plastics, and the like, and may be transparent or opaque. When extracting light from the side of the substrate 11, the substrate 11 is preferably transparent. Preferably used transparent substrate 11 includes glass, quartz, and transparent resin film. Particularly preferable substrate 11 is a resin film which can gives flexibility to the organic EL element 10.

Examples of the resin film include polyesters such as polyethylene terephthalate (PET) and polyethylene naphthalate (PEN), polyethylene, polypropylene, cellulose esters or derivative thereof such as cellophane, cellulose diacetate, cellulose triacetate (TAC), cellulose acetate butylate, cellulose acetate propionate (CAP), cellulose acetate phthalate and cellulose nitrate, polyvinylidene chloride, polyvinyl alcohol, polyethylene vinyl alcohol, syndiotactic polystyrene, polycarbonate, norbornen resin, polymethylpenten, polyether ketone, polyimide, polyether sulphone (PES), polyphenylene sulfide, polysluphones, polyether imide, polyether ketone imide, polyamide, fluororesin, Nylon, polymethyl methacrylate, acryl or polyallylates, cycloolefin-based resins such as Alton (commercial name of JSR) or APEL (commercial name of Mitsui Chemicals), and the like.

A coating film of inorganic materials or organic materials, or a barrier membrane by both of the hybrid coating films or the like may be formed on the surface of the resin film. The barrier membrane is preferably a barrier film having a water vapor transmittance (25±0.5° C., relative humidity 90±2% RH) measured by the method in accordance with JIS-K-7129-1992 of 0.01 g/(m²·24 hrs) or less. Furthermore, the barrier membrane is preferably a high barrier film having an oxygen transmittance measured by the method in accordance with JIS-K-7126-1987 of 10⁻³ ml/(m²·24 hrs·atm) or less and a water vapor transmittance of 10⁻⁵ g/(m²·24 hrs) or less.

A material for forming the barrier membrane may be a material having a function of suppressing penetration of substances such as water vapor and oxygen which deteriorate the resin film. For example, there can be used silicon oxide, silicon dioxide, silicon nitride, and the like. Furthermore, in order to improve fragility of the barrier membrane, it is more preferably to give a lamination structure of the inorganic layer and a layer of organic material. The order of lamination of the inorganic layer and the organic layer is not particularly limited, and is preferable to alternately laminate both of the layers a plurality of times.

The method of forming the barrier membrane is not particularly limited, and there can be used, for example, vacuum deposition method, spattering method, reactive spattering method, molecular beam epitaxial method, cluster ion beam method, ion platting method, plasma polymerization method, atmospheric pressure plasma polymerization method, plasma CVD method, laser CVD method, thermal CVD method, coating method, and the like. Preferable is the atmospheric pressure plasma polymerization method described in, for example, Japanese Patent Application Laid-Open Publication No. 2004-68143.

[Nitrogen-Containing Layer]

The nitrogen-containing layer 12 is formed adjacent to the transparent electrode 13 and is a layer sandwiched between the substrate 11 and the transparent electrode 13.

As the result of the formation of the transparent electrode 13 in contact with the nitrogen-containing layer 12, diffusion distance of silver atoms at the surface of the nitrogen-containing layer is reduced due to the interaction between silver being the principal component of the transparent electrode 13 and a compound containing a nitrogen atom constituting the nitrogen-containing layer 12, and thus aggregation of the silver is suppressed. Therefore, generally, a thin silver layer that tends to be easily isolated in an island shape as the result of the growth by a nuclear growth-type (Volumer-Weber: VW type) is formed by the growth of a single layer growth type (Frank-van der Merwe: FM type). Accordingly, the transparent electrode 13 having a uniform thickness, although the thickness is small, can be obtained by forming the transparent electrode 13 containing silver as the principal component in contact with the nitrogen-containing layer 12.

The nitrogen-containing layer 12 preferably has the thickness of 5 nm or less. This is because a smaller thickness of the nitrogen-containing layer 12, that is, a smaller distance between the substrate 11 and the transparent electrode 13 gives higher light transmittance. Note that the thickness of the nitrogen-containing layer 12 is set to be a thickness that does not prevent the FM type growth of the transparent electrode 13 formed on the nitrogen-containing layer 12, that is, to be approximately a thickness of the extent that the transparent electrode 13 is formed not in an island shape but as a continuous layer covering the substrate 11.

Furthermore, the nitrogen-containing layer 12 is a layer provided adjacent to the transparent electrode 13, and is constituted using a compound containing a nitrogen atom (N). An unshared electron pair of a nitrogen atom that is bonded stably to silver being the main material for constituting the transparent electrode 13 in the compound containing a nitrogen atom is referred to as an “effective unshared electron pair.” Additionally, the compound constituting the nitrogen-containing layer 12 is characterized in that the content ratio of the effective unshared electron pair” is within a prescribed range.

Here, the “effective unshared electron pair” is defined as an unshared electron pair that is not involved in aromaticity and is not coordinated to a metal, among unshared electron pairs of a nitrogen atom contained in a compound. The aromaticity means an unsaturated ring structure in which atoms having a π electron are arranged in a ring shape, and the aromaticity follows the so-called “Huckel's rule” which requires a condition in which the number of electrons contained in the π electron system on the ring is “4n+2” (n=0, or a natural number).

The “effective unshared electron pair” is selected based on whether or not the unshared electron pair of a nitrogen atom is involved in the aromaticity irrespective of whether or not the nitrogen atom itself including the unshared electron pair is a hetero atom constituting the aromatic ring. For example, even if a certain nitrogen atom is a hetero atom constituting an aromatic ring, when the nitrogen atom has an unshared electron pair that is not directly involved in the aromaticity as the essential element, the unshared electron pair is counted as one of the “effective unshared electron pair.” Namely, if there is an unshared electron pair which is not involved in aromaticity expression as the essential element in the delocalized π electron system in the conjugated unsaturated ring structure (aromatic ring), the unshared electron pair is counted as one of the “effective unshared electron pair.” In contrast, even in a case where a certain nitrogen atom is not a hetero atom constituting an aromatic ring, if all the unshared electron pairs of the nitrogen atom are involved in the aromaticity, the unshared electron pairs of the nitrogen atom are not the “effective unshared electron pair.” Note that, in respective compounds, the number of the “effective unshared electron pair” n coincides with the number of the nitrogen atoms having the “effective unshared electron pair.”

Next, the above-described “effective unshared electron pair” will be explained in detail by referring specific examples.

A nitrogen atom is an element of the group 15 and has 5 electrons on the outermost shell. Among them, three unpaired electrons are used for covalent bond with the other atoms, and the remaining two electrons serve as one pair of unshared electron pair. Therefore, usually, the number of bonds of nitrogen atom is 3.

Examples of the group having a nitrogen atom includes an amino group (—NR¹R²), an amide group (—C(═O)NR¹R²), nitro group (—NO₂), cyano group (—CN), diazo group (—N₂), azide group (—N₃), an urea group (—NR¹C═ONR²—), isothiocyanate group (—N═C═S), a thioamide group (—C(═S)NR¹R²), and the like. Note that R1 and R2 are each a hydrogen atom (H) or a substituent. The unshared electron pair of the nitrogen atom constituting these groups corresponds to [effective unshared electron pair] since the pair is not involved in aromatibity and does not covertical axis with a metal. Among them, although the unshared electron pair of the nitrogen atom of nitro group (—NO₂) is utilized for resonance structure with oxygen atom, it is considered that the pair exists on the nitrogen atom as the [effective unshared electron pair] which is not involved in aromaticity and does not covertical axis with a metal, since the good results are obtained as shown in the following examples.

Furthermore, the nitrogen atom can produce the fourth bond by utilizing the unshared electron pair. One example of such a case will be explained by referring FIG. 7. FIG. 7 shows the structural formulae of tetrabutylammonium chloride (TBAC), and tris(2-phenylpyridine)iridium (III)[Ir(ppy)₃].

Among them, TBAC is a quaternary ammonium salt where one of four butyl groups ionically bonds to a nitrogen atom and has a chloride ion as a counter ion. In this case, one of the electrons constituting the unshared electron pair of a nitrogen atom is donated to the ionic bond with the butyl group. Therefore, the nitrogen atom of TBAC is equal to a state where an unshared electron pair does not exist initially. Accordingly, the unshared electron pair of the nitrogen constituting TBAC does not correspond to the “effective unshared electron pair” which is not involved in aromaticity and is not coordinated to a metal.

Furthermore, Ir(ppy)₃ is a neutral metal complex in which the iridium atom and the nitrogen atom are covertical axisly bonded. The unshared electron pair of the nitrogen atom constituting Ir(ppy)₃ is coordinated to the iridium atom, and is utilized for covertical axis bonding. Accordingly, the unshared electron pair of the nitrogen constituting Ir(ppy)₃ does not correspond to the “effective unshared electron pair” which is not involved in aromaticity and is not coordinated to a metal.

Moreover, nitrogen atom is a usual hetero atom that can constitute an aromatic ring, and can contribute to expression of aromaticity. Examples of the “nitrogen-containing aromatic ring” include pyridine ring, piperazine ring, pyrimidine ring, triazine ring, pyrrole ring, imidazole ring, pyrazole ring, triazole ting, tetrazole ring, and the like.

FIG. 8 shows the structural formula and the molecular orbital of the pyridine ring which is one of the above-described nitrogen-containing aromatic rings. AS shown in FIG. 8, the pyridine ring has 6 delocalized π electrons in the conjugated (resonant) unsaturated ring structure arranged in the form of a 6-membered ring, and thus satisfies 4n+2 (n=0 or natural numeral) of the “Hueckel's rule”. Since the nitrogen atom in the 6-membered ring is the substituent of —CH═, only one unshared electron is used for the 6 π electron system, and the unshared electron pair is not involved in expression of aromaticity as an essential element.

Accordingly, the unshared electron pair of the nitrogen atom constituting the pyridine ring corresponds to the [effective unshared electron pair] which is not involved in aromaticity and is not coordinated to a metal.

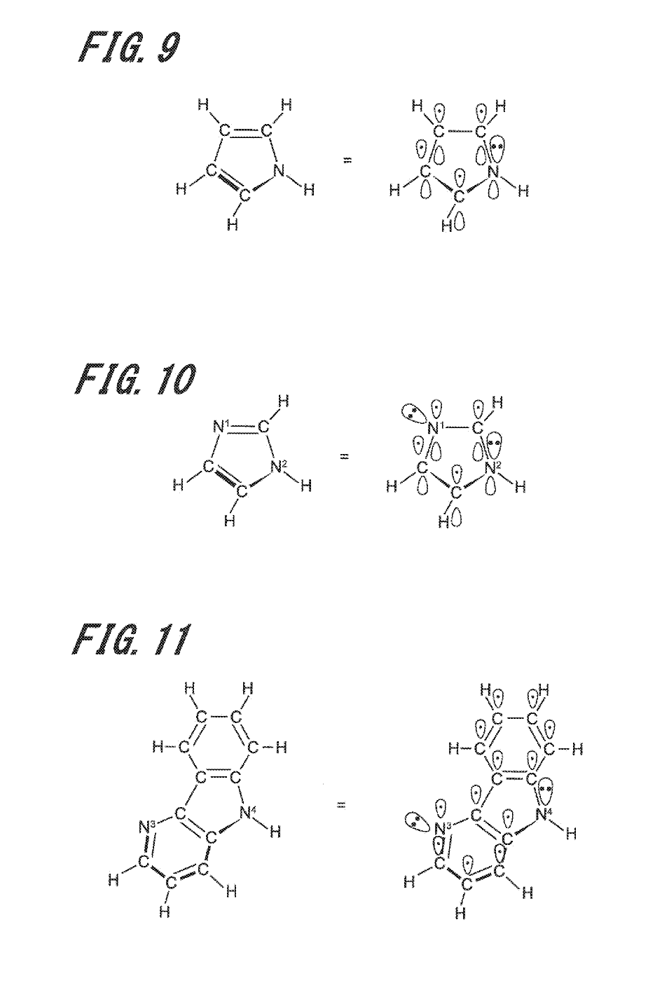

FIG. 9 shows the structural formula and the molecular orbital of the pyrrole ring. AS shown in FIG. 9, the pyrrole ring has a structure in which one of the carbon atoms constituting five-membered ring is substituted with a nitrogen atom, and since the number of π electrons is six, the pyrrole ring is a nitrogen-containing aromatic ring which satisfies the “Hueckel's rule”. Since the nitrogen atom of the pyrrole ring also bonds to a hydrogen atom, the unshared electron pair is used for the 6 π electron system.

Therefore, though the nitrogen atom of the pyrrole ring has an unshared electron pair, the unshared electron pair is utilized for expressing the aromaticity as the essential element, and thus does not correspond to the “effective unshared electron pair” which is not involved in aromaticity and is not coordinated to a metal.

FIG. 10 shows the structural formula and the molecular orbital of the imidazole ring. As shown in FIG. 10, the imidazole ring has a structure in which the carbon atoms of 1-position and 3-position of the five-membered ring are substituted by the two nitrogen atoms N¹, N², and is also a nitrogen-containing aromatic ring having six π electrons. Among them, one nitrogen atom N¹ supplies only one unshared electron to the 6 π electron system, and thus, is the nitrogen atom of the pyridine ring-type nitrogen atom in which the unshared electron pair is not utilized for the expression of aromaticity. Accordingly, the unshared electron pair of the nitrogen atom N¹ corresponds to the [effective unshared electron pair]. In contrast to this, since the other nitrogen atom N² is the pyrrole ring-type nitrogen atom which supplies the unshared electron pair to the 6 π electron system, the unshared electron pair of the nitrogen atom N² does not correspond to the “effective unshared electron pair”.

Accordingly, in the imidazole ring, among the two nitrogen atoms N¹, N², only the unshared electron pair of the nitrogen atom N¹ corresponds to the [effective unshared electron pair].

The selection of the unshared electron pair in the nitrogen atom of the “nitrogen-containing aromatic ring” as described above also applies to the case of a condensed ring compound having a nitrogen-containing aromatic ring structure in the same way.

FIG. 11 shows the structural formula and the molecular orbital of the δ-carboline ring. As shown in FIG. 11, the δ-carboline ring is a condensed ring compound having a nitrogen-containing aromatic ring structure, and is an azacarbazole compound in which a benzene ring structure, a pyrrole ring structure and a pyridine ring structure are condensed in this order. In this compound, the nitrogen atom N³ of the pyridine ring supplies only one unshared electron to the π electron system, and the nitrogen atom N⁴ of the pyridine ring supplies one unshared electron pair to the π electron system, and thus the number of the whole π electrons is fourteen together with eleven π electrons derived from the carbon atoms which form the rings.

Accordingly, among the two nitrogen atoms N³ and N⁴ of δ-carboline ring, the unshared electron pair of the nitrogen atom N³ constituting the pyridine ring corresponds to the “effective unshared electron pair”, but the unshared electron pair of the nitrogen atom N⁴ constituting the pyrrole ring does not correspond to the “effective unshared electron pair”.

As described above, the unshared electron pair of the nitrogen atom constituting the condensed ring compound is involved in bonding in the condensed ring compound in the same way as bonding in the monocyclic rings such as pyridine ring and pyrrole ring constituting the condensed ring compound.

The “effective unshared electron pair” as explained above is important because it expresses a strong interaction with the silver which is a main component of the transparent electrode 13. The nitrogen atoms having these “effective unshared electron pairs” are preferably nitrogen atoms in the nitrogen-containing aromatic ring from the viewpoint of stability, durability. Accordingly, the compound included in the nitrogen-containing layer 12 preferably has an aromatic heterocyclic ring which sets, as the hetero atom, the nitrogen atom having the “effective unshared electron pair”.

In the present embodiment, the number n of the “effective unshared electron pair” relative to the molecular weight M of such a compound is defined as, for example, an effective unshared electron pair content ratio [n/M]. In addition, the nitrogen-containing layer 12 is characterized by being constituted using a compound that is selected so that the [n/M] is 2.0×10⁻³≦[n/M]. Furthermore, the nitrogen-containing layer 12 is preferable when the effective unshared electron pair content ratio [n/M] defined as described above is within the range of 3.9×10⁻³≦[n/M], more preferable when the content ratio [n/M] is within the range of 6.5×10⁻³≦[n/M]. The above-described effect of the nitrogen-containing layer 12 suppressing the aggregation of silver constituting the transparent electrode 13 is obtained by constituting the nitrogen-containing layer 12 through the use of a compound having the effective unshared electron pair content ratio of [n/M].

In addition, since the nitrogen-containing layer 12 may use a compound whose effective unshared electron pair content ratio [n/M] is within the above-described prescribed range, for example, the nitrogen-containing layer 12 may also be constituted only of such a compound, or may be constituted mixing such a compound and another compound for use. Another compound may or may not contain a nitrogen atom, and furthermore, the effective unshared electron pair content ratio [n/M] may not be within the prescribed range.

When the nitrogen-containing layer 12 is constituted using a plurality of compounds, for example, the molecular weight M of the mixed compound obtained by mixing these compounds is obtained based on the mixing ratio of the compounds. Additionally, an average value of the effective unshared electron pair content ratio [n/M] is obtained from the total number n of “effective unshared electron pairs” relative to the molecular weight M. The value is preferably within the prescribed range. Namely, the effective unshared electron pair content ratio [n/M] of the nitrogen-containing layer 12 itself is preferably within the prescribed range.

Note that, in a case where the nitrogen-containing layer 12 is constituted using a plurality of compounds and has a configuration different in the mixing ratio (content ratio) of compounds in the thickness direction, it is sufficient that the effective unshared electron pair content ratio [n/M] in the surface layer of the nitrogen-containing layer 12 on the side in contact with the transparent electrode 13 is within the prescribed range.

### [Compound-1]

Hereinafter, specific examples of compounds (No. 1 to No. 48), which satisfy that the effective unshared electron pair content ratio [n/M] is 2.0×10⁻³≦[n/M], will be shown as compounds constituting the nitrogen-containing layer 12. In respective compounds of No. 1 to No. 48, o is given to a nitrogen atom having the “effective unshared electron pair.” In addition, in the Table 1 below, molecular weights M of these compounds of No. 1 to No. 48, numbers n of the “effective unshared electron pair,” and effective unshared electron pair content ratios [n/M] are shown. In copper phthalocyanine of a compound 33 below, unshared electron pairs not coordinated to the copper, among unshared electron pairs of a nitrogen atom, are counted as the effective unshared electron pair.

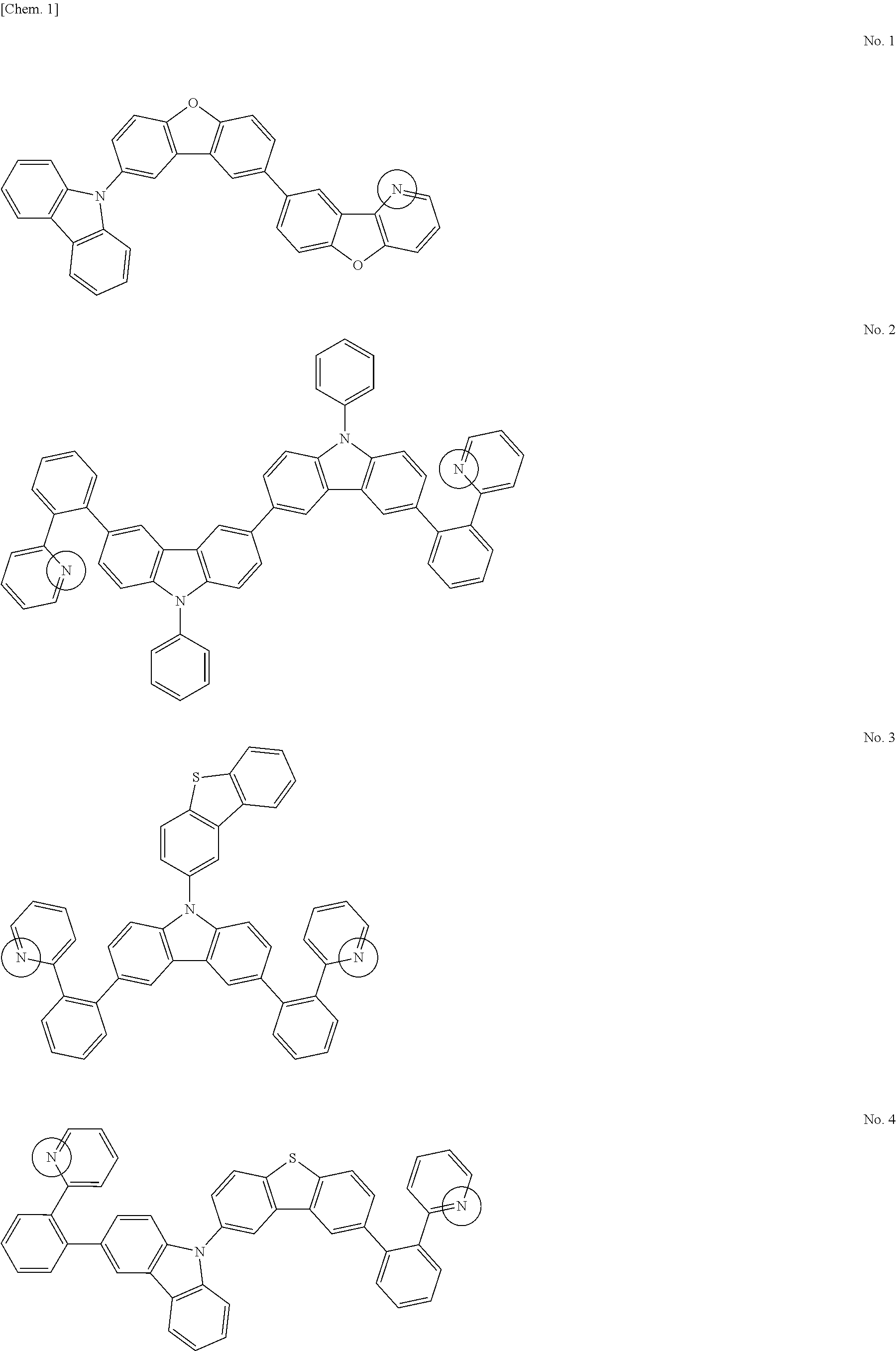 [SMILES: c1cnc2c(c1)oc1ccc(-c3ccc4oc5ccc(-n6c7ccccc7c7ccccc76)cc5c4c3)cc12 ; c1ccc(-n2c3ccc(-c4ccc5c(c4)c4cc(-c6ccccc6-c6ccccn6)ccc4n5-c4ccccc4)cc3c3cc(-c4ccccc4-c4ccccn4)ccc32)cc1 ; c1ccc(-c2ccccc2-c2ccc3c(c2)c2cc(-c4ccccc4-c4ccccn4)ccc2n3-c2ccc3sc4ccccc4c3c2)nc1 ; c1ccc(-c2ccccc2-c2ccc3sc4ccc(-n5c6ccccc6c6cc(-c7ccccc7-c7ccccn7)ccc65)cc4c3c2)nc1]

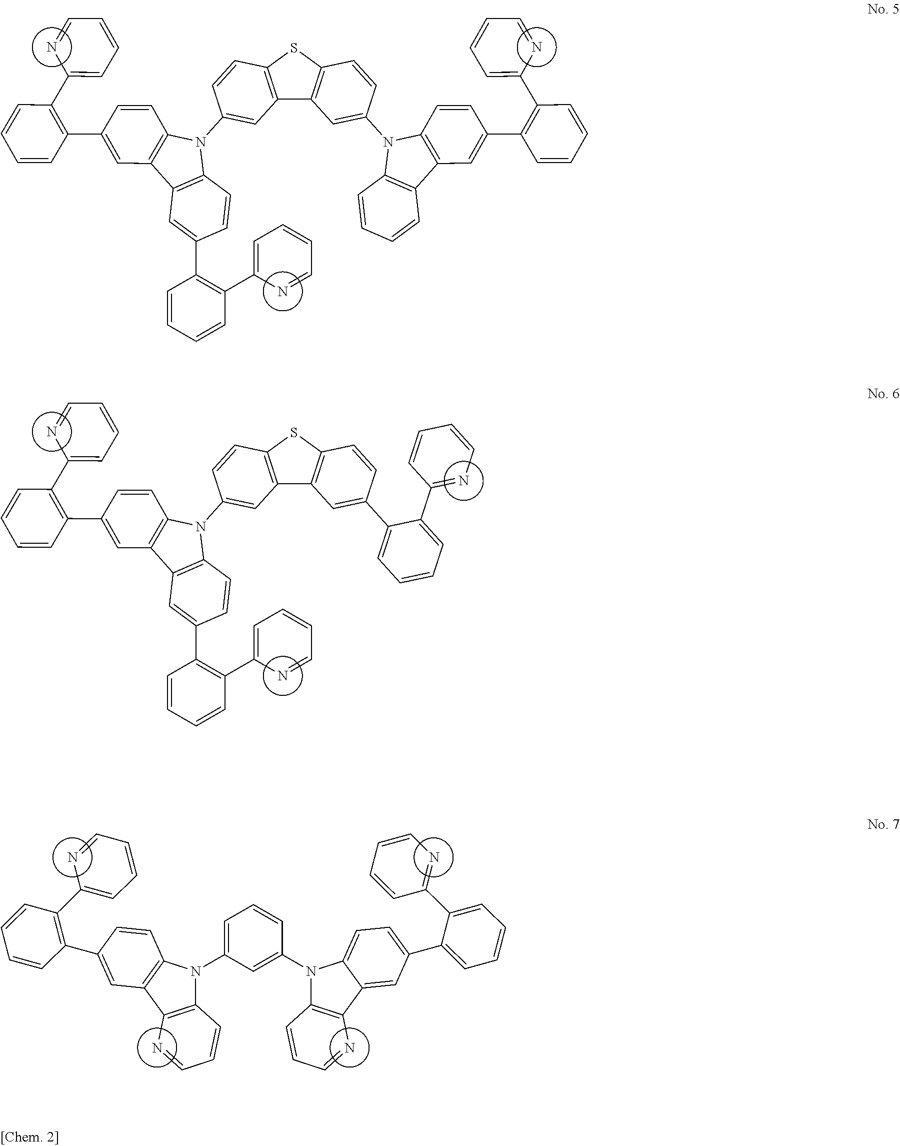 [SMILES: c1ccc(-c2ccccc2-c2ccc3c(c2)c2ccccc2n3-c2ccc3sc4ccc(-n5c6ccc(-c7ccccc7-c7ccccn7)cc6c6cc(-c7ccccc7-c7ccccn7)ccc65)cc4c3c2)nc1 ; c1ccc(-c2ccccc2-c2ccc3sc4ccc(-n5c6ccc(-c7ccccc7-c7ccccn7)cc6c6cc(-c7ccccc7-c7ccccn7)ccc65)cc4c3c2)nc1 ; c1ccc(-c2ccccc2-c2ccc3c(c2)c2ncccc2n3-c2cccc(-n3c4ccc(-c5ccccc5-c5ccccn5)cc4c4ncccc43)c2)nc1]

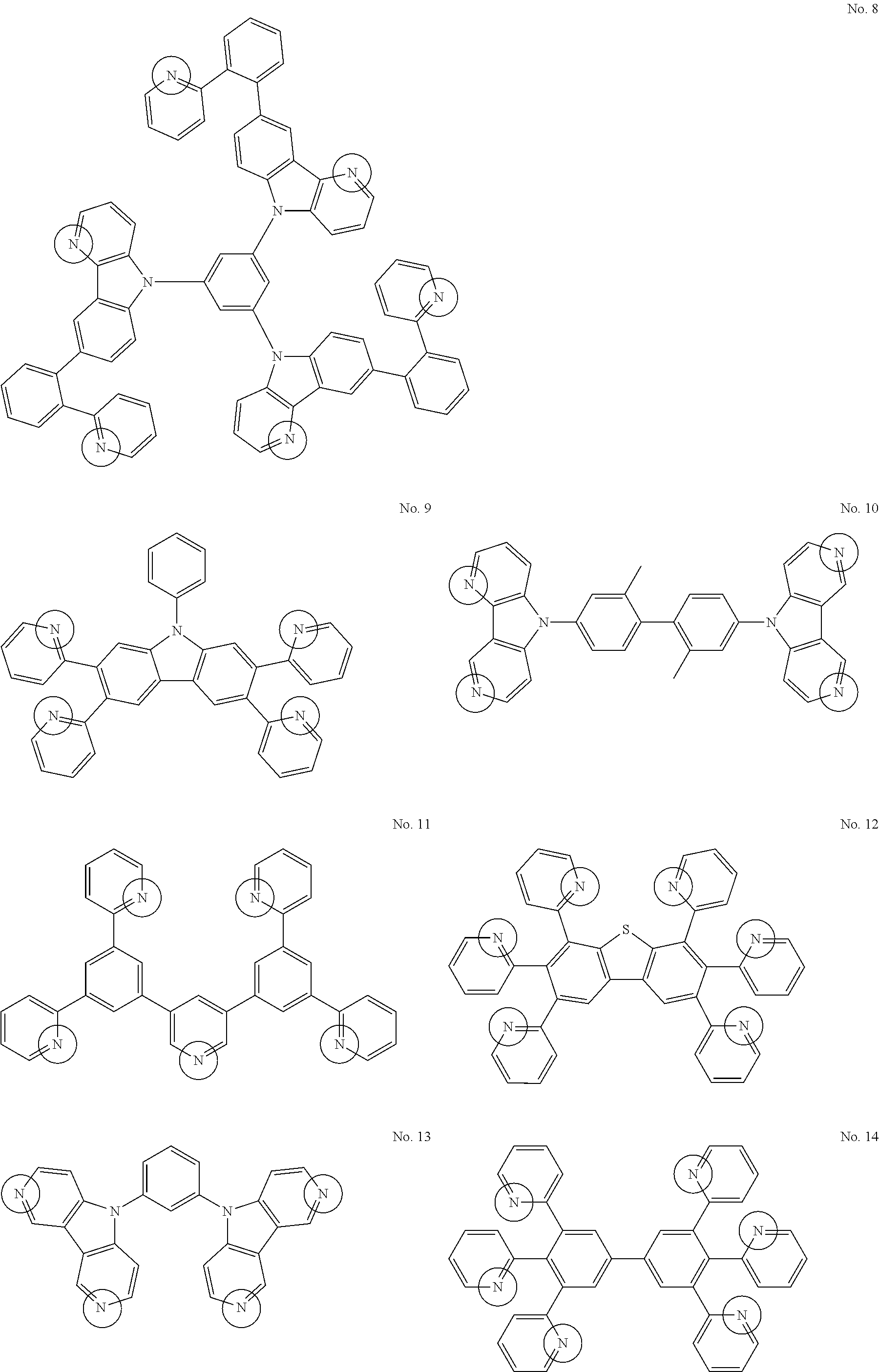

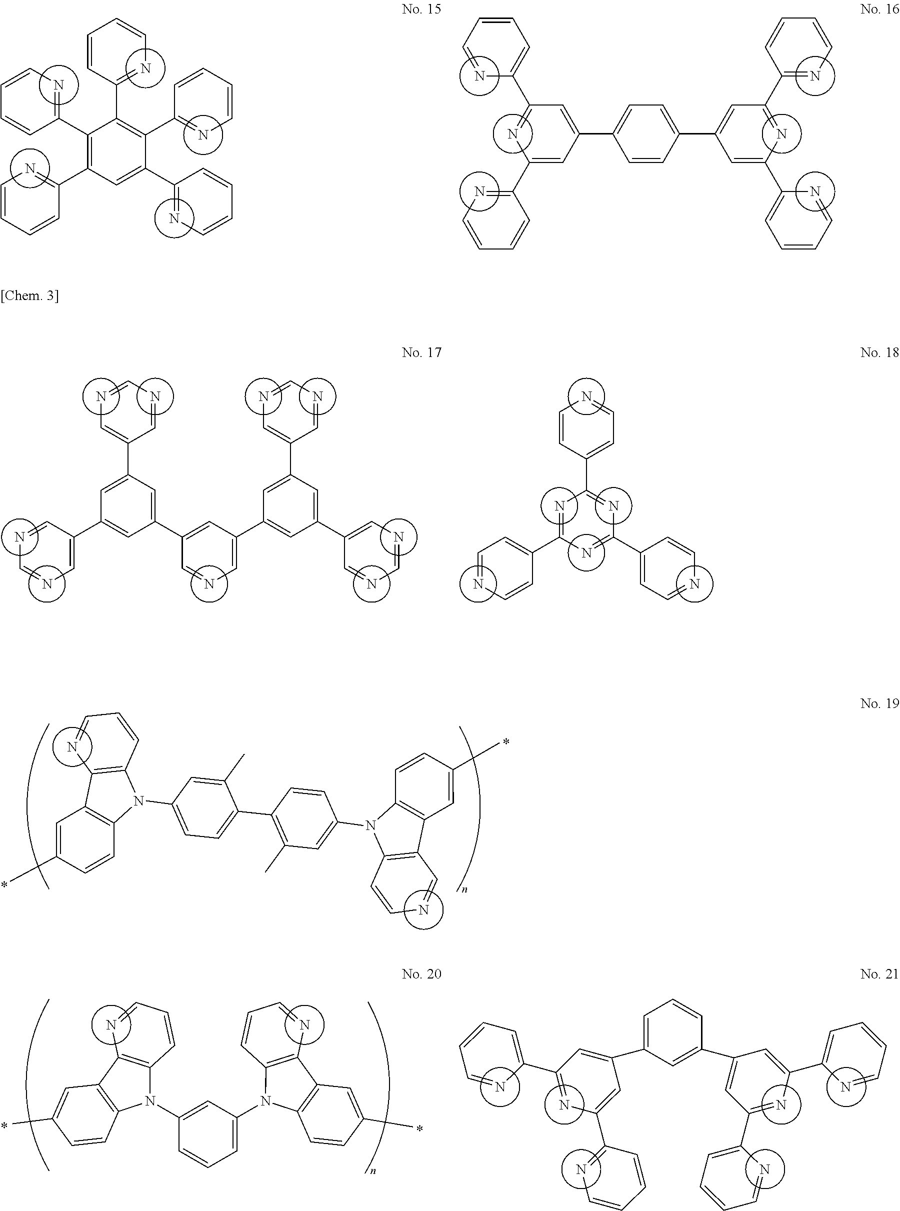

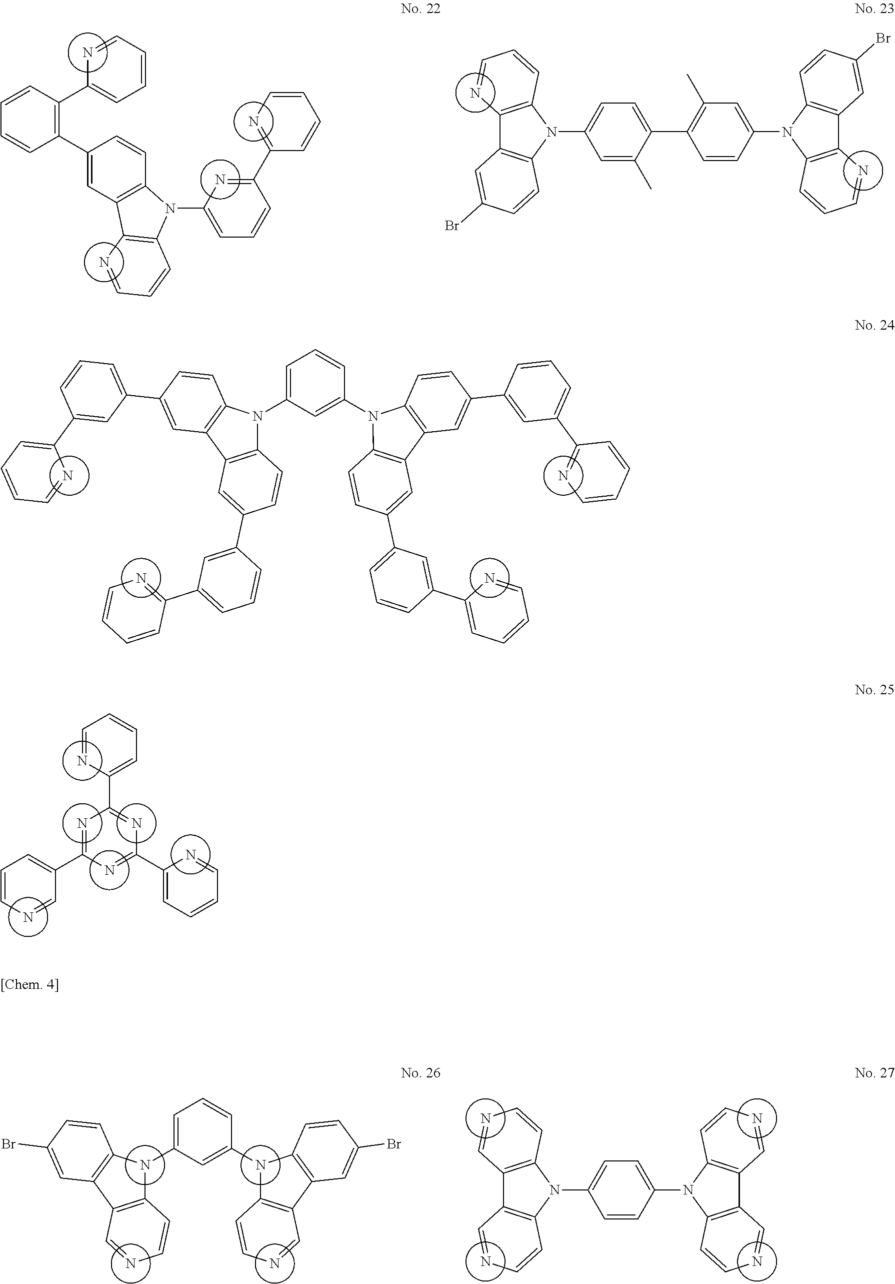 [SMILES: c1ccc(-c2cccc(-n3c4ccc(-c5ccccc5-c5ccccn5)cc4c4ncccc43)n2)nc1 ; Cc1cc(-n2c3ccc(Br)cc3c3ncccc32)ccc1-c1ccc(-n2c3ccc(Br)cc3c3ncccc32)cc1C ; c1ccc(-c2cccc(-c3ccc4c(c3)c3cc(-c5cccc(-c6ccccn6)c5)ccc3n4-c3cccc(-n4c5ccc(-c6cccc(-c7ccccn7)c6)cc5c5cc(-c6cccc(-c7ccccn7)c6)ccc54)c3)c2)nc1 ; c1ccc(-c2nc(-c3cccnc3)nc(-c3ccccn3)n2)nc1 ; Brc1ccc2c(c1)c1cnccc1n2-c1cccc(-n2c3ccncc3c3cc(Br)ccc32)c1 ; c1cc2c(cn1)c1cnccc1n2-c1ccc(-n2c3ccncc3c3cnccc32)cc1]

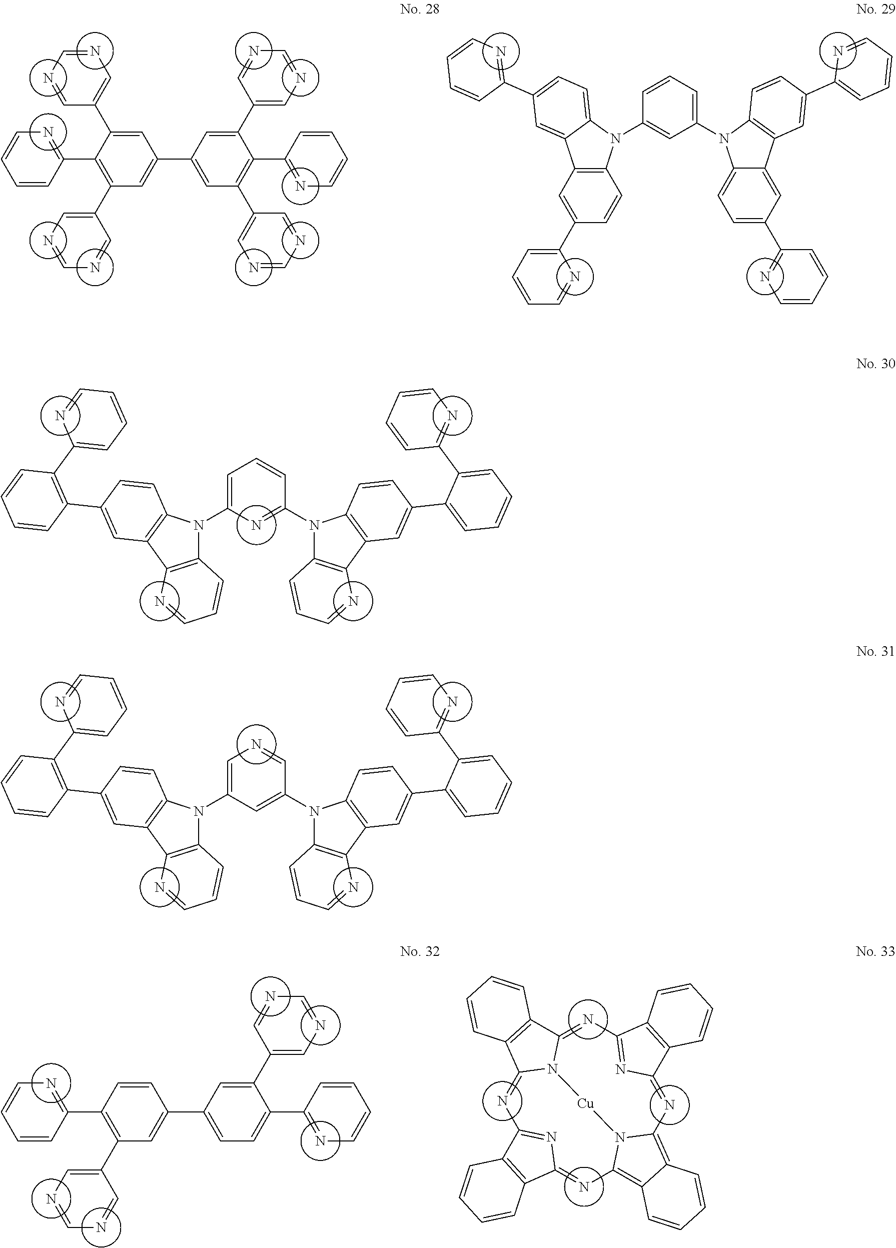

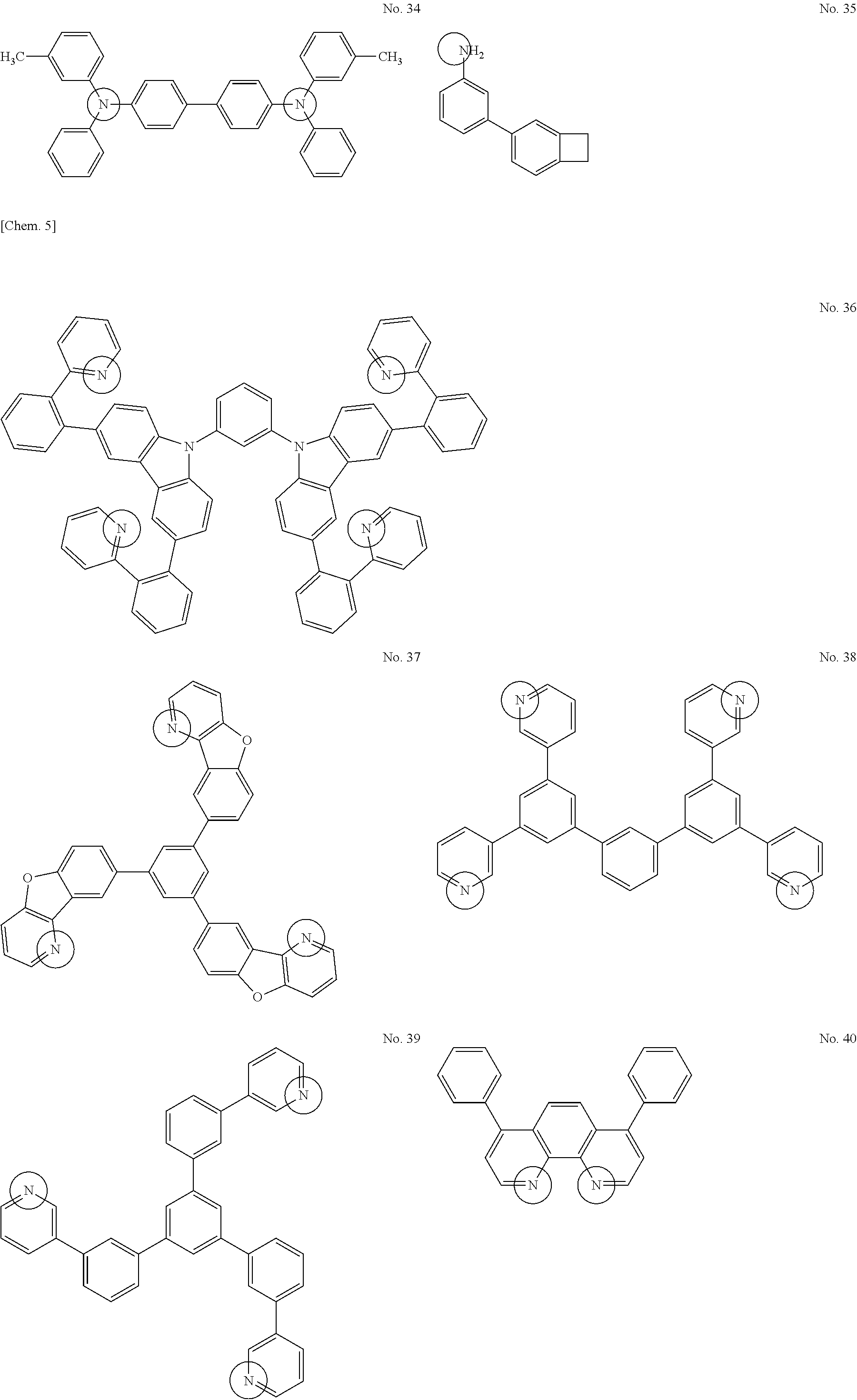

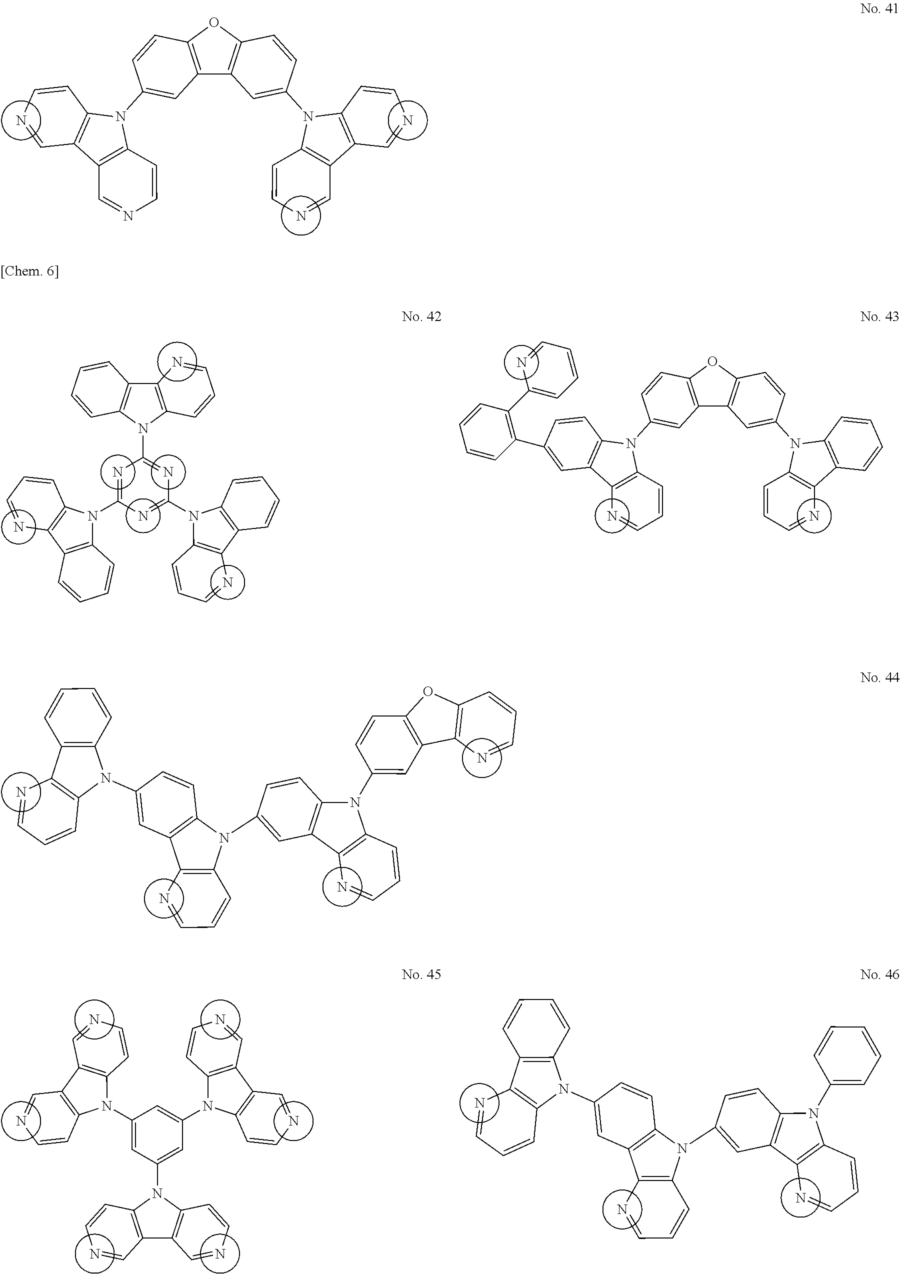 [SMILES: c1cc2c(cn1)c1cnccc1n2-c1ccc2oc3ccc(-n4c5ccncc5c5cnccc54)cc3c2c1 ; c1ccc2c(c1)c1ncccc1n2-c1nc(-n2c3ccccc3c3ncccc32)nc(-n2c3ccccc3c3ncccc32)n1 ; c1ccc(-c2ccccc2-c2ccc3c(c2)c2ncccc2n3-c2ccc3oc4ccc(-n5c6ccccc6c6ncccc65)cc4c3c2)nc1 ; c1cnc2c(c1)oc1ccc(-n3c4ccc(-n5c6ccc(-n7c8ccccc8c8ncccc87)cc6c6ncccc65)cc4c4ncccc43)cc12 ; c1cc2c(cn1)c1cnccc1n2-c1cc(-n2c3ccncc3c3cnccc32)cc(-n2c3ccncc3c3cnccc32)c1 ; c1ccc(-n2c3ccc(-n4c5ccc(-n6c7ccccc7c7ncccc76)cc5c5ncccc54)cc3c3ncccc32)cc1]

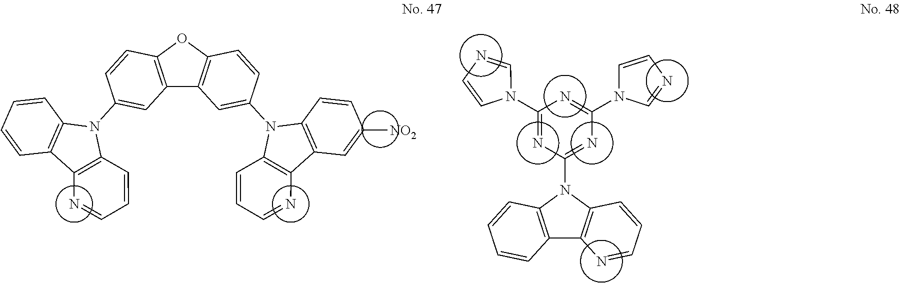 [SMILES: O=[N+]([O-])c1ccc2c(c1)c1ncccc1n2-c1ccc2oc3ccc(-n4c5ccccc5c5ncccc54)cc3c2c1 ; c1ccc2c(c1)c1ncccc1n2-c1nc(-n2ccnc2)nc(-n2ccnc2)n1]

TABLE 1

| | Number (n) of | Molecular | | Corresponding |
|---|---|---|---|---|
| | effective unshared | weight | | General |
| Compound | electron pairs | (M) | [n/M] | formula |
| No. 1 | 1 | 500.55 | 2.0E−03 | (1b) |
| No. 2 | 2 | 790.95 | 2.5E−03 | |
| No. 3 | 2 | 655.81 | 3.0E−03 | |
| No. 4 | 2 | 655.81 | 3.0E−03 | |
| No. 5 | 3 | 974.18 | 3.1E−03 | (2) |
| No. 6 | 3 | 808.99 | 3.7E−03 | |
| No. 7 | 4 | 716.83 | 5.6E−03 | (1a-1), (2) |
| No. 8 | 6 | 1036.19 | 5.8E−03 | (1a-1), (4) |
| No. 9 | 4 | 551.64 | 7.3E−03 | |
| No. 10 | 4 | 516.60 | 7.7E−03 | (1a-2), (3) |
| No. 11 | 5 | 539.63 | 9.3E−03 | |
| No. 12 | 6 | 646.76 | 9.3E−03 | (5) |
| No. 13 | 4 | 412.45 | 9.7E−03 | (1a-2), (3) |
| No. 14 | 6 | 616.71 | 9.7E−03 | (5) |
| No. 15 | 5 | 463.53 | 1.1E−02 | (2) |
| No. 16 | 6 | 540.62 | 1.1E−02 | (6) |
| No. 17 | 9 | 543.58 | 1.7E−02 | |
| No. 18 | 6 | 312.33 | 1.9E−02 | |
| No. 19 | 2 | 512.60 | 3.9E−03 | (1a-1) |
| No. 20 | 2 | 408.45 | 4.9E−03 | (1a-1) |
| No. 21 | 6 | 540.62 | 1.1E−02 | (6) |
| No. 22 | 4 | 475.54 | 8.4E−03 | (1a-1) |
| No. 23 | 2 | 672.41 | 3.0E−03 | (1a-1) |
| No. 24 | 4 | 1021.21 | 3.9E−03 | |
| No. 25 | 6 | 312.33 | 1.9E−02 | (6) |
| No. 26 | 2 | 568.26 | 3.5E−03 | (1a) |
| No. 27 | 4 | 412.45 | 9.7E−03 | (1a-2), (3) |
| No. 28 | 10 | 620.66 | 1.6E−02 | (5) |
| No. 29 | 4 | 716.83 | 5.6E−03 | |
| No. 30 | 5 | 717.82 | 7.0E−03 | (1a-1), (2) |
| No. 31 | 5 | 717.82 | 7.0E−03 | (1a-1), (2) |
| No. 32 | 6 | 464.52 | 1.3E−02 | |
| No. 33 | 4 | 576.10 | 6.9E−03 | |
| No. 34 | 2 | 516.67 | 3.9E−03 | |
| No. 35 | 1 | 195.26 | 5.1E−03 | |
| No. 36 | 4 | 1021.21 | 3.9E−03 | (2) |
| No. 37 | 3 | 579.60 | 5.2E−03 | (1b) |
| No. 38 | 4 | 538.64 | 7.4E−03 | |
| No. 39 | 3 | 537.65 | 5.6E−03 | |
| No. 40 | 2 | 332.40 | 6.0E−03 | |
| No. 41 | 4 | 502.15 | 8.0E−03 | (1a-2), (3) |
| No. 42 | 6 | 579.19 | 1.0E−02 | (1a-1) |
| No. 43 | 3 | 653.22 | 4.6E−03 | (1a-1) |
| No. 44 | 4 | 667.21 | 6.0E−03 | (1a-1), (1b) |
| No. 45 | 6 | 579.19 | 1.0E−02 | (1a-2), (3) |
| No. 46 | 3 | 576.65 | 5.2E−03 | (1a-1) |
| No. 47 | 3 | 545.55 | 5.5E−03 | (1a-1) |
| No. 48 | 6 | 379.38 | 1.6E−02 | (1a-1), (7), (8a) |

Note that, in the above Table 1, when those exemplified compounds are also involved in the general formulae (1) to (8a) which represent other compound-2 explained herein below, the corresponding general formulae are indicated.

[Compound-2]

In addition, as the compound constituting the nitrogen-containing layer 12, other than the above compound having the effective unshared electron pair content [n/M] of the above-described predetermined range, other compounds may be used. The other compounds used for the nitrogen-containing layer 12 are preferably compounds containing a nitrogen atom, regardless of whether or not the effective unshared electron pair content [n/M] is within the predetermined range. Among them, a compound containing the nitrogen atom having the [effective unshared electron pair] is particularly preferably used. In addition, there are used, as other compounds used for the nitrogen-containing layer 12, compounds having properties to be required for each of the organic EL element provided with the nitrogen-containing layer 12 is applied. In a case where the nitrogen-containing layer 12 is used as the organic EL element 10, the following compounds represented by the general formulae (1) to (8a) are preferably used as the compound constituting the nitrogen-containing layer 12 from the viewpoints of film formation and electron transport property.

Among these compounds represented by the general formulae (1) to (8a), a compound which falls within the above-described range of the effective unshared electron pair content [n/M] is included, and such a compound can be used alone as the compound constituting the nitrogen-containing layer 12 (See Table 1). On the other hand, if a compound represented by the general formulae (1) to (8a) does not fall within the above-described range of the effective unshared electron pair content [n/M], the compound can be used as the compound constituting the nitrogen-containing layer 12 by mixing with the compound having the above-described range of the effective unshared electron pair content [n/M].

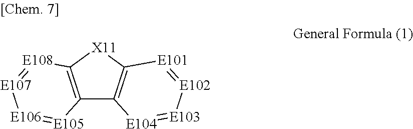

In the above general formula (1), X11 represents —N(R11) or —O—. In addition, in the general formula (1), E101 to E108 each represent —C(R12)= or —N═; and at least one of E101 to E108 is −N═. In addition, the above-described R11 and R12 each represent hydrogen atom or a substituent.

Examples of the substituent include an alkyl group (for example, methyl group, ethyl group, propyl group, isopropyl group, tert-butyl group, pentyl group, hexyl group, octyl group, dodecyl group, tridecyl group, tetradecyl group, pentadecyl group and the like), a cycloalkyl group (for example, cyclopentyl group, cyclohexyl group and the like), an alkenyl group (for example, vinyl group, allyl group and the like), an alkynyl group (for example, ethynyl group, propargyl group and the like), an aromatic hydrocarbon group (also referred to as an aromatic carbon ring group, an aryl group or the like, for example; phenyl group, p-chlorophenyl group, mesityl group, tolyl group, xylyl group, naphthyl group, anthryl group, azulenyl group, acenaphthenyl group, fluorenyl group, phenanthryl group, indenyl group, pyrenyl group, biphenyryl group and the like), an aromatic heterocyclic ring group (for example, furyl group, thienyl group, pyridyl group, pyridazinyl group, pyrimidinyl group, pyrazinyl group, triazinyl group, imidazolyl group, pyrazolyl group, thiazolyl group, quinazolinyl group, carbazolyl group, carbolinyl group, diazacarbazolyl group (a group in which a certain carbon atom constituting the carboline ring of the above-described carbolinyl group is substituted with a nitrogen atom), phtharazinyl group and the like), a ring group (for example, pyrrolidyl group, imidazolidyl group, morpholyl group, oxazolidyl group and the like), an alkoxy group (for example, methoxy group, ethoxy group, propyloxy group, pentyloxy group, hexyloxy group, octyloxy group, dodecyloxy group and the like), a cycloalkoxy group (for example, cyclopentyloxy group, cyclohexyloxy group and the like), an aryloxy group (for example, phenoxy group, naphthyloxy group and the like), an alkylthio group (for example, methylthio group, ethylthio group, propylthio group, pentylthio group, hexylthio group, octylthio group, dodecylthio group and the like), a cycloalkylthio group (for example, cyclopentylthio group, cyclohexylthio group and the like), an arylthio group (for example, phenylthio group, naphthylthio group and the like), an alkoxycarbonyl group (for example, methyloxycarbonyl group, ethyloxycarbonyl group, butyloxycarbonyl group, octyloxycarbonyl group, dodecyloxycarbonyl group and the like), an aryloxycarbonyl group (for example, phenyloxycarbonyl group, naphthyloxycarbonyl group and the like), a sulfamoyl group (for example, aminosulfonyl group, methylaminosulfonyl group, dimethylaminosulfonyl group, butylaminosulfonyl group, hexylaminosulfonyl group, cyclohexylaminosulfonyl group, octylaminosulfonyl group, dodecylaminosulfonyl group, phenylaminosulfonyl group, naphthylaminosulfonyl group, 2-pyridylaminosulfonyl group and the like), an acyl group (for example, acetyl group, ethylcarbonyl group, propylcarbonyl group, pentylcarbonyl group, cyclohexylcarbonyl group, octylcarbonyl group, 2-ethylhexylcarbonyl group, dodecylcarbonyl group, phenylcarbonyl group, naphthylcarbonyl group, pyridylcarbonyl group and the like), an acyloxy group (for example, acetyloxy group, ethylcarbonyloxy group, butylcarbonyloxy group, octylcarbonyloxy group, dodecylcarbonyloxy group, phenylcarbonyloxy group and the like), an amido group (for example, methylcarbonylamino group, ethylcarbonylamino group, dimethylcarbonylamino group, propylcarbonylamino group, pentylcarbonylamino group, cyclohexylcarbonylamino group, 2-ethylhexylcarbonylamino group, octylcarbonylamino group, dodecylcarbonylamino group, phenylcarbonylamino group, naphthylcarbonylamino group and the like), a carbamoyl group (for example, aminocarbonyl group, methylaminocarbonyl group, dimethylaminocarbonyl group, propylaminocarbonyl group, pentylaminocarbonyl group, cyclohexylaminocarbonyl group, octylaminocarbonyl group, 2-ethylhexylaminocarbonyl group, dodecylaminocarbonyl group, phenylaminocarbonyl group, naphthylaminocarbonyl group, 2-pyridylaminocarbonyl group and the like), an ureido group (for example, methylureido group, ethylureido group, pentylureido group, cyclohexylureido group, octylureido group, dodecylureido group, phenylureido group, naphthylureido group, 2-pyridylaminoureido group and the like), a sulfinyl group (for example, methylsulfinyl group, ethylsulfinyl group, butylsulfinyl group, cyclohexylsulfinyl group, 2-ethylhexylsulfinyl group, dodecylsulfinyl group, phenylsulfinyl group, naphthylsulfinyl group, 2-pyridylsulfinyl group and the like), an alkylsulfonyl group (for example, methylsulfonyl group, ethylsulfonyl group, butylsulfonyl group, cyclohexylsulfonyl group, 2-ethylhexylsulfonyl group, dodecylsulfonyl group and the like), an arylsulfonyl group or a heteroarylsulfonyl group (for example, phenylsulfonyl group, naphthylsulfonyl group, 2-pyridylsulfonyl group and the like), an amino group (for example, amino group, ethylamino group, dimethylamino group, butylamino group, cyclopentylamino group, 2-ethylhexylamino group, dodecylamino group, anilino group, naphthylamino group, 2-pyridylamino group, piperidyl group (also referred to as piperidinyl group), 2,2,6,6-tetramethylpiperidinyl group and the like), a halogen atom (for example, fluorine atom, chlorine atom, bromine atom and the like), a fluorinated hydrocarbon group (for example, fluoromethyl group, trifluoromethyl group, pentafluoroethyl group, pentafluorophenyl group and the like), cyano group, nitro group, hydroxyl group, mercapto group, a silyl group (for example, trimethylsilyl group, triisopropylsilyl group, triphenylsilyl group, phenyldiethylsilyl group and the like), a phosphate group (for example, dihexylphosphoryl group and the like), a phosphite group (for example, diphenylphosphinyl group and the like), phosphono group, and the like.

Some of these substituents may further be substituted by the above-described substituent. In addition, a plurality of the substituents may bind to each other to form a ring. The substituents which do not prevent the interaction between a compound and silver (Ag) are preferably used, and further the substituents having the nitrogen atom having the above-described effective unshared electron pair are particularly preferably applied. Note that the above description as to the substituents is also applied to the substituents designated in the following explanation of the general formulae (2) to (8a).

The compound having the structure represented by the above general formula (1) is preferable because the strong interaction between the nitrogen atom in the compound and the silver constituting the transparent electrode 13 can be expressed.

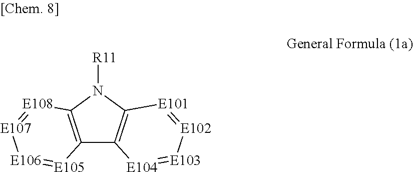

The compound having the structure represented by the above general formula (1a) is one form of the compound having the structure expressed by the above general formula (1), and is a compound in which X11 is —N(R11)- in the general formula (1). This compound is preferable because the above interaction can be more strongly expressed.

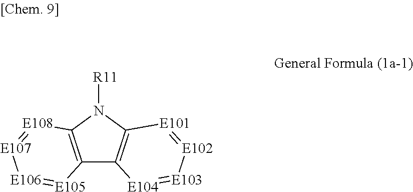

The compound having the structure represented by the above general formula (1a-1) is one form of the compound having the structure expressed by the above general formula (1a), and is a compound in which E104 is —N═ in the general formula (1a). This compound is preferable because the above interaction can be more effectively expressed.

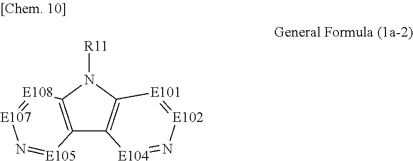

The compound having the structure represented by the above general formula (1a-2) is another form of the compound having the structure expressed by the above general formula (1a), and is a compound in which E103 and E106 are —N═ in the general formula (1a). This compound is preferable because the above interaction can be more strongly expressed.

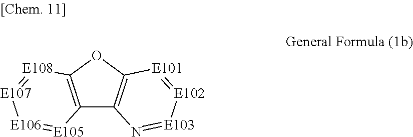

The compound having the structure represented by the above general formula (1b) is another form of the compound having the structure expressed by the above general formula (1), and is a compound in which X11 is —O— and E104 is —N═ in the general formula (1). This compound is preferable because the above interaction can be more effectively expressed.

Furthermore, the compounds having the structure represented by the following general formulae (2) to (8a) are preferable because the above interaction can be more effectively expressed.

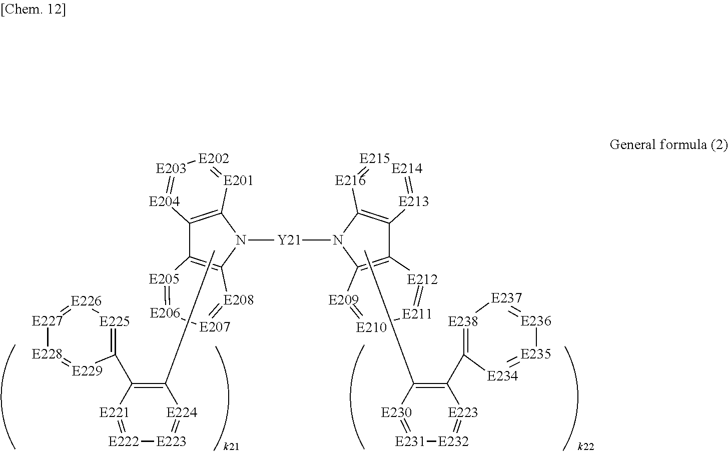

The above-described general formula (2) is also one embodiment of the general formula (1). In the general formula (2), Y21 represents a divalent linking group of an arylene group, a heteroarylene group or a combination thereof. E201 to E216 and E221 to E238 each represent —C(R21)= or —N═, and R21 represents hydrogen atom (H) or a substituent. However, at least one of E221 to E229 and at least one of E230 to E238 represent —N═. k21 and k22 represent an integer of 0 to 4, and k21+k22 is an integer of 2 or more.

In the general formula (2), examples of an arylene group represented by Y21 include, for example, o-phenylene group, p-phenylene group, naphthalenediyl group, anthracenediyl group, naphthacenediyl group, pyrenediyl group, naphthylnaphthalenediyl group, biphenyldiyl group (for example, [1,1′-biphenyl]-4,4′-diyl group, 3,3′-biphenyldiyl group, 3,6-biphenyldiyl group and the like), terphenyldiyl group, quaterphenyldiyl group, quinquephenyldiyl group, sexiphenyldiyl group, septiphenyldiyl group, octiphenyldiyl group, nobiphenyldiyl group, deciphenyldiyl group and the like.

Furthermore, in the general formula (2), examples of a heteroarylene group represented by Y21 include, for example, a divalent group derived from a group consisting of carbazole ring, carboline ring, diazacarbazole ring (also referred to as monoazacarboline ring, and indicating a ring structure in which one carbon atom constituting the carboline ring is substituted with a nitrogen atom), triazole ring, pyrrole ring, pyridine ring, pyrazine ring, quinoxaline ring, thiophene ring, oxadiazole ring, dibenzofuran ring, dibenzothiophene ring, indole ring and the like.

As a preferable divalent linking group which is an arylene group, a heteroarylene group or a combination thereof represented by Y21 contain, among the heteroarylene groups, preferable is a group which is derived from a condensed aromatic heterocyclic ring formed by condensing three or more rings, and as the group derived from the condensed aromatic heterocyclic ring formed by condensing three or more rings, preferable is a group derived from dibenzofuran ring or a group derived from dibenzothiophene ring.

In the general formula (2), it is preferable that six or more of E201 to E208 and six or more of E209 to E216 each represent —C(R21)=.

In the general formula (2), it is preferable that at least one of E225 to E229 and at least one of E234 to E238 represent —N═.

Furthermore, in the general formula (2), it is preferable that at least one of E225 to E229 and at least one of E234 to E238 represent —N═.

In addition, in the general formula (2), preferable embodiment is that E221 to E224 and E230 to E233 each represent —C(R21)=.

Moreover, in the compound represented by the general formula (2), it is preferable that E203 represents —C(R21)=, and R21 represents a linking moiety, and in addition, it is preferable that E211 also represents —C(R21)=, and R21 represents a linking moiety.

Furthermore, it is preferable that E225 and E234 represent —N═, and it is preferable that E221 to E224 and E230 to E233 each represent —C(R21)=.

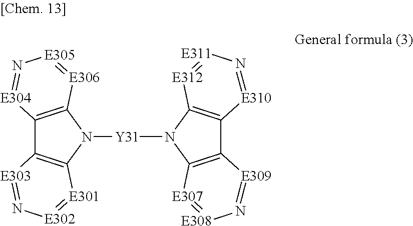

The general formula (3) is also one embodiment of the general formula (1a-2). In the general formula (3), E301 to E312 each represent —C(R31)=, and the above-described R31 represents hydrogen atom (H) or a substituent. Y31 represents a divalent linking group of an arylene group, a heteroarylene group or combination thereof.

In addition, in the general formula (3), a preferable embodiment of the divalent linking group of an arylene group, a heteroarylene group or combination thereof represented by Y31, is the same as that in Y21 of the general formula (2).

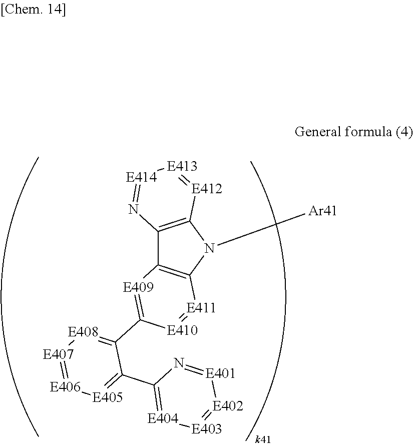

The general formula (4) is also one embodiment of the general formula (1a-1). In the above-described the general formula (4), E401 to E414 each represent —C(R41)=, and the above-described R41 represents hydrogen atom (H) or a substituent. Ar41 represents a substituted or un-substituted aromatic hydrocarbon ring or a substituted or un-substituted aromatic heterocyclic ring. Furthermore, k41 represents an integer of 3 or more.

In addition, in the general formula (4), when Ar41 represents an aromatic hydrocarbon ring, examples of the aromatic hydrocarbon ring include benzene ring, biphenyl ring, naphthalene ring, azulene ring, anthracene ring, phenanthrene ring, pyrene ring, chrysene ring, naphthacene ring, triphenylene ring, o-terphenyl ring, m-terphenyl ring, p-terphenyl ring, acenaphthene ring, coronene ring, fluorene ring, fluoranthrene ring, naphthacene ring, pentacene ring, perylene ring, pentaphene ring, picene ring, pyrene ring, pyranthrene ring, anthranthrene ring, and the like. These rings may also have a substituent represented by R11, R12 of the general formula (1).

Additionally, in the general formula (4), when Ar41 represents an aromatic heterocyclic ring, examples of the aromatic heterocyclic ring include furan ring, thiophene ring, oxazole ring, pyrrole ring, pyridine ring, pyridazine ring, pyrimidine ring, pyrazine ring, triazine ring, benzimidazole ring, oxadiazole ring, triazole ring, imidazole ring, pyrazole ring, thiazole ring, indole ring, benzimidazole ring, benzothiazole ring, benzoxazole ring, quinoxaline ring, quinazoline ring, phthalazine ring, carbazole ring, azacarbazole ring, and the like. Note that the azacarbazole ring means a ring obtained by substituting one or more of carbon atoms of a benzene ring with a nitrogen atom constituting a carbazole ring. These rings may also have a substituent represented by R11, R12 of the general formula (1).

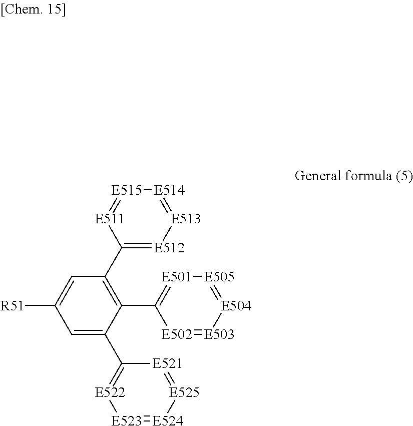

In the above-described general formula (5), R51 represents a substituent, E501, E502, E511 to E515, E521 to E525 each represent —C(R52)= or —N═. E503 to E505 each represent —C(R52)=. R52 represents hydrogen atom (H) or a substituent. At least one of E501 and E502 is —N═, at least one of E511 to E515 is —N═, at least one of E521 to E525 is —N═.

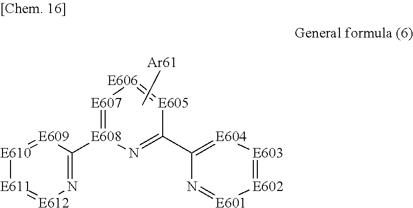

In the above-described general formula (6), E601 to E612 each represent —C(R61)= or —N═, R61 represents hydrogen atom (H) or a substituent. In addition, Ar61 represents a substituted or un-substituted aromatic hydrocarbon ring or a substituted or un-substituted aromatic heterocyclic ring.

In addition, in the general formula (6), the substituted or un-substituted aromatic hydrocarbon ring or substituted or un-substituted aromatic heterocyclic ring represented by Ar61 is the same as that in Ar41 of the general formula (4).

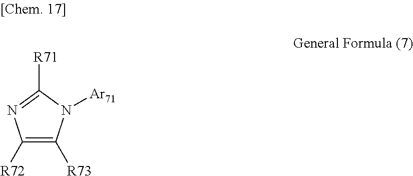

R71 to R73 in the above general formula (7) each represent a hydrogen atom (H) or a substituent, Ar71 represents an aromatic hydrocarbon ring group or an aromatic heterocyclic group.

Additionally, examples of the aromatic hydrocarbon ring group or an aromatic heterocyclic group represented by Ar71 in the above general formula (7) include the same as those of Ar41 of the general formula (4).

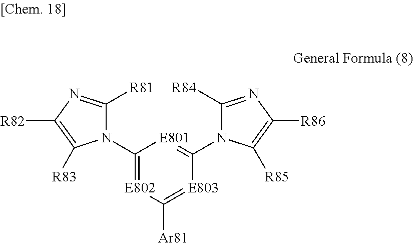

The above general formula (8) is also one form of the general formula (7). R81 to R86 in the above general formula (8) each represents a hydrogen atom (H) or a substituent. E801 to E803 each represents —C(R87)= or —N═, and R87 represents a hydrogen atom (H) or a substituent. Ar81 represents an aromatic hydrocarbon ring group or an aromatic heterocyclic group.

In addition, examples of the aromatic hydrocarbon ring group or an aromatic heterocyclic group represented by Ar81 in the above general formula (8) include the same as those of Ar41 of the general formula (4).

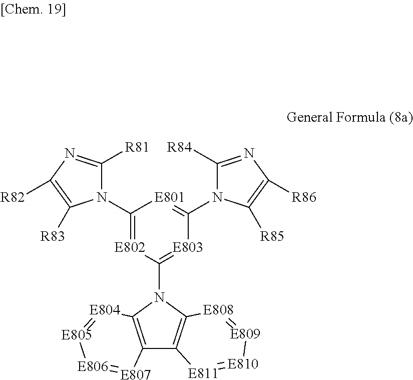

The above general formula (8a) is also one form of the nitrogen-containing compound represented by the general formula (8), Ar81 in the above general formula (8) is a carbazole derivative. E804 to E811 in the above general formula (8a) each represents —C(R88)= or —N═, and R88 represents a hydrogen atom (H) or a substituent. At least one of E808 to E811 is —N═, and E804 to E807, E808 to E811 may bond each other to form a new ring.

[Compound-3]

In addition, as the other compound constituting the nitrogen-containing layer 12, there are compounds 1 to 166 specifically exemplified in the followings, other than the above compounds represented by the general formulae (1) to (8a). These compounds are compounds containing a nitrogen atom which interacts with silver constituting the transparent electrode 13. Additionally, these compounds are materials having electron transport property or electron injection property. Accordingly, the nitrogen-containing layer 12 constituted using such a compound is suitable as the organic EL element 10, and the nitrogen-containing layer 12 can be used as an electron transport layer or an electron injection layer in the organic EL element. Note that, among these compounds 1 to 166, a compound which falls within the above-described range of the effective unshared electron pair content [n/M] is included, and such a compound can be used alone as the compound constituting the nitrogen-containing layer 12. Furthermore, in the compounds 1 to 166, there are compounds which are applicable to the above-described general formulae (1) to (8a).

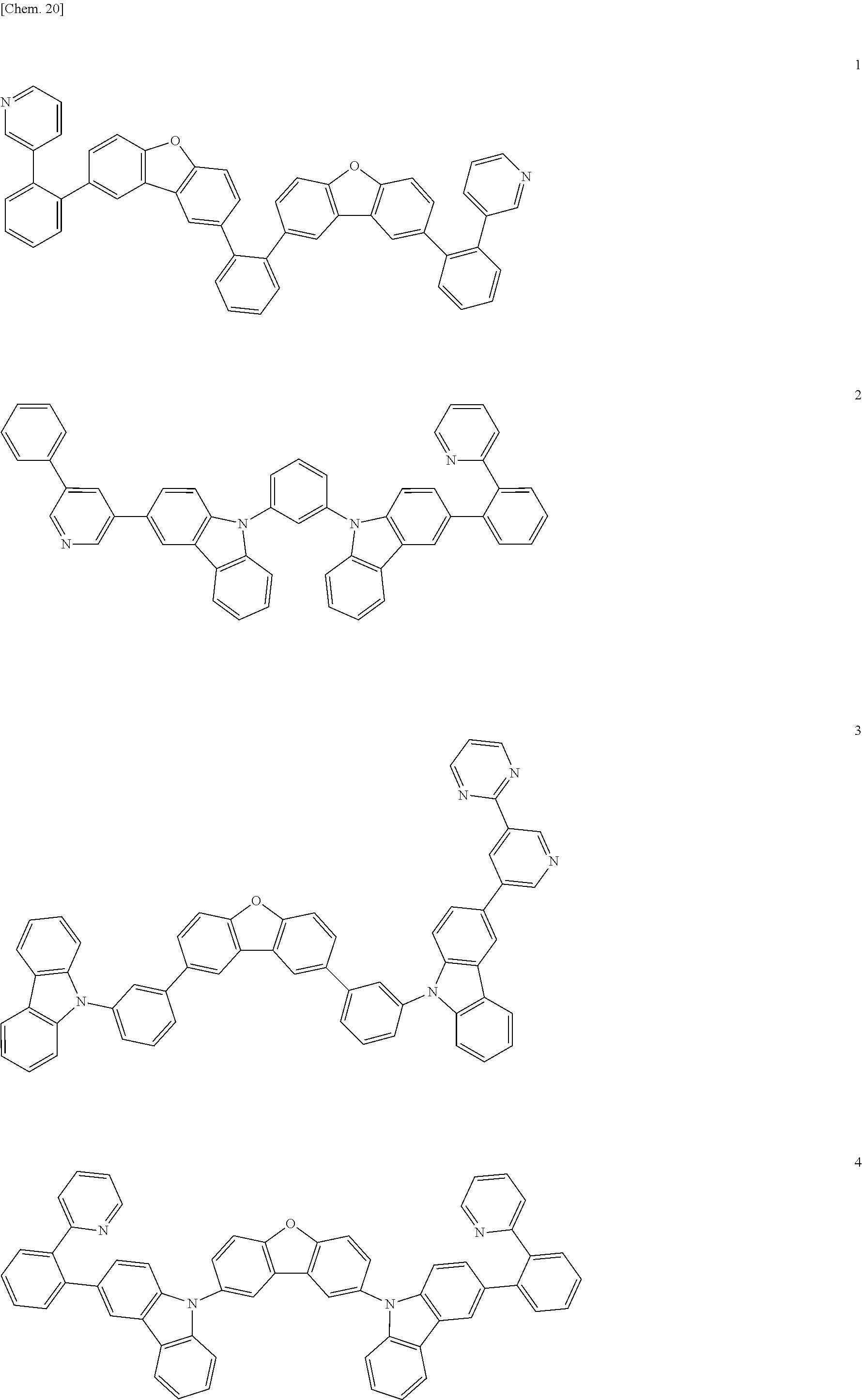

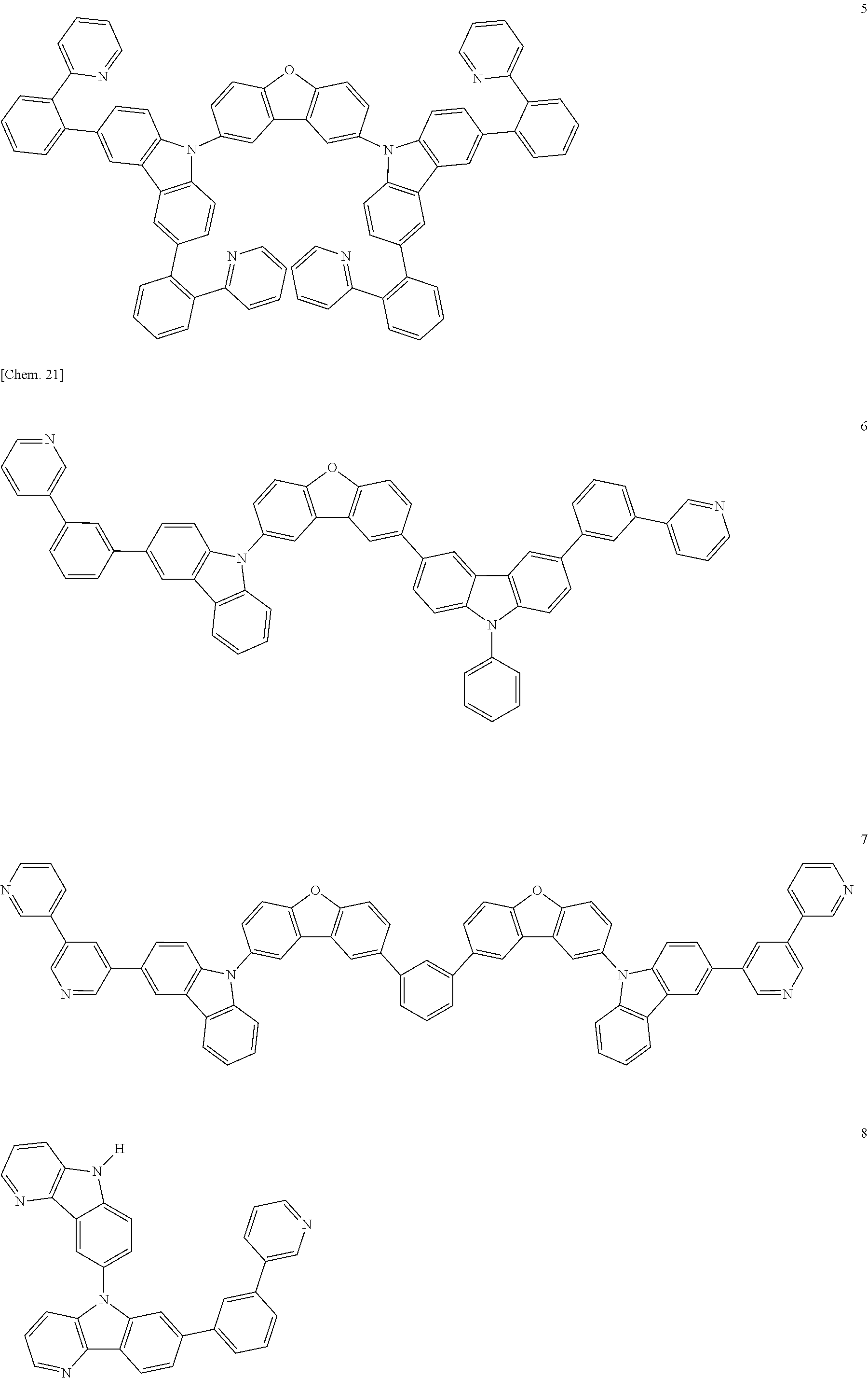

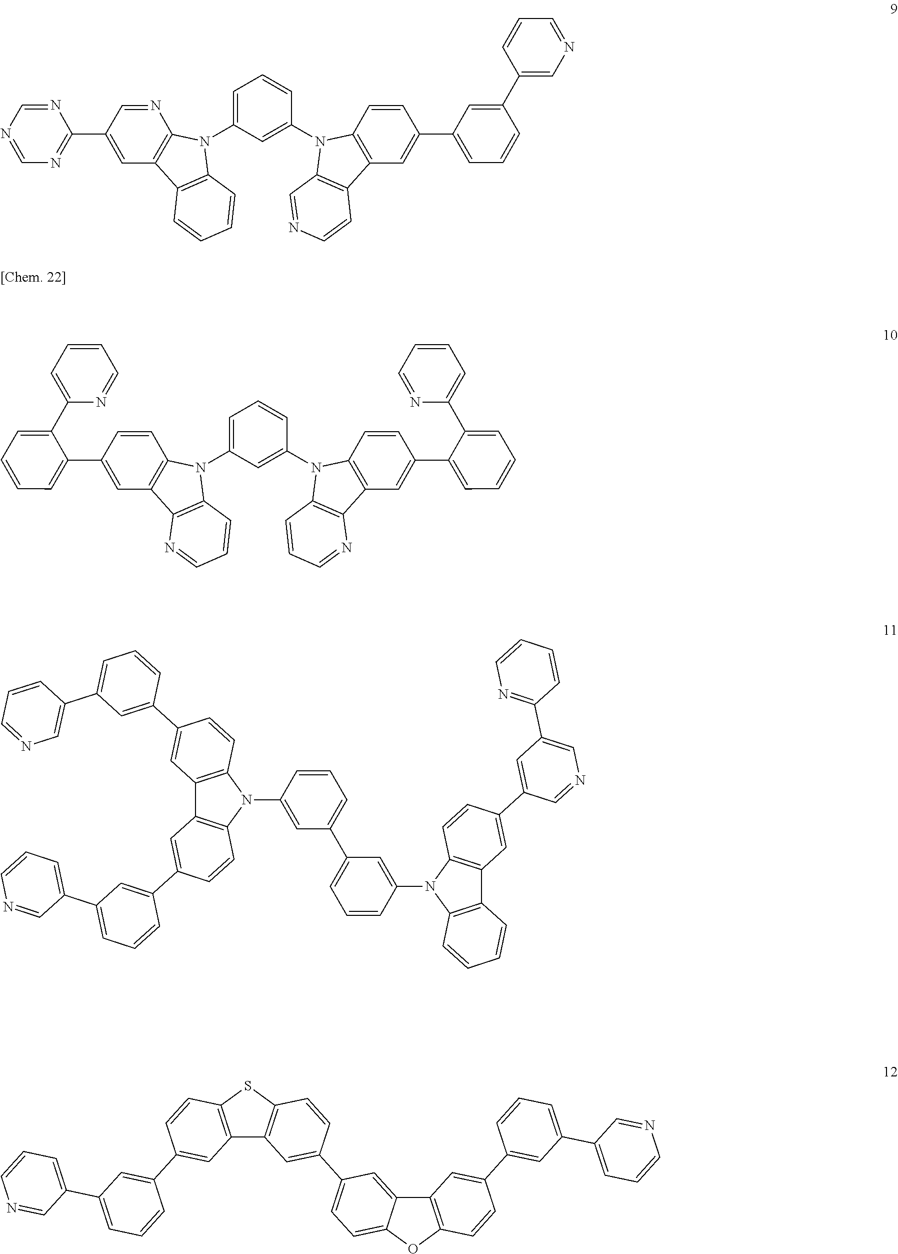

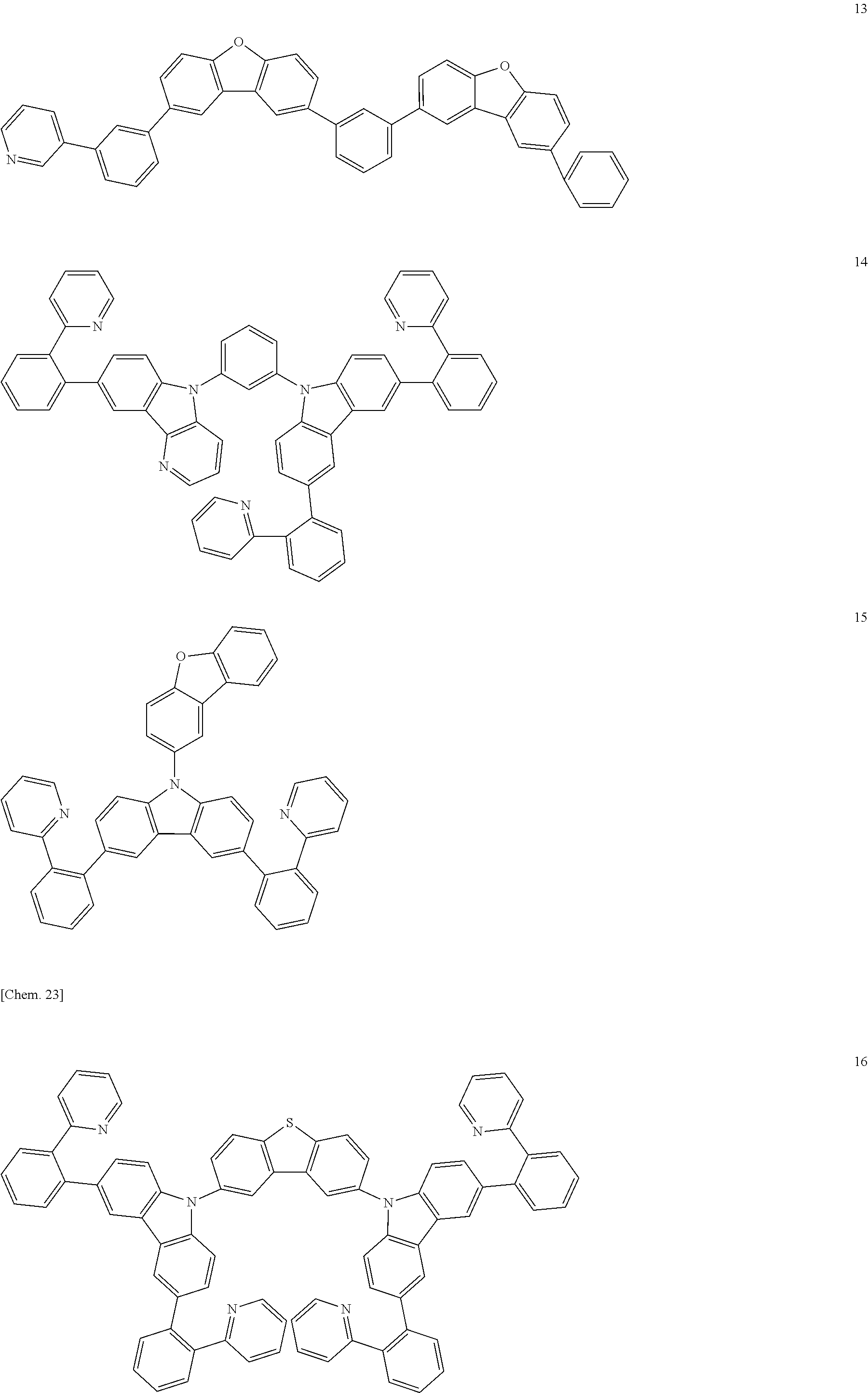

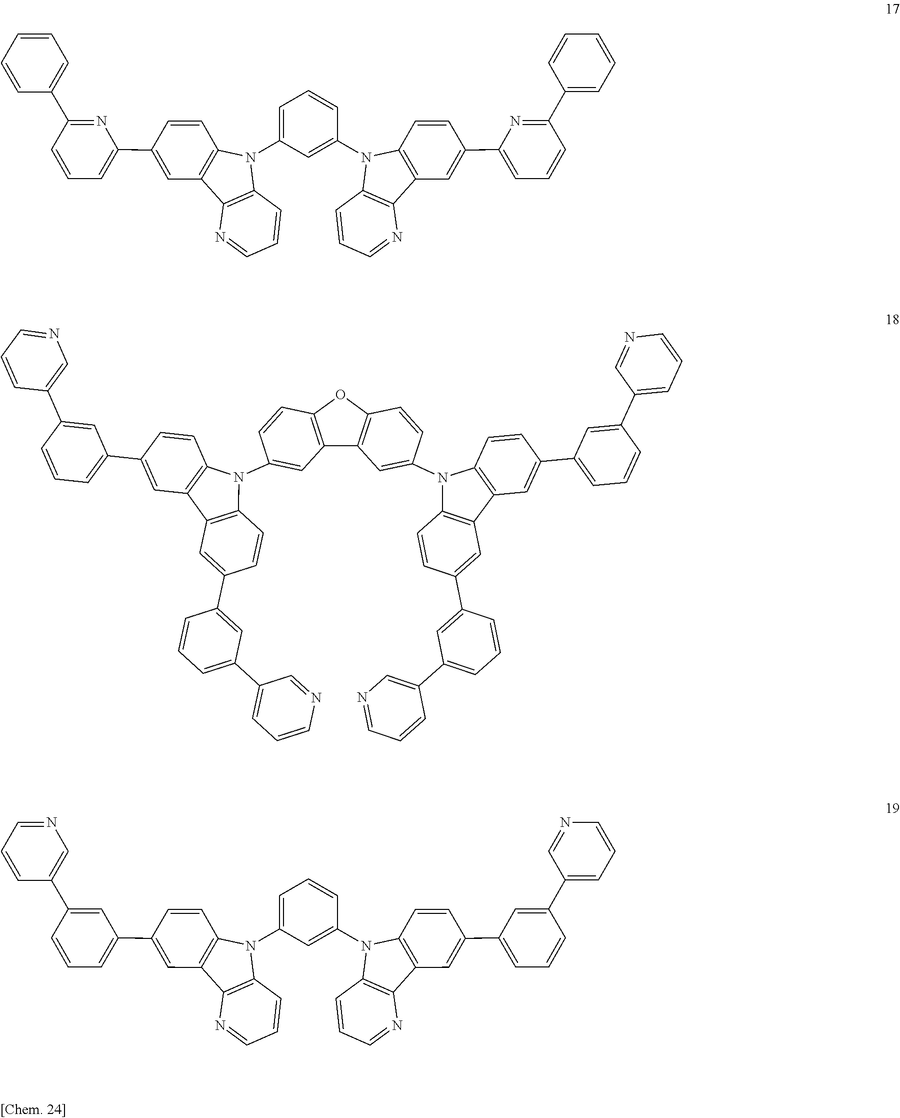

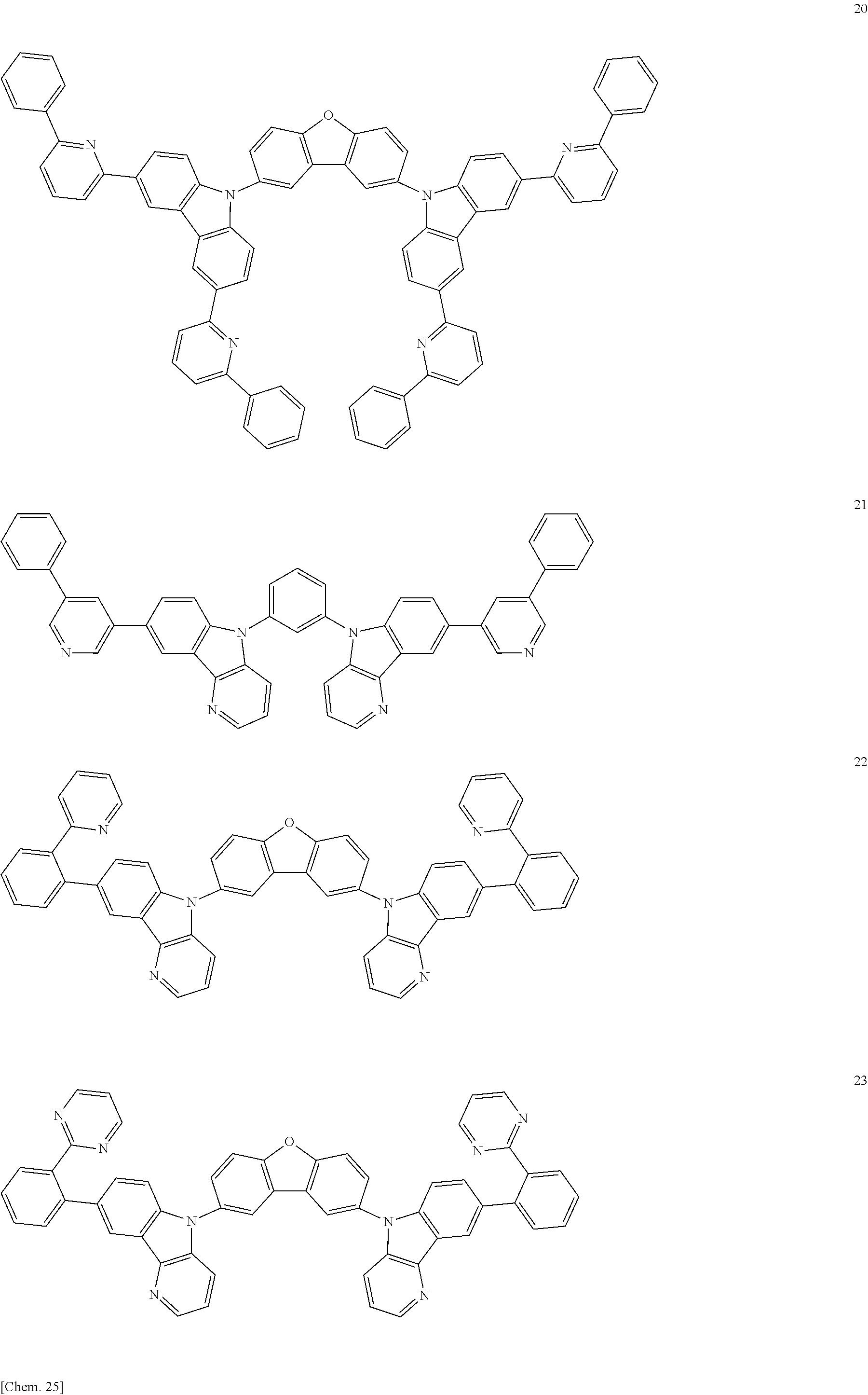

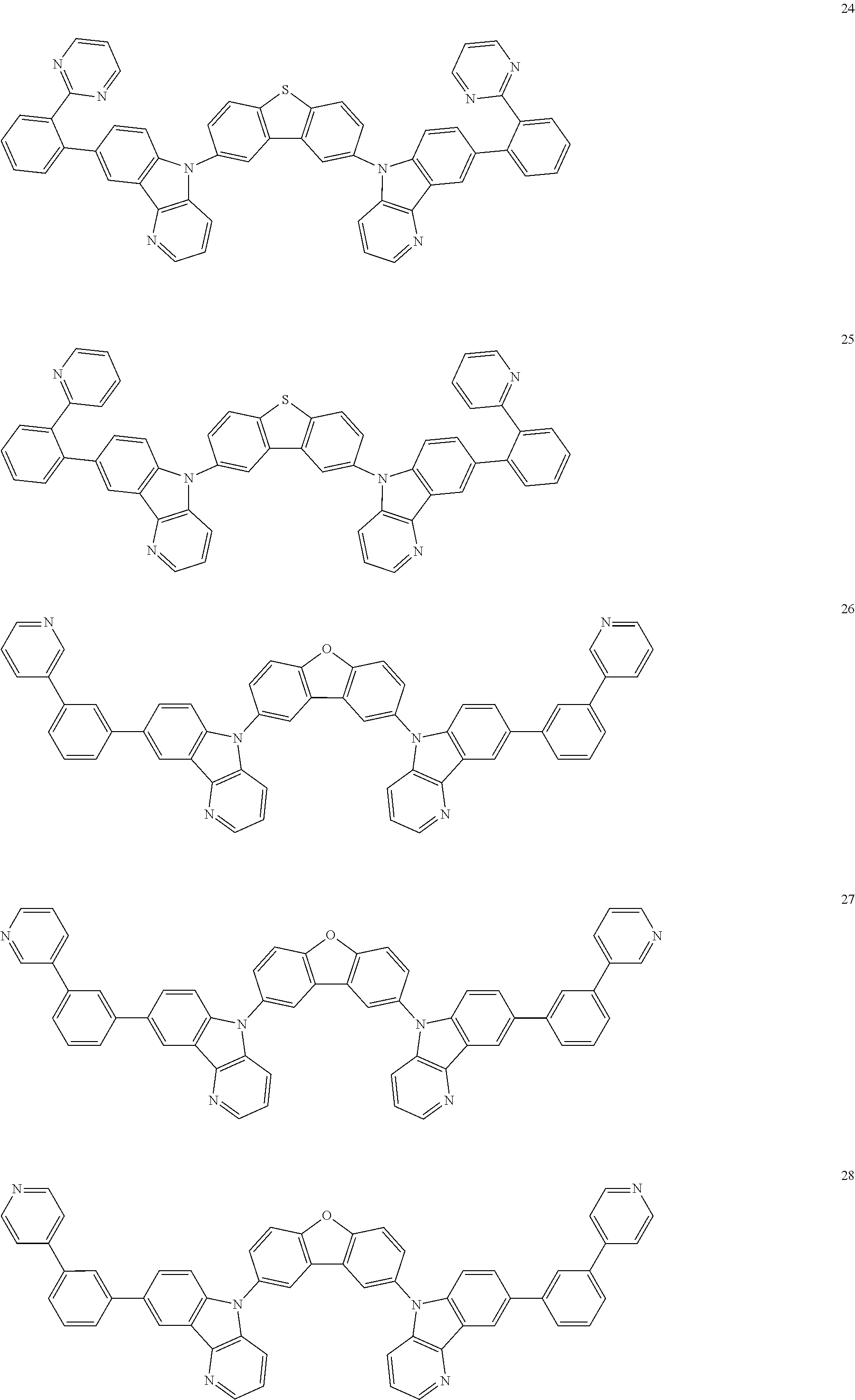

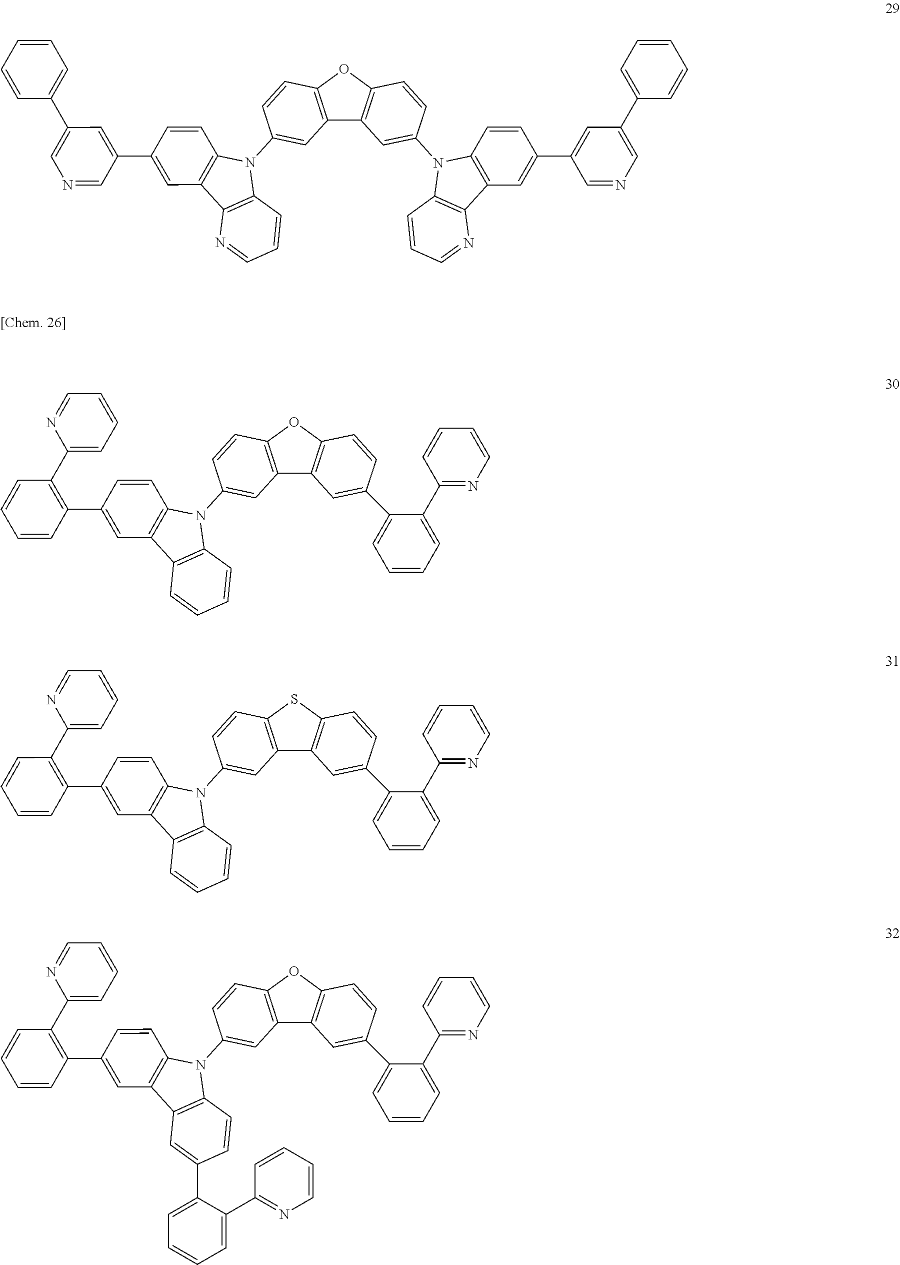

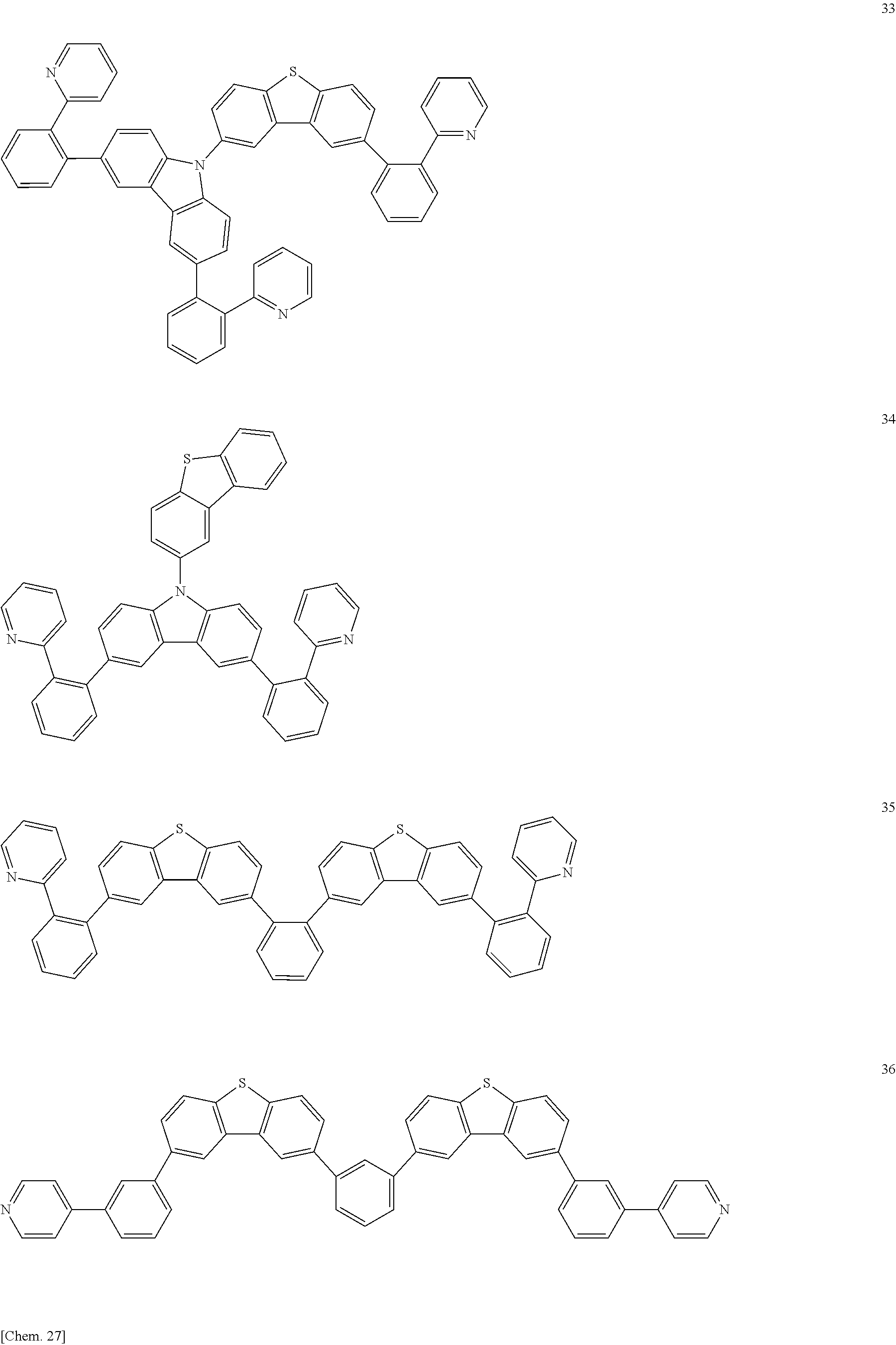

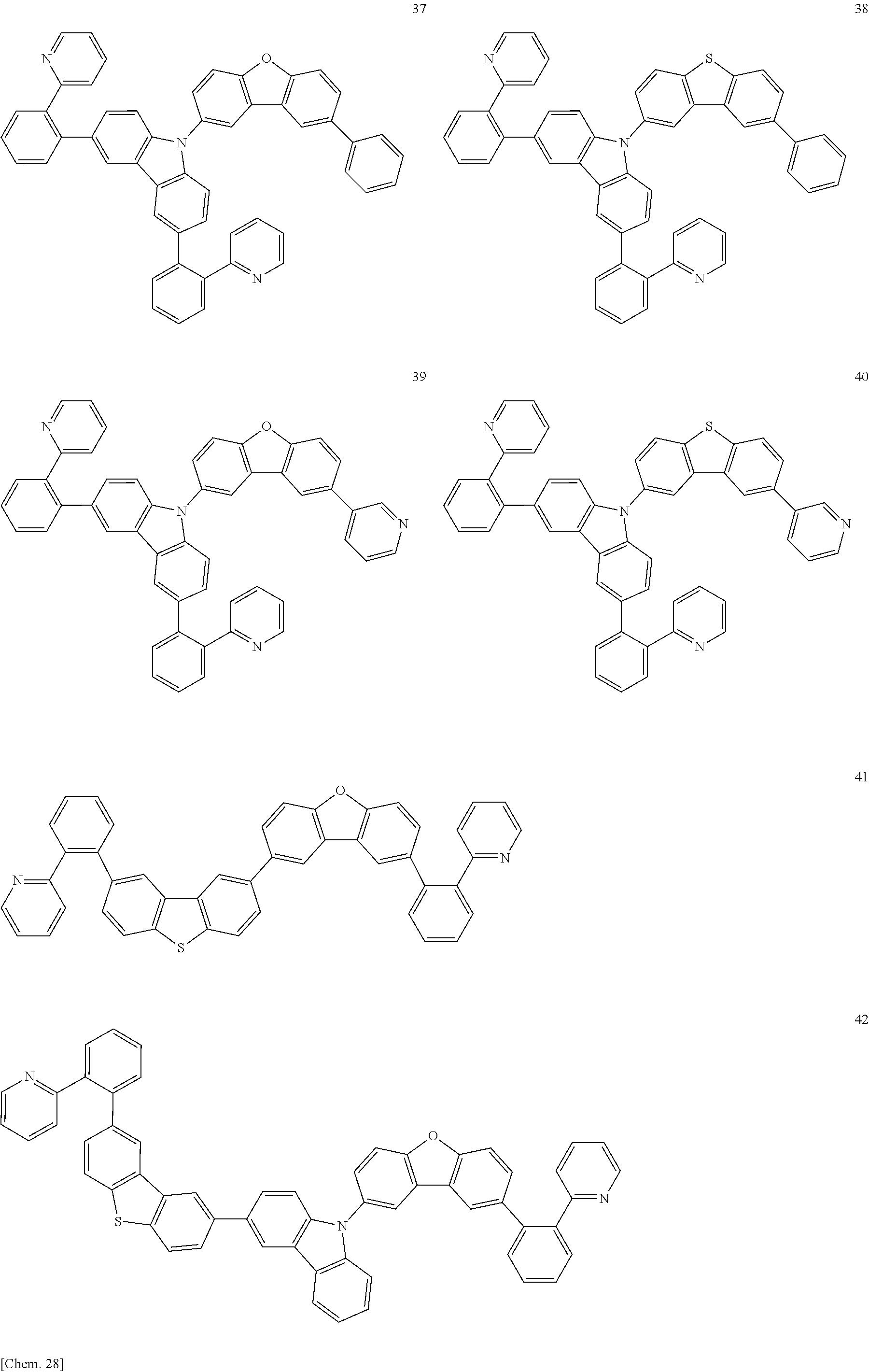

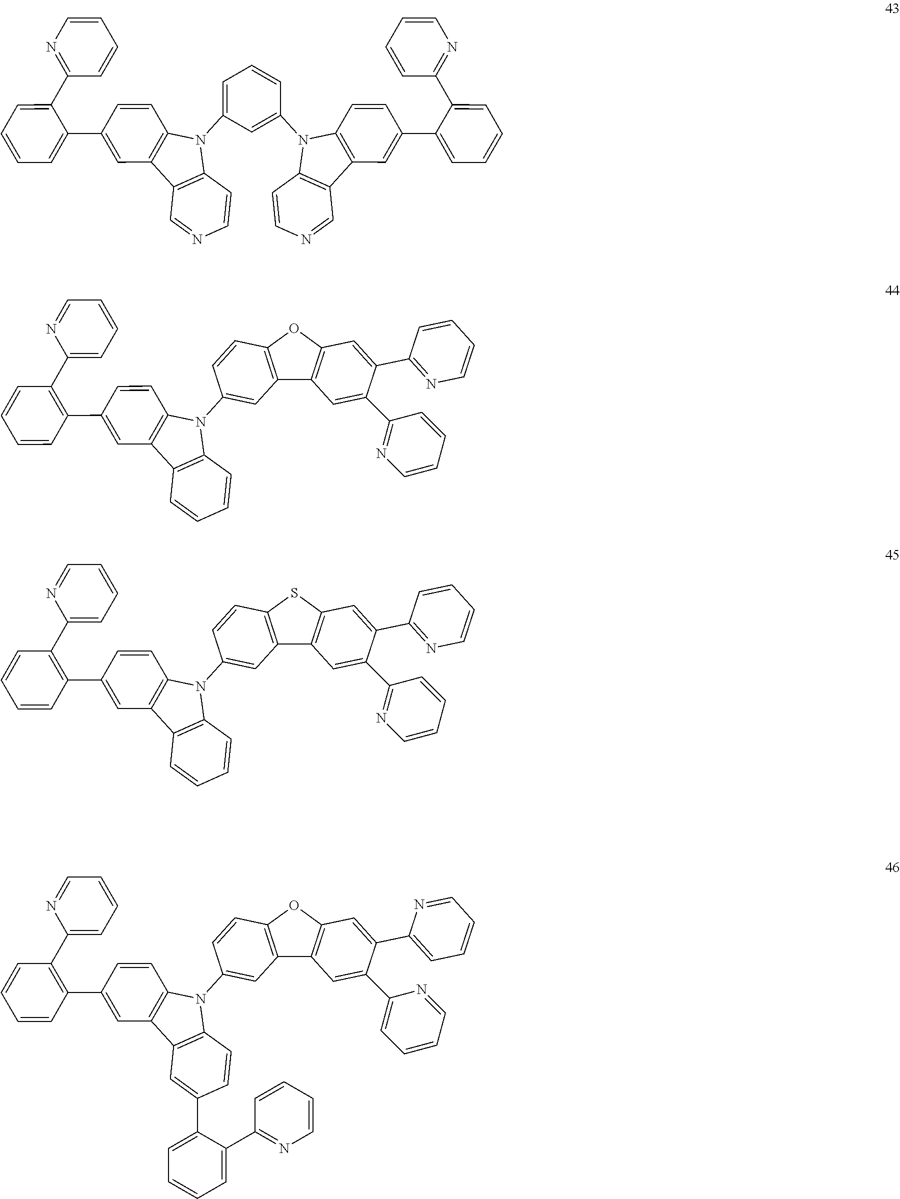

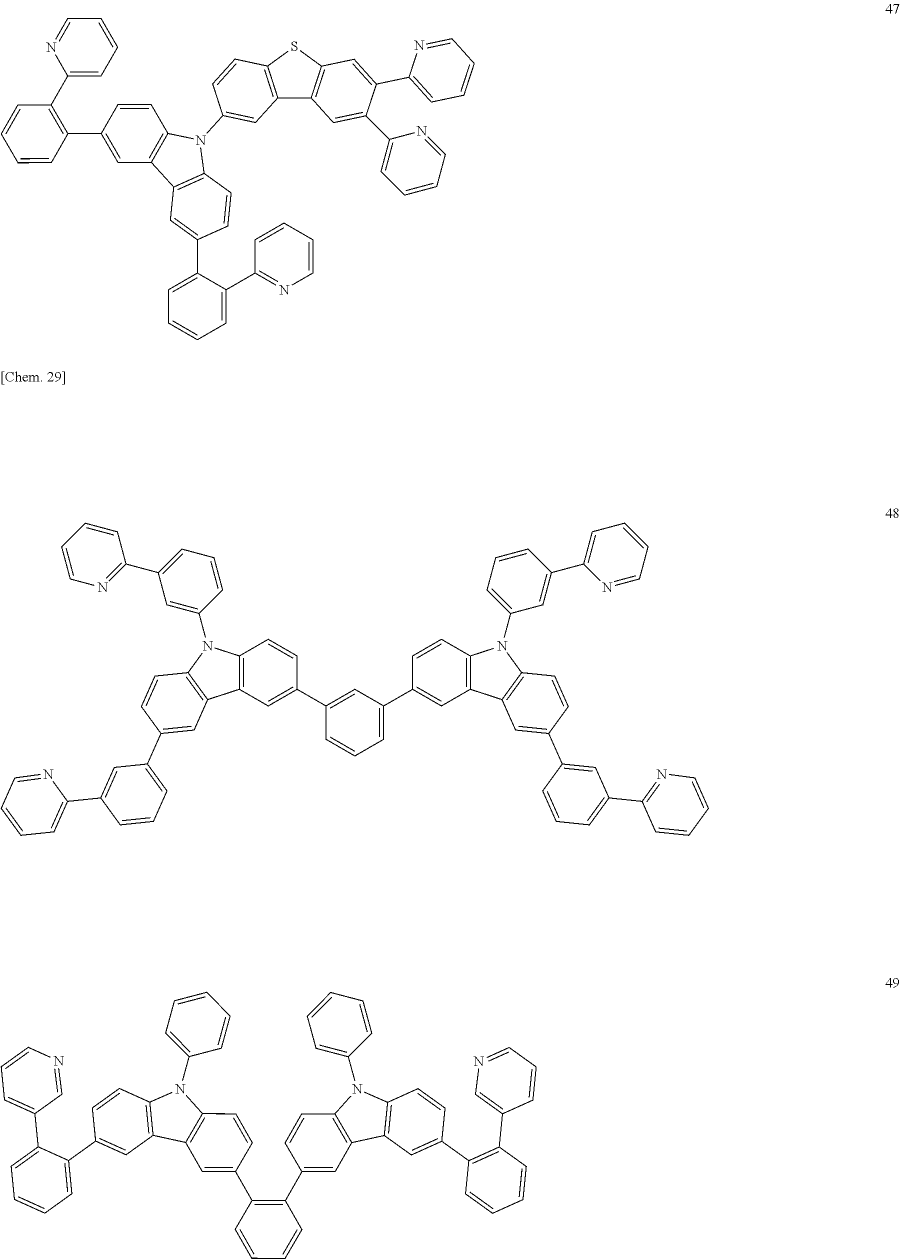

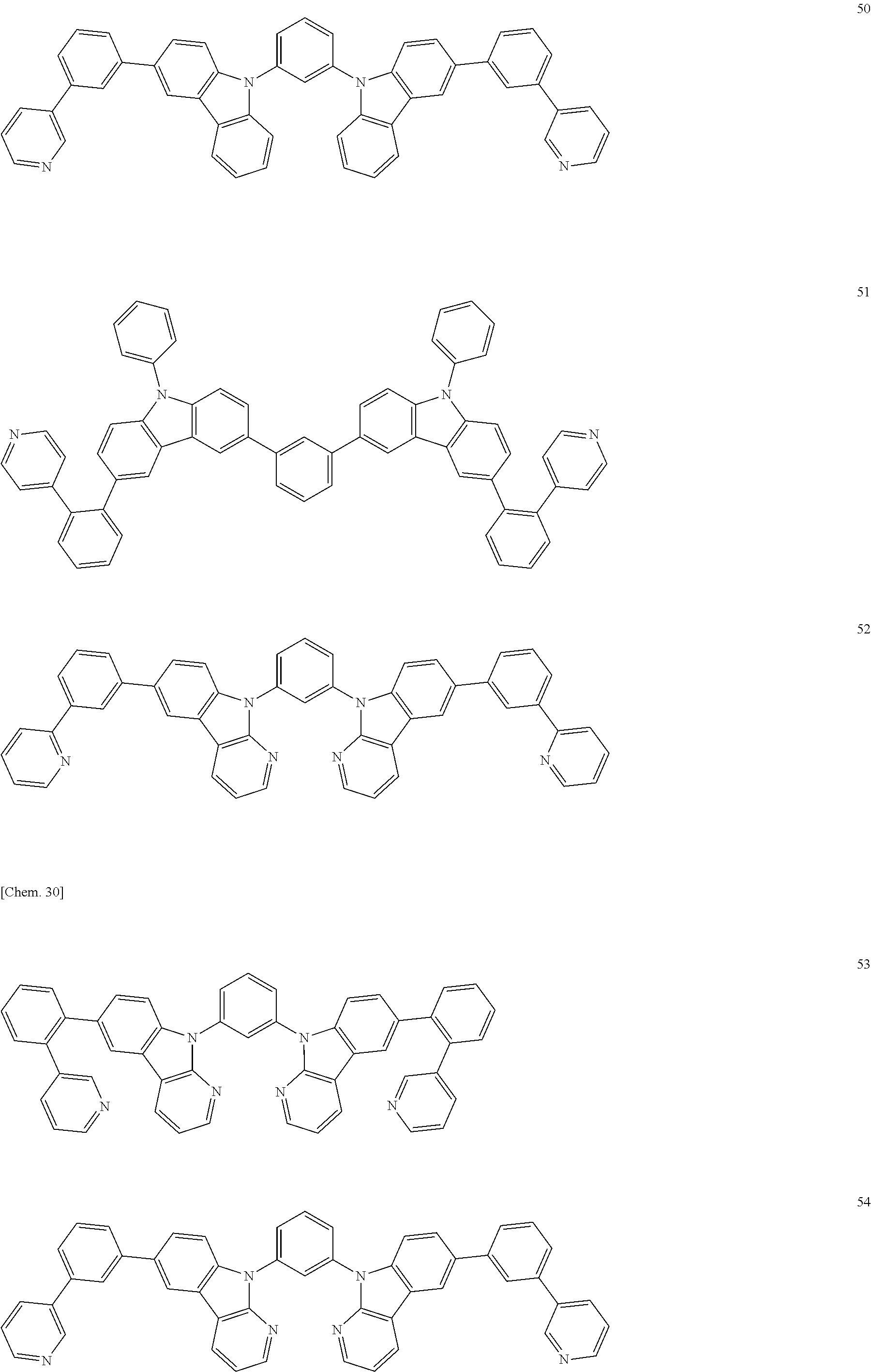

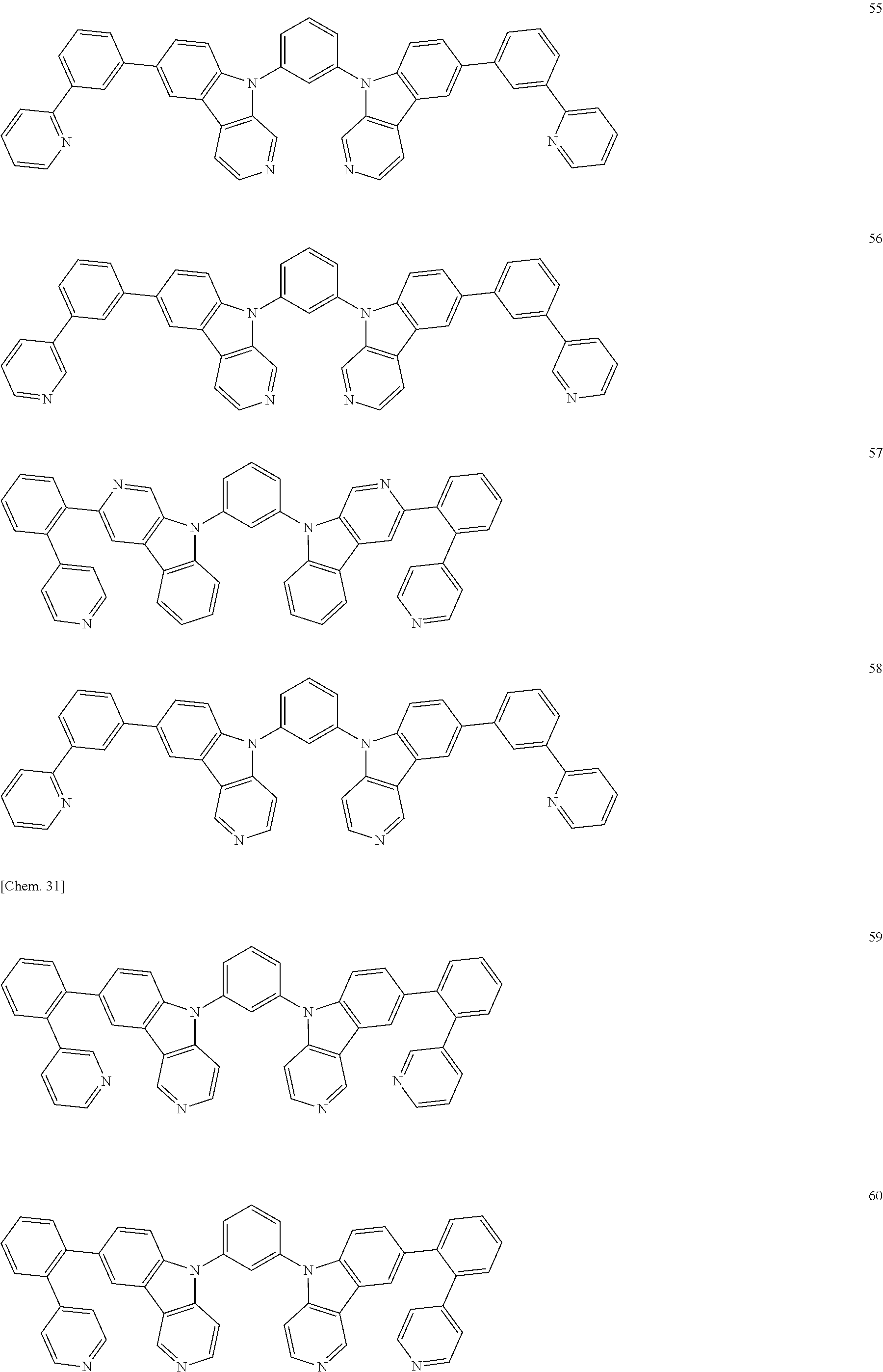

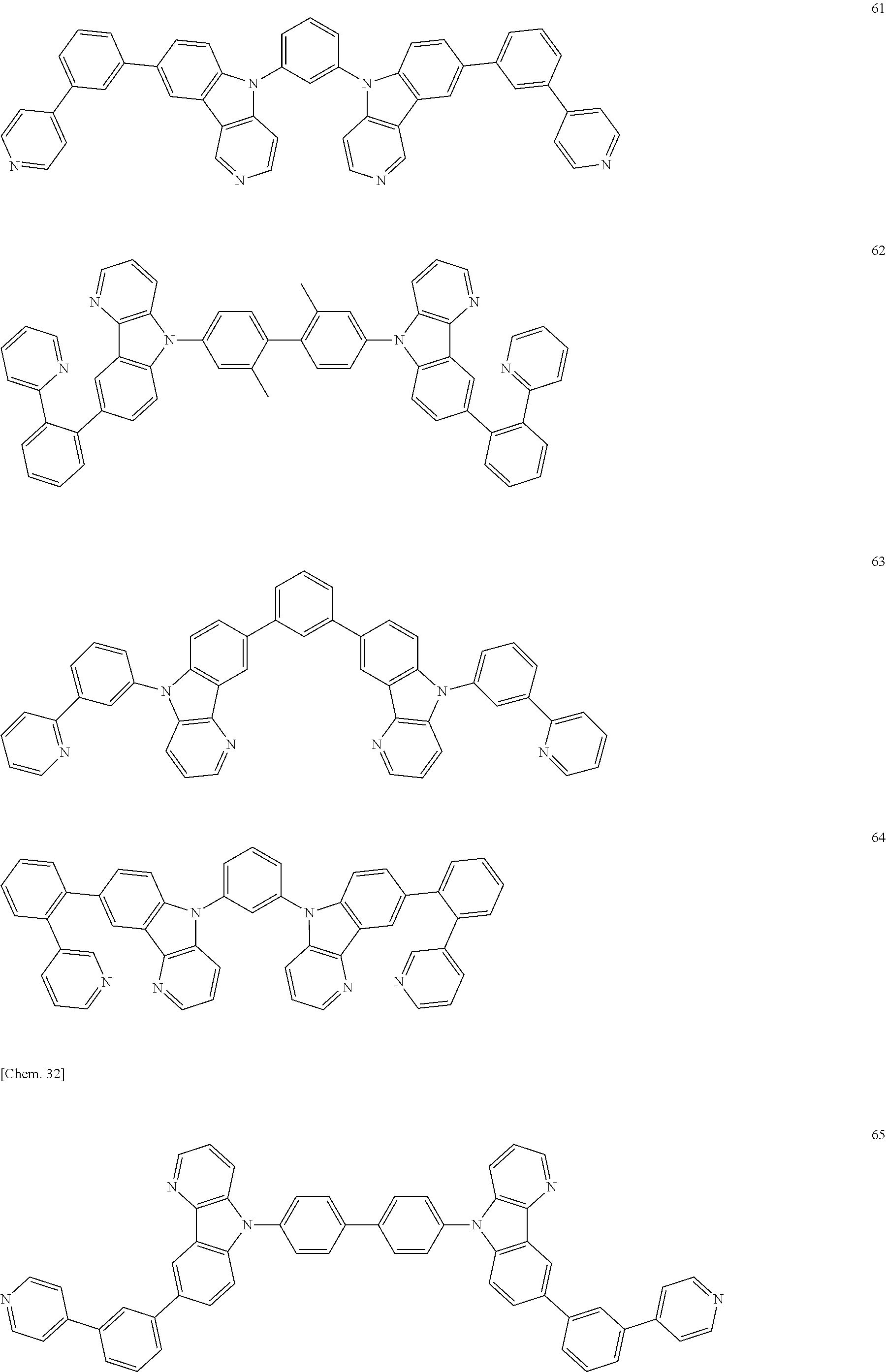

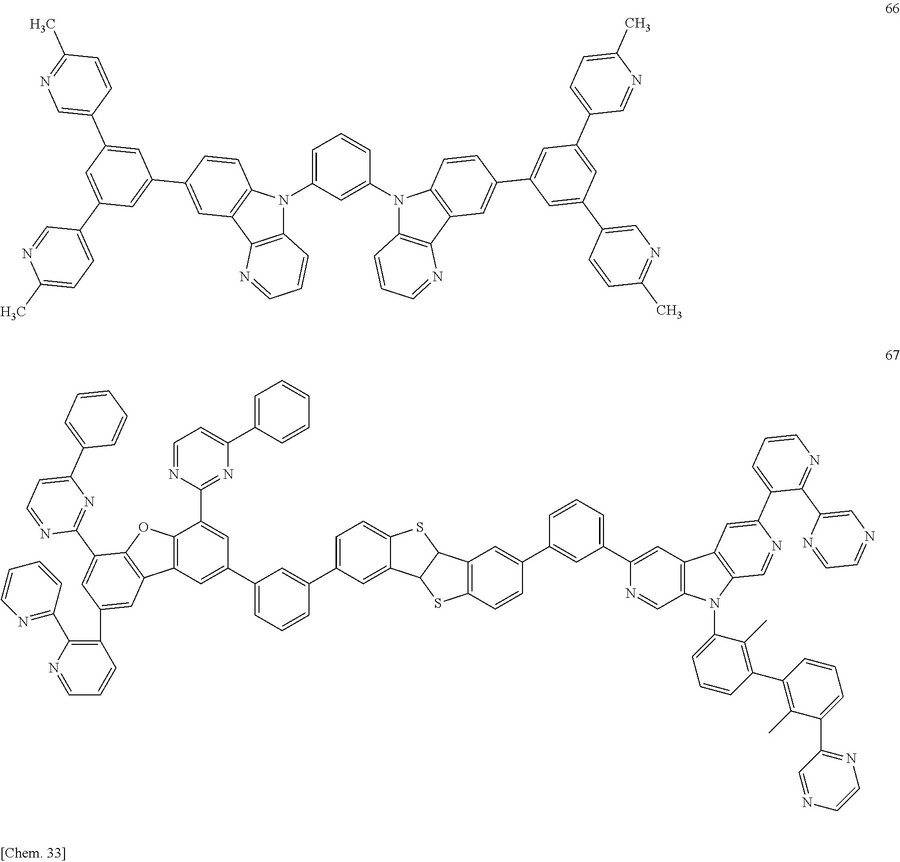

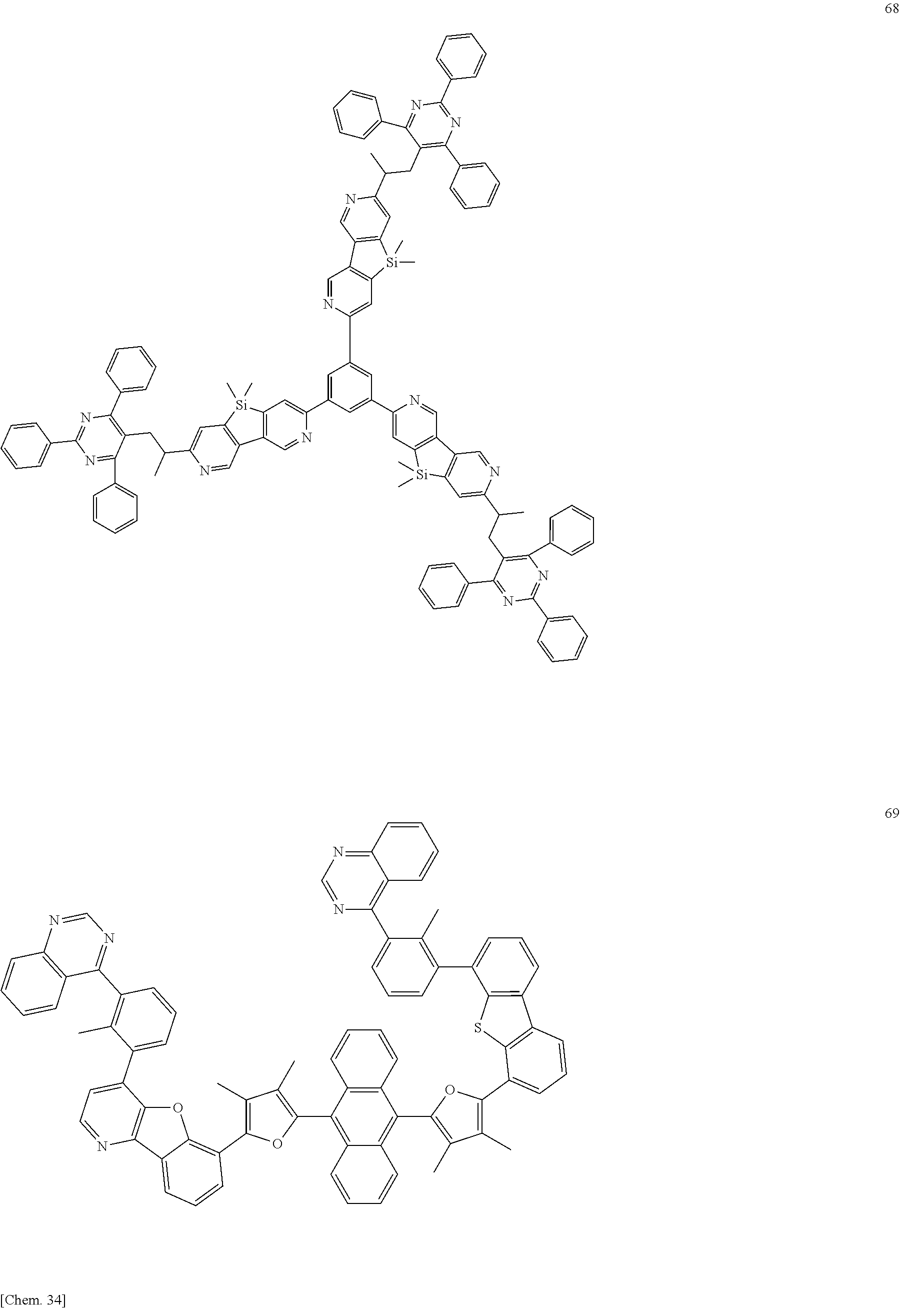

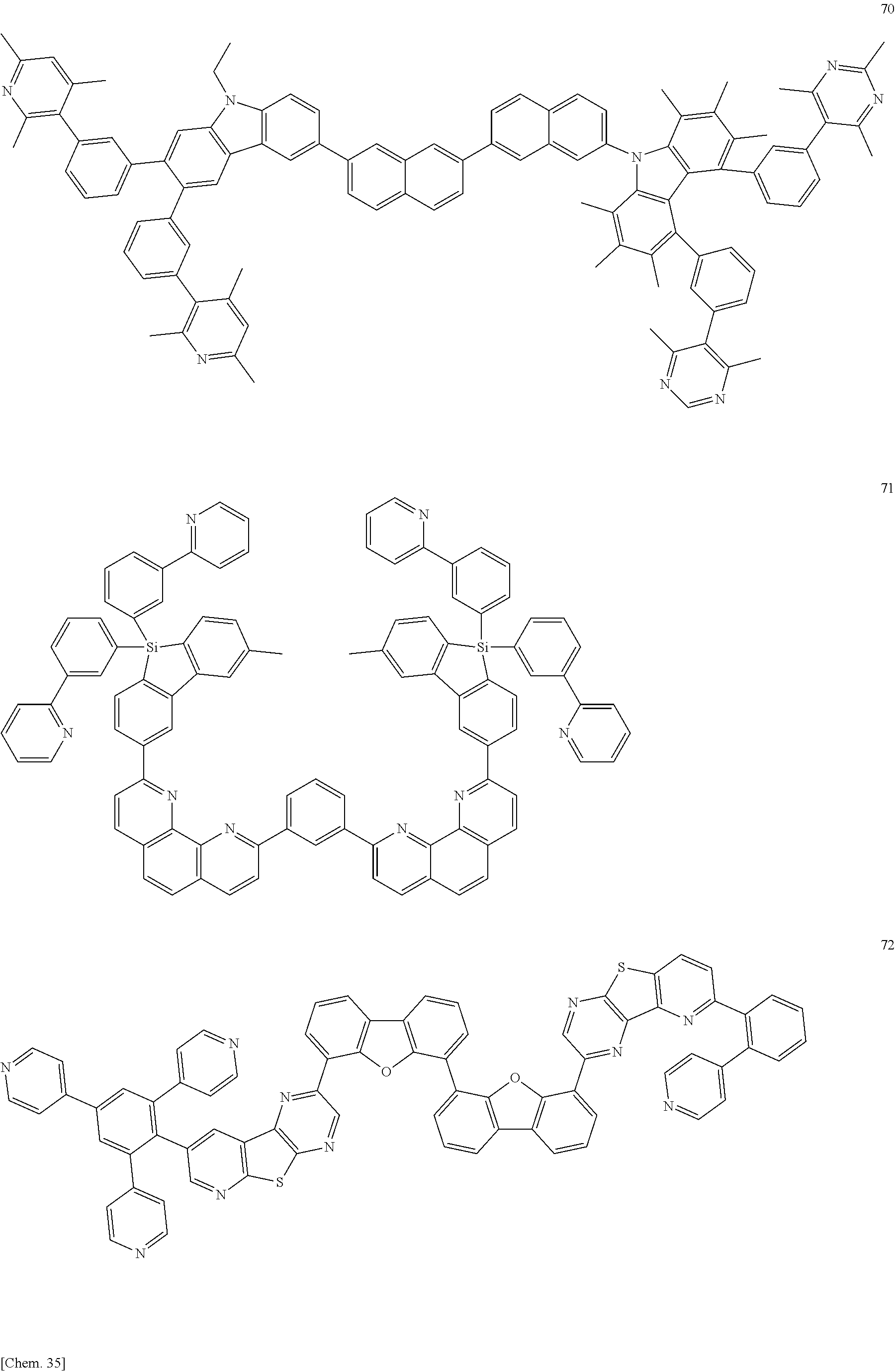

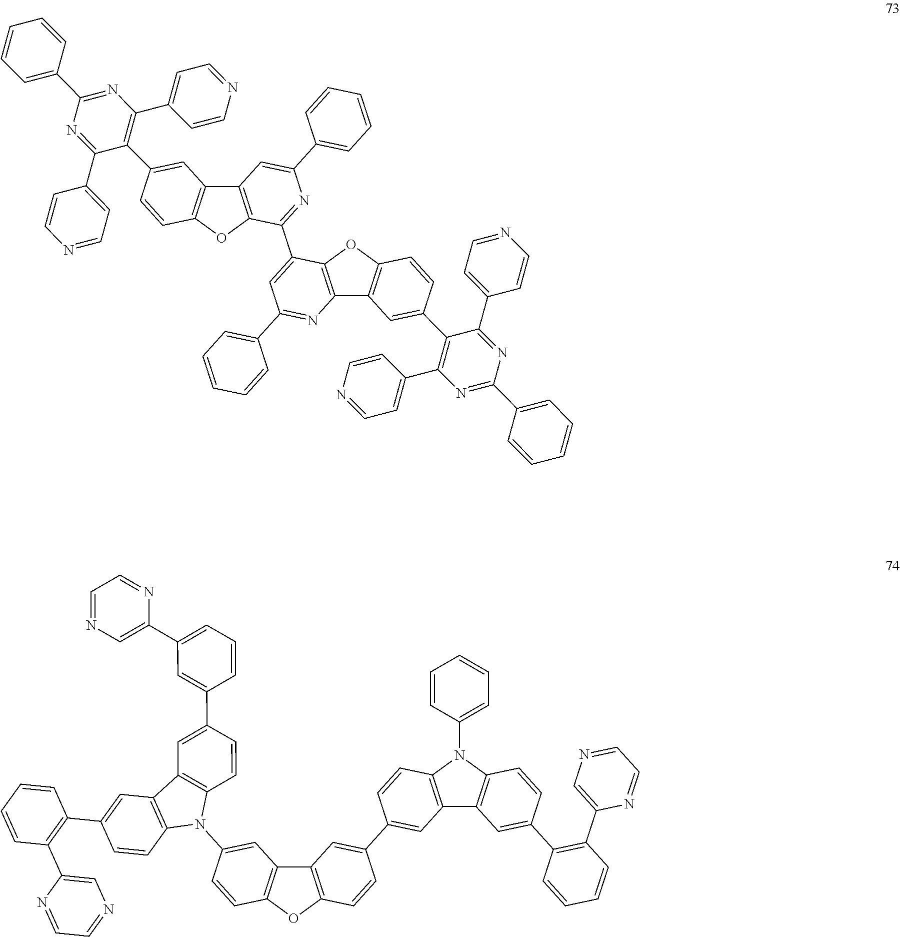

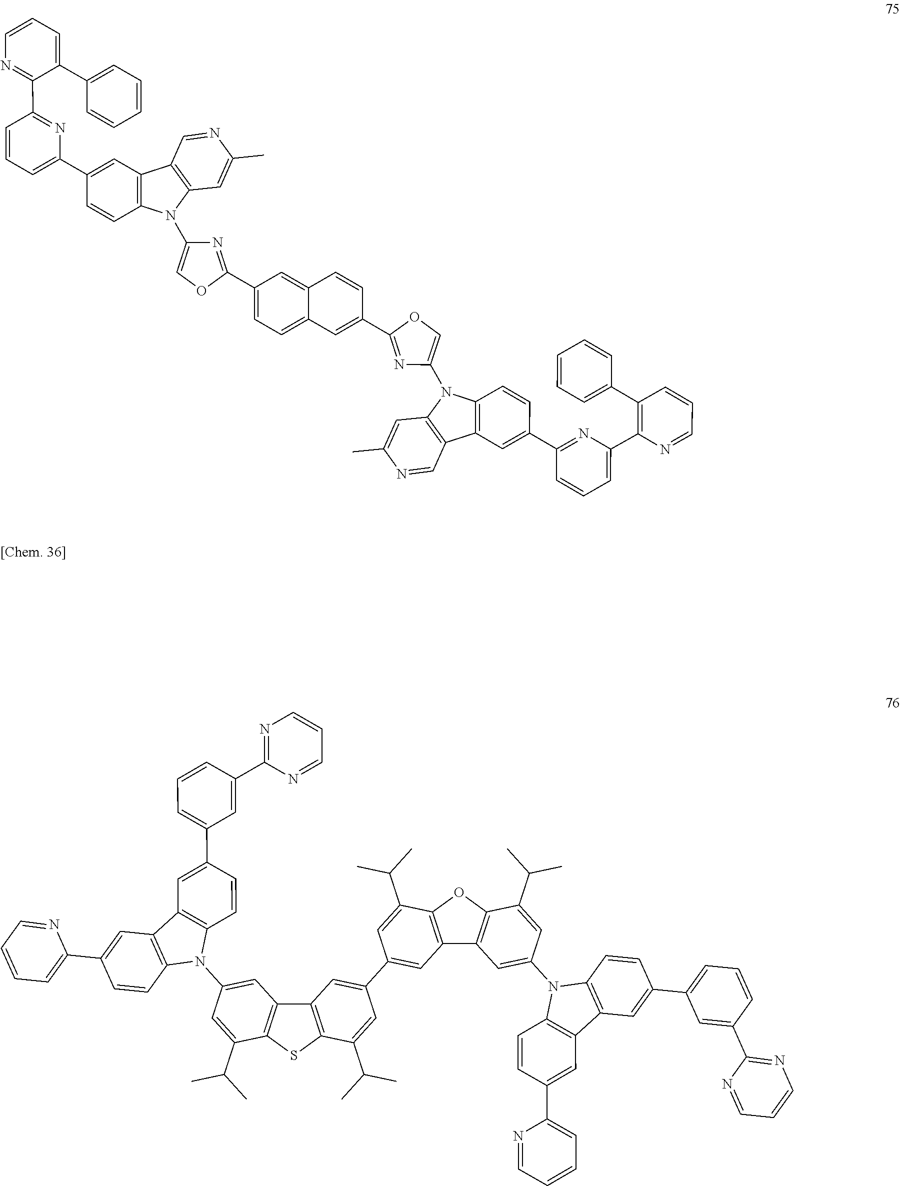

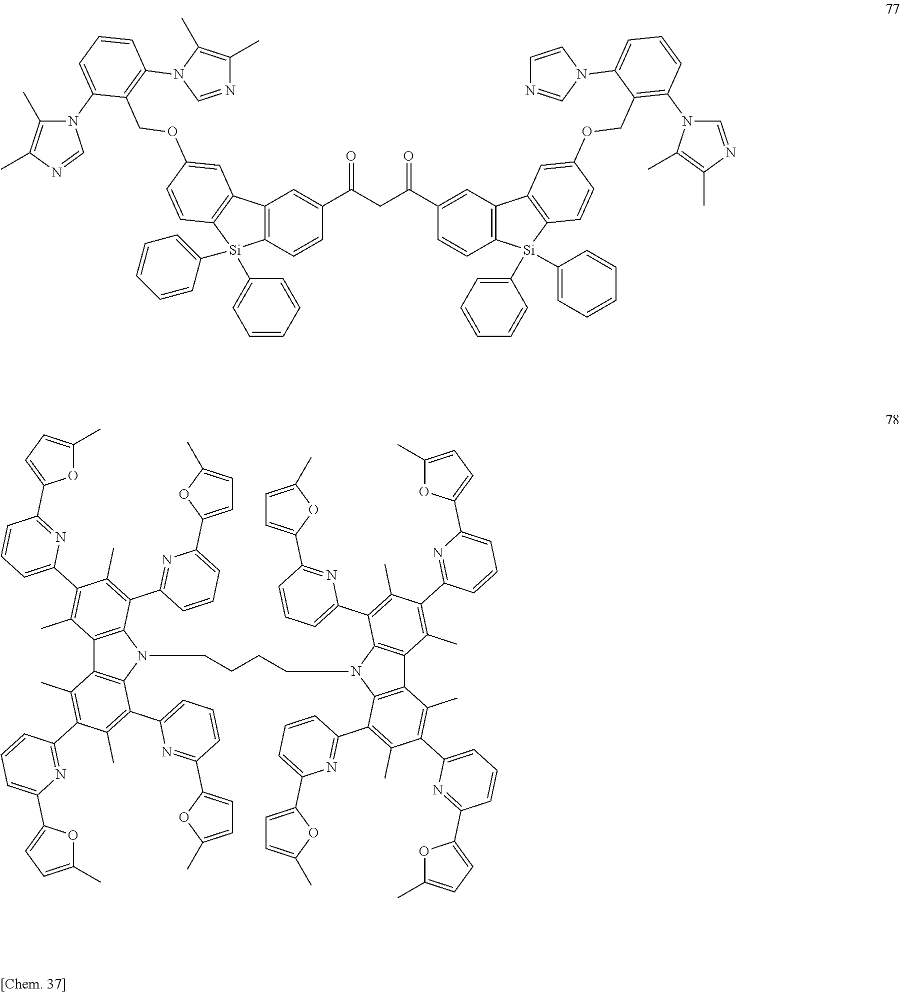

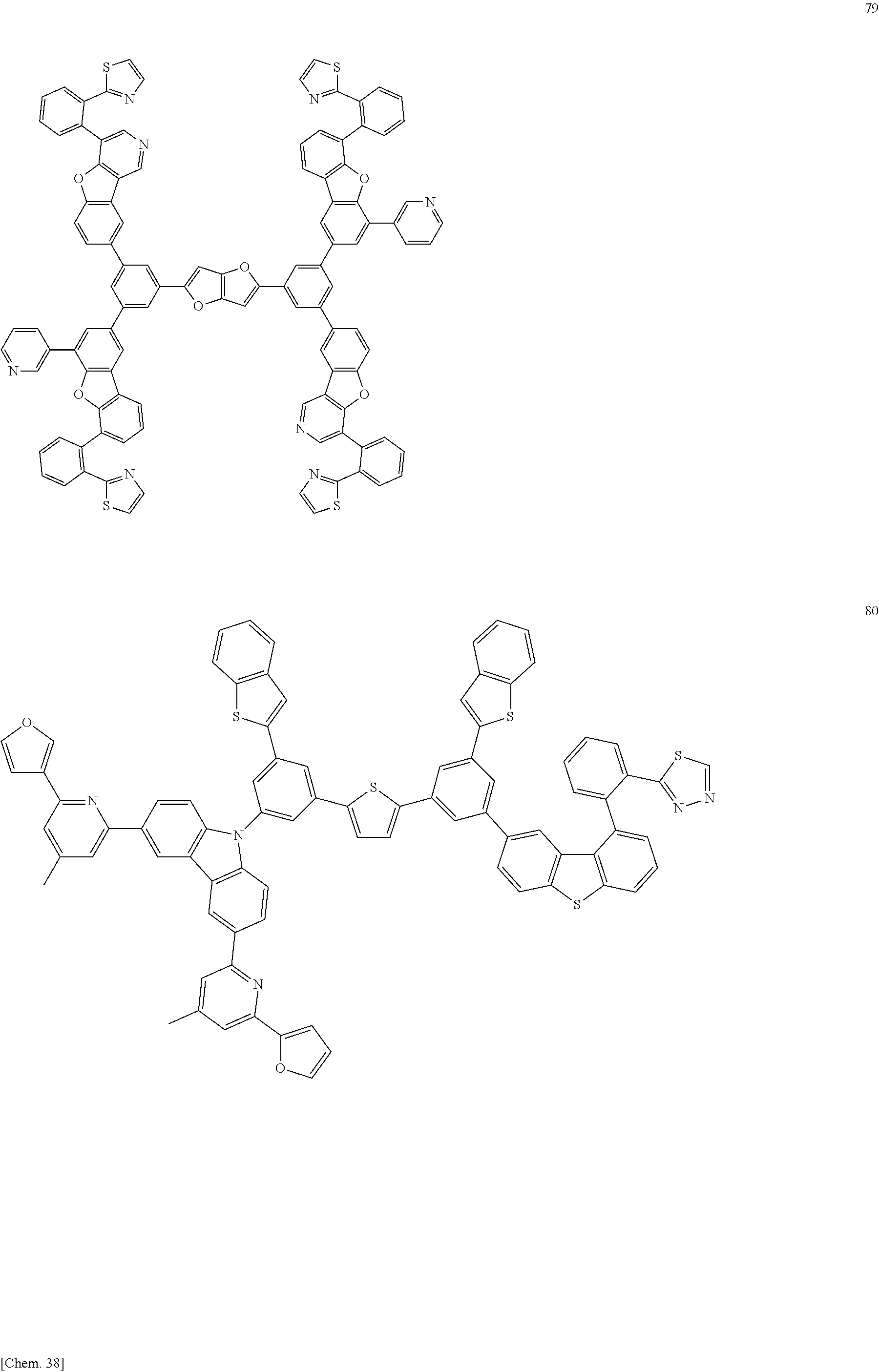

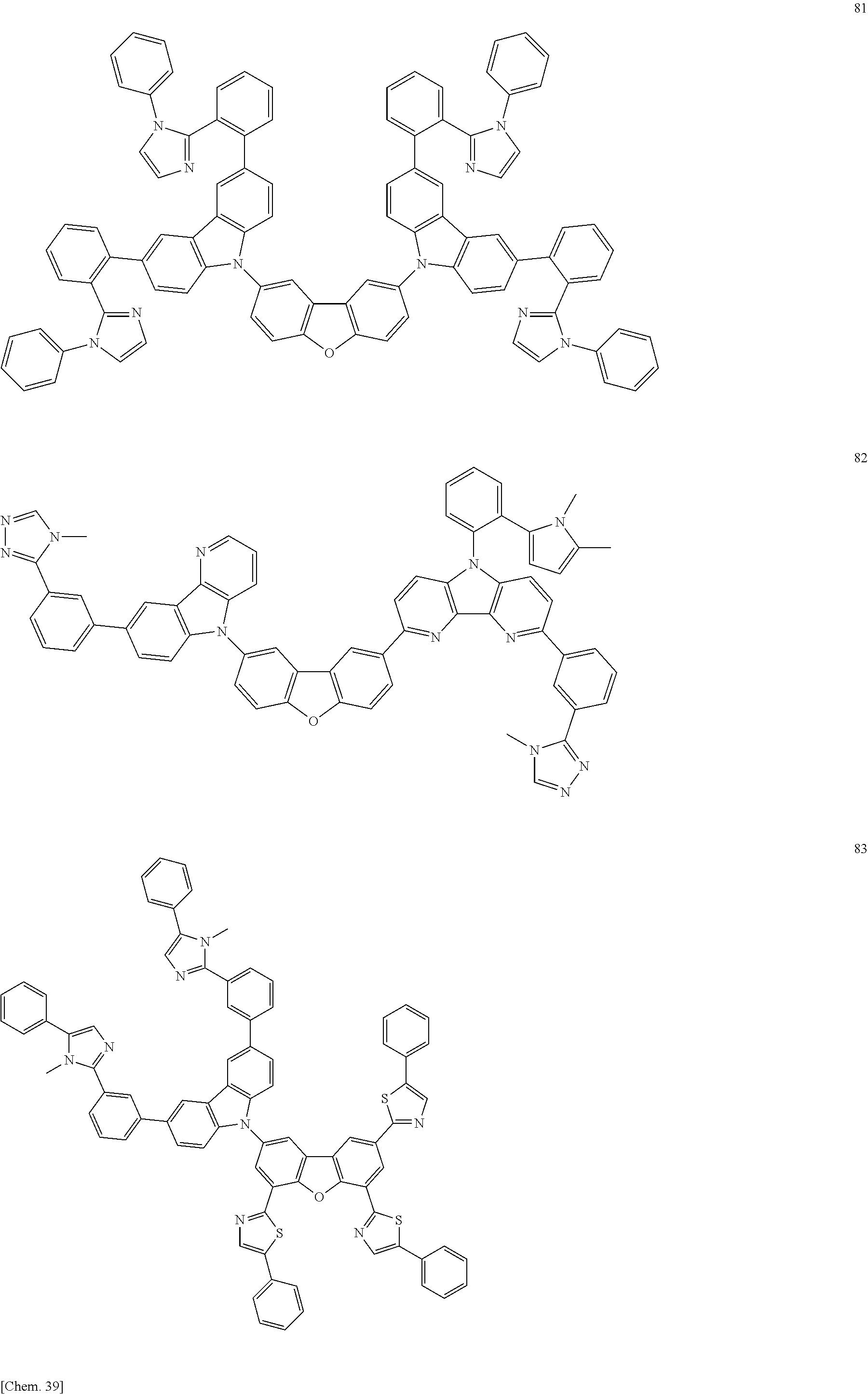

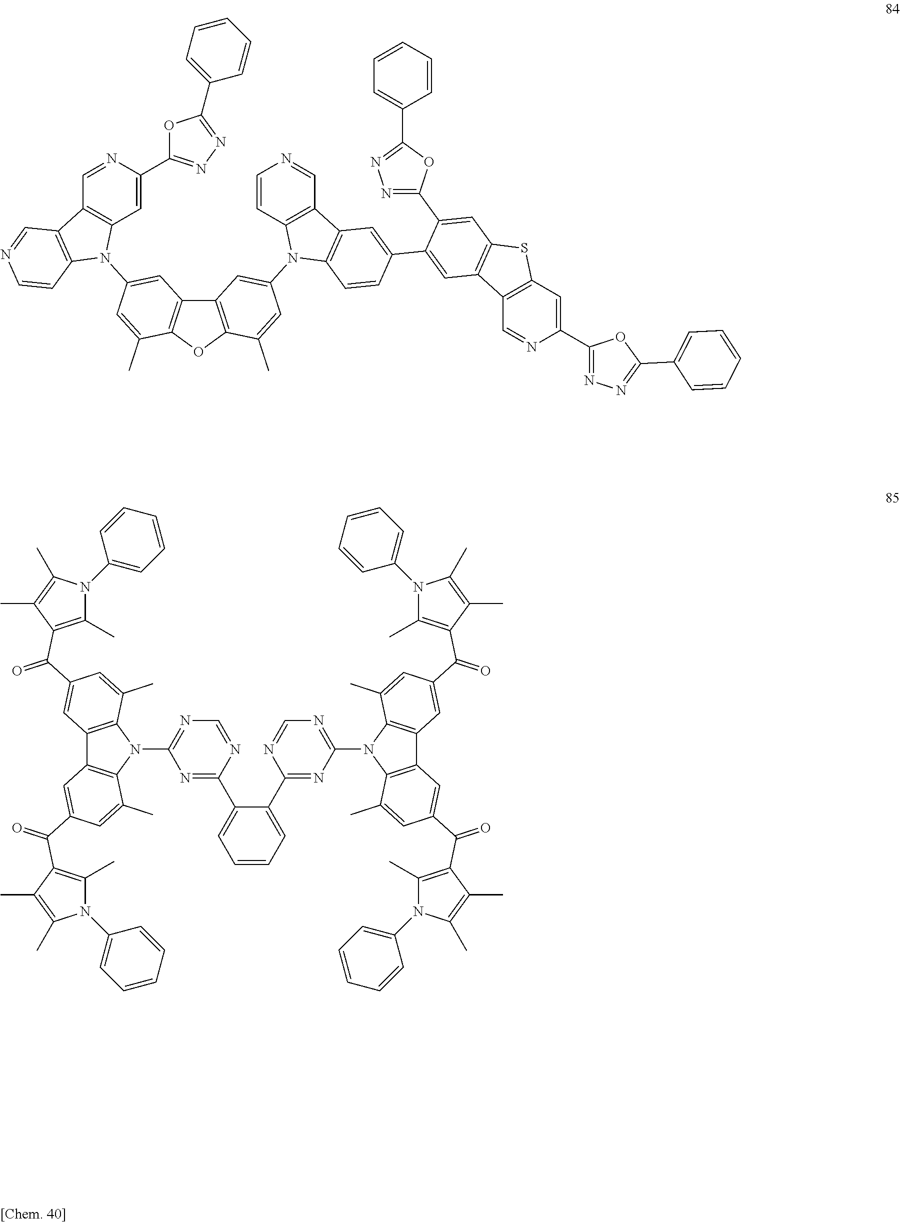

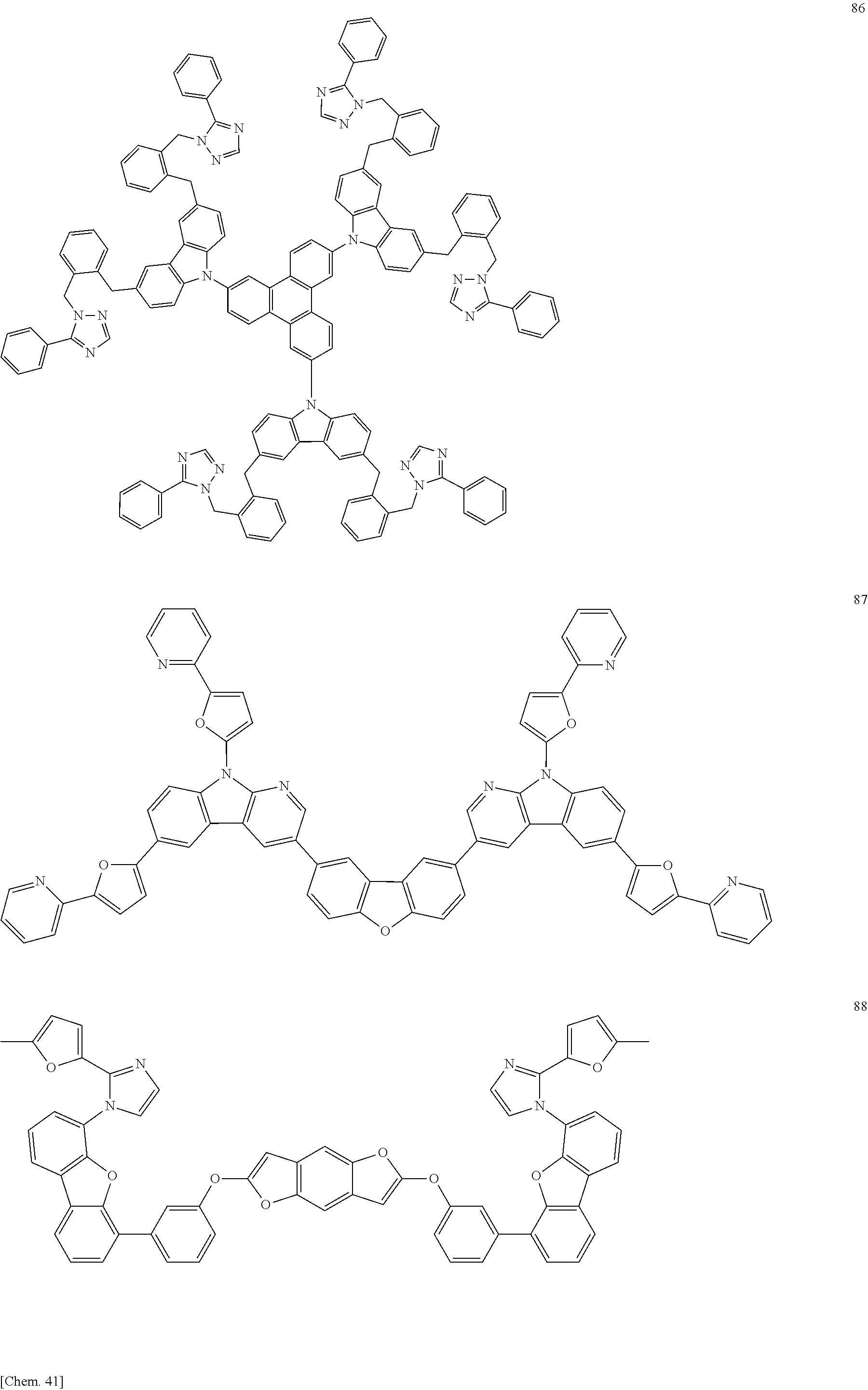

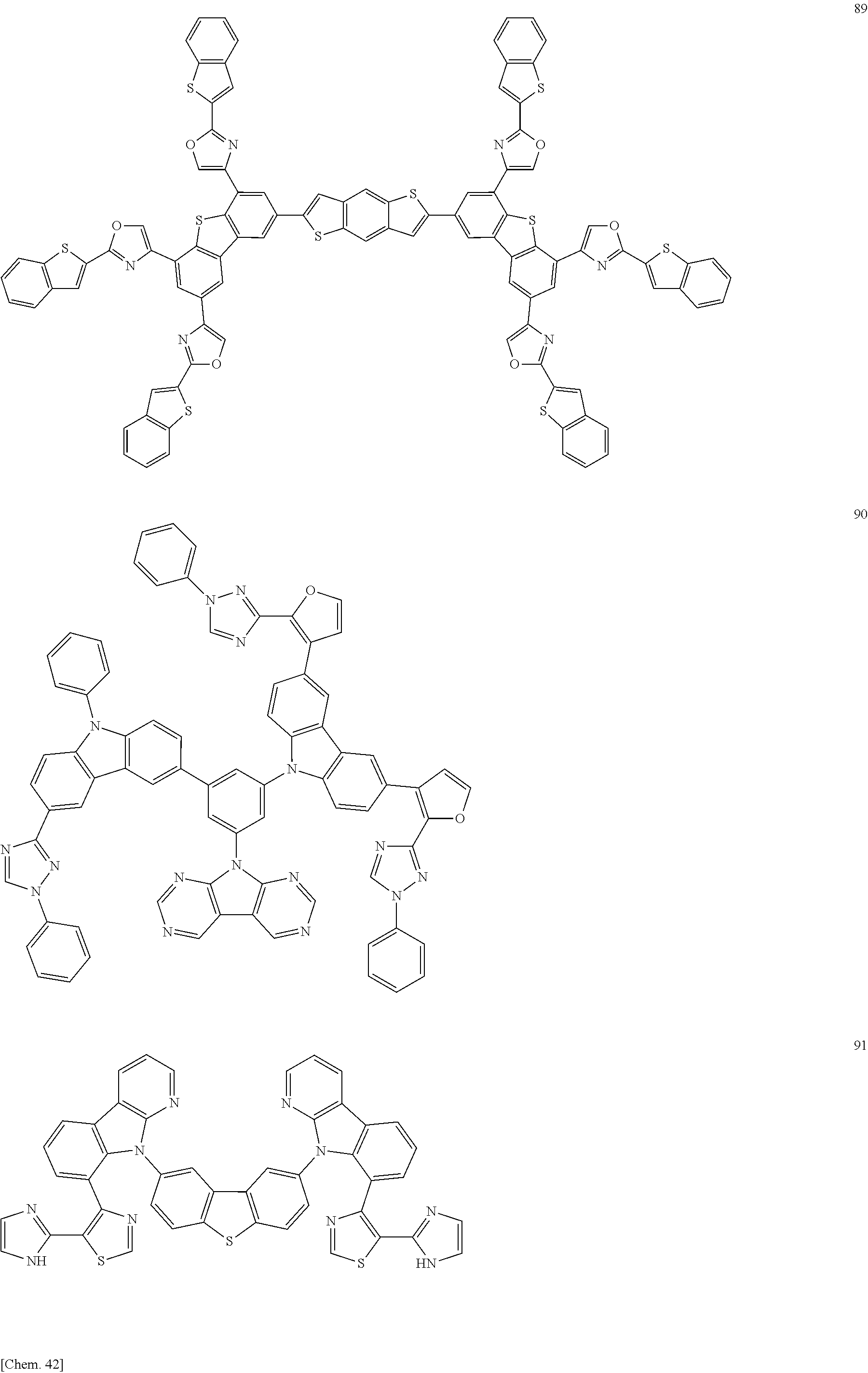

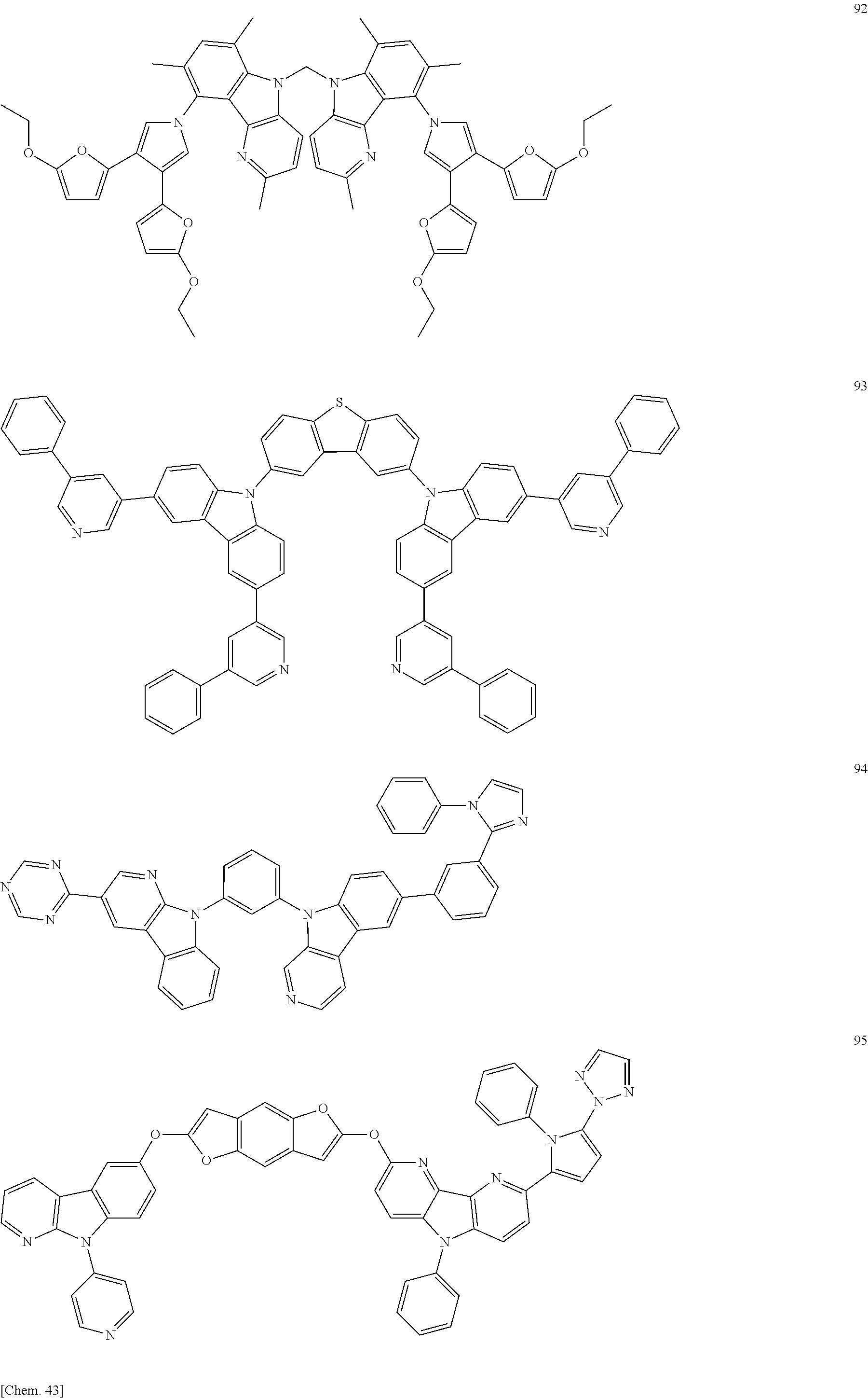

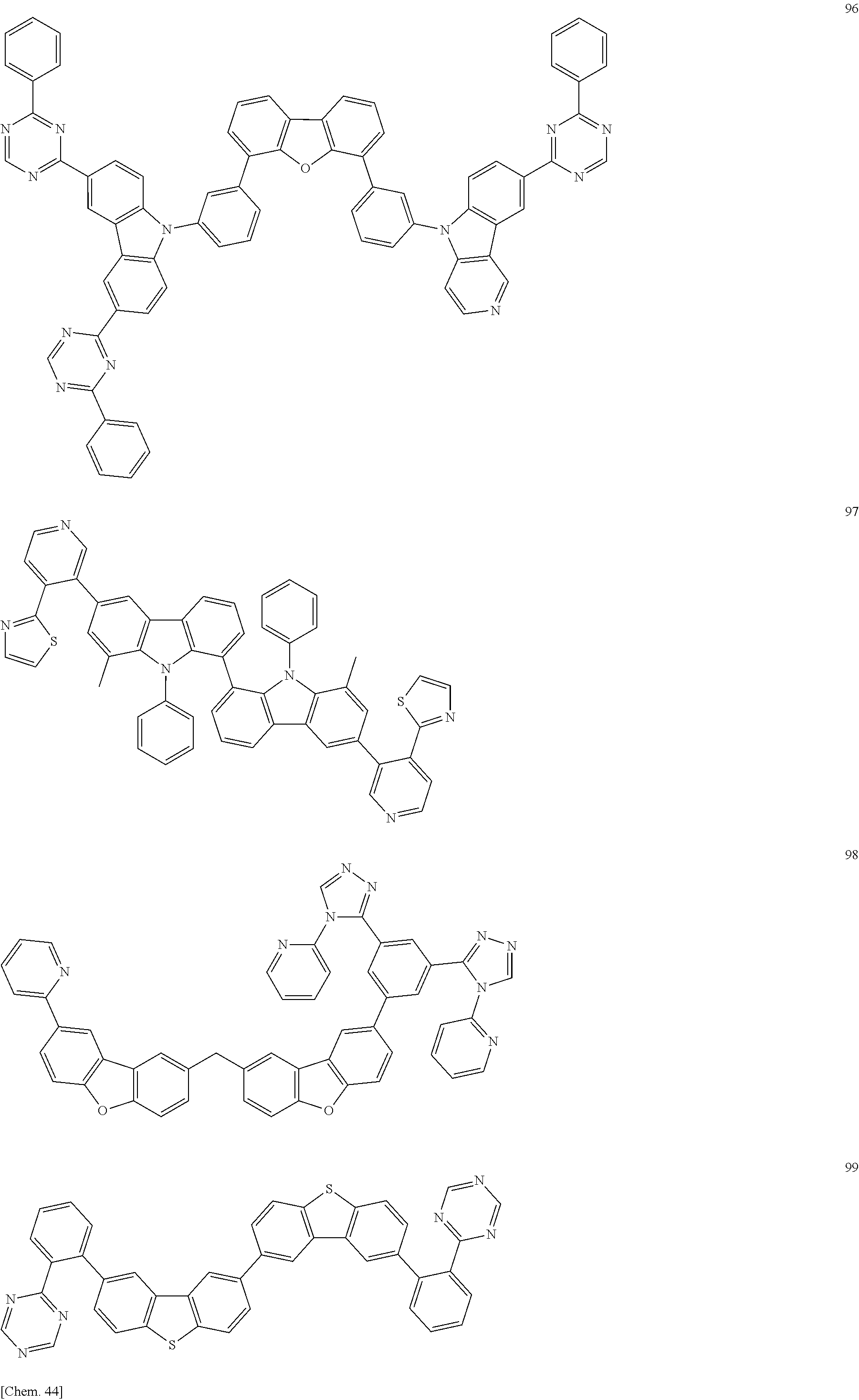

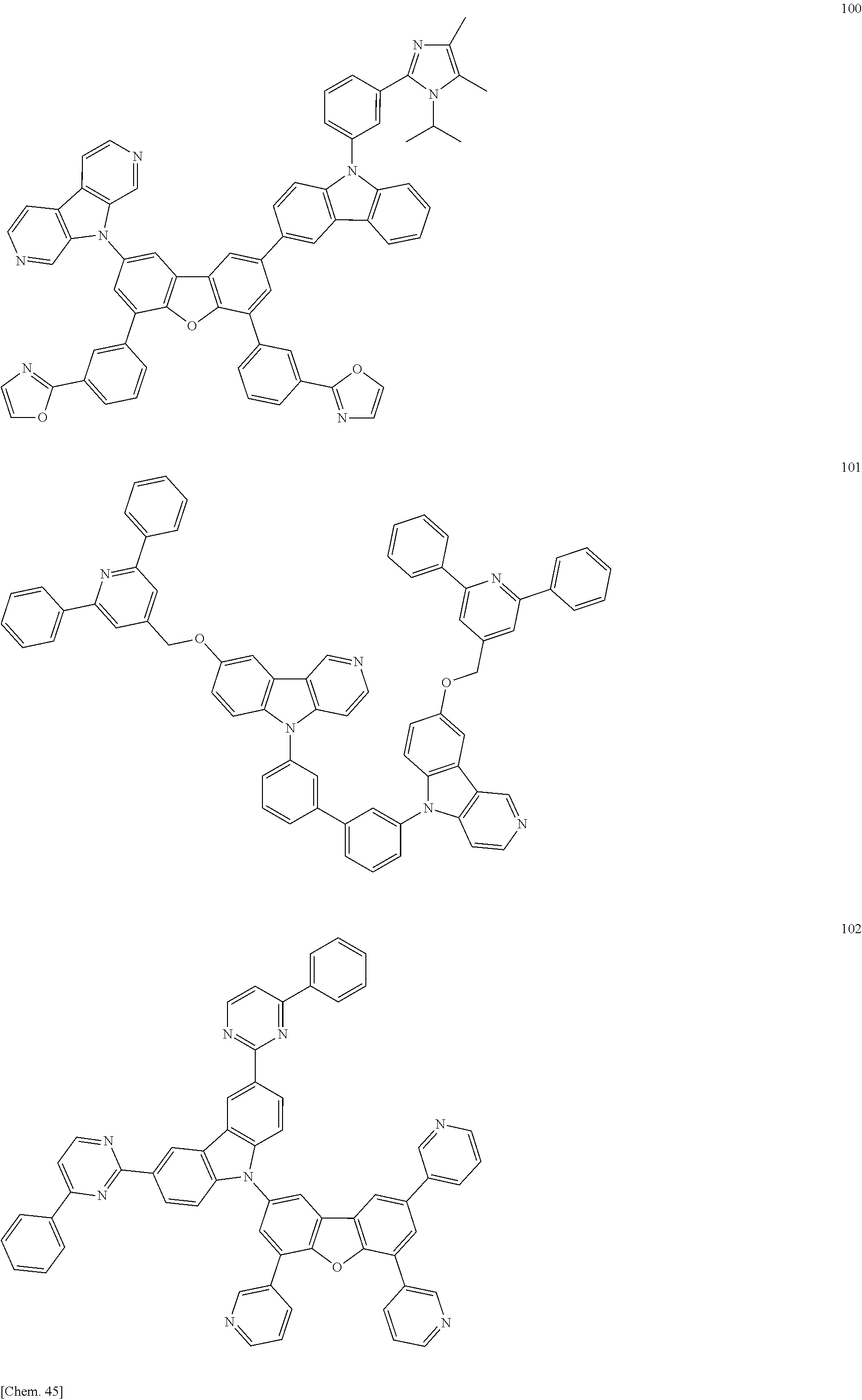

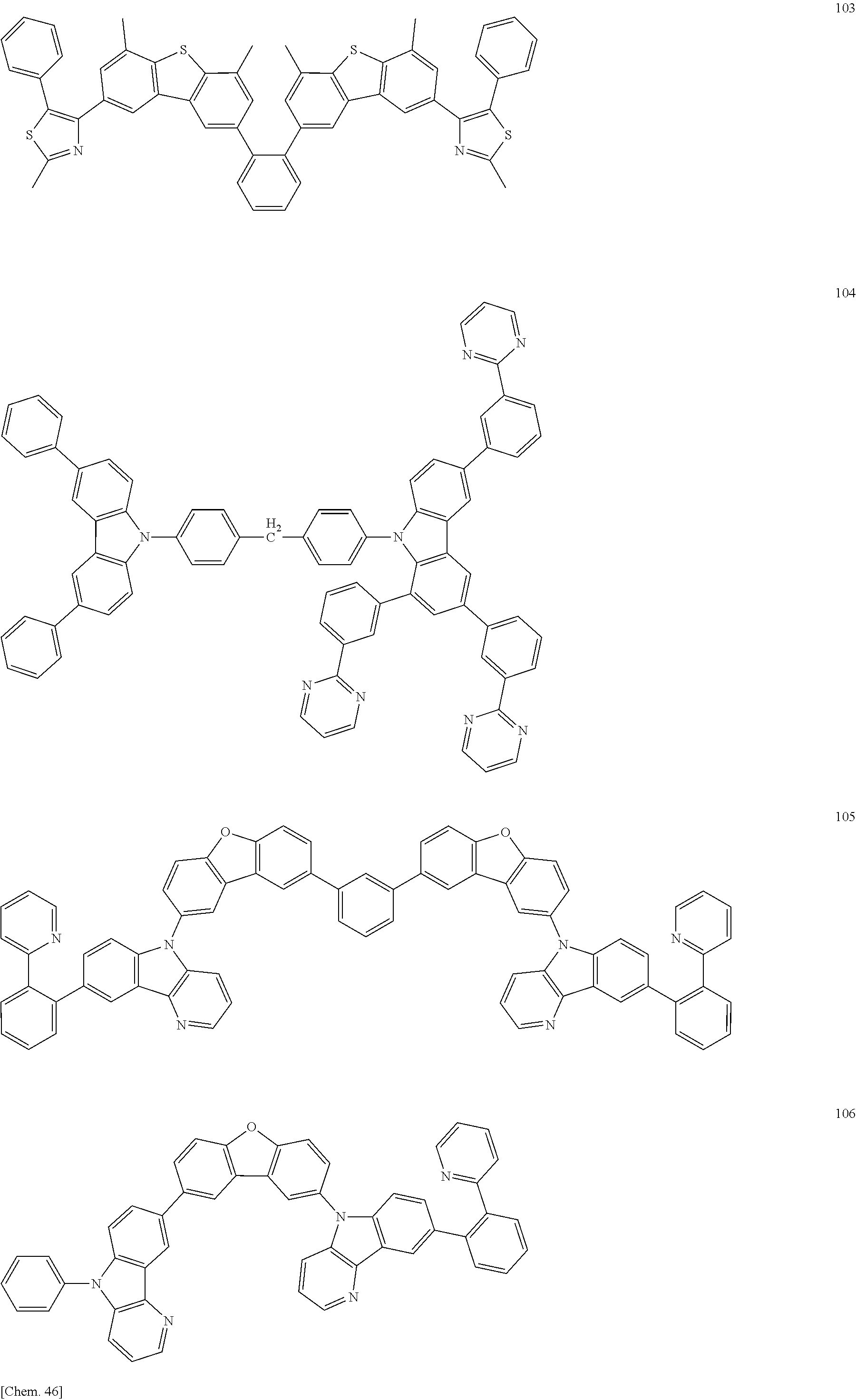

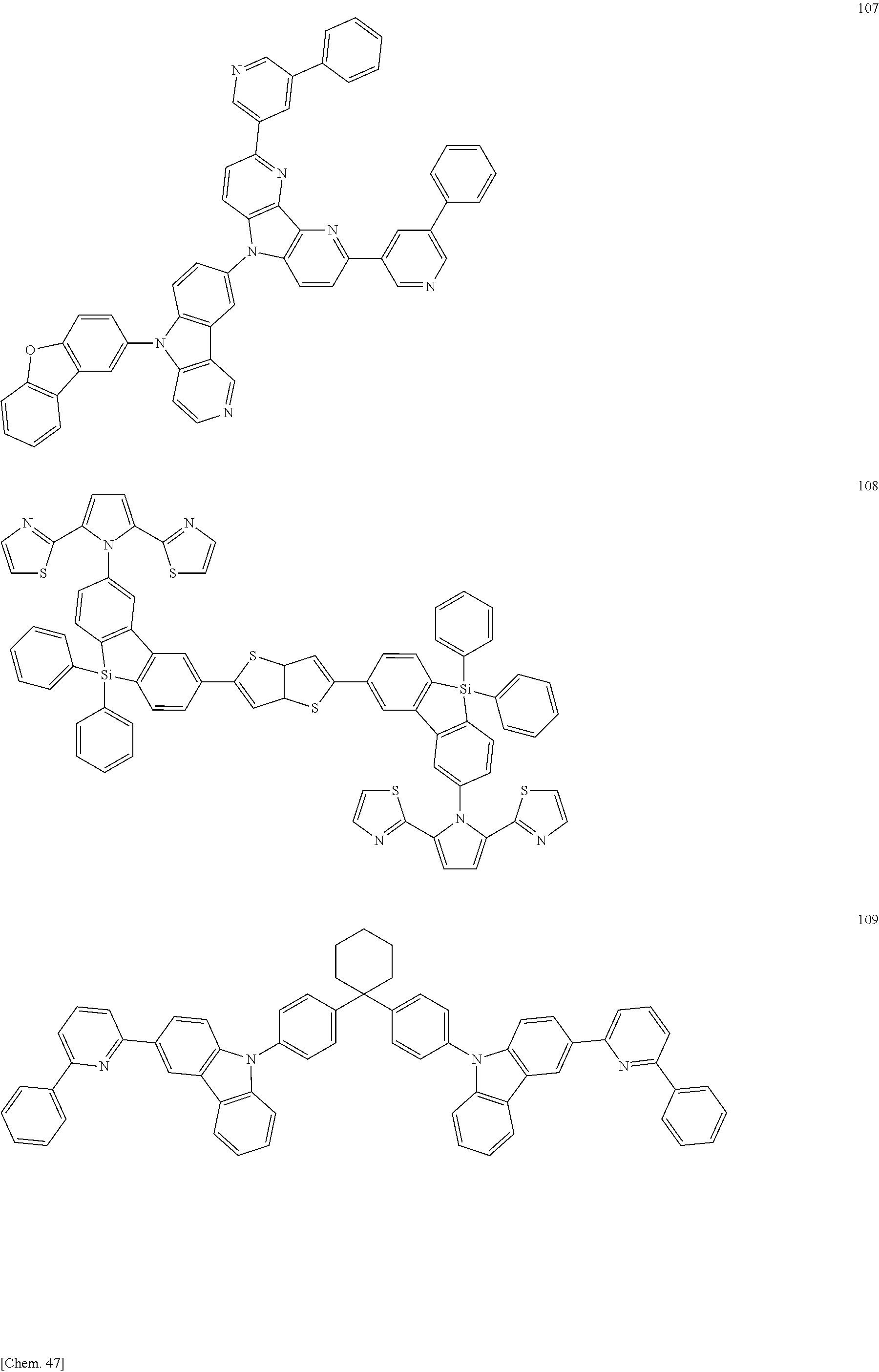

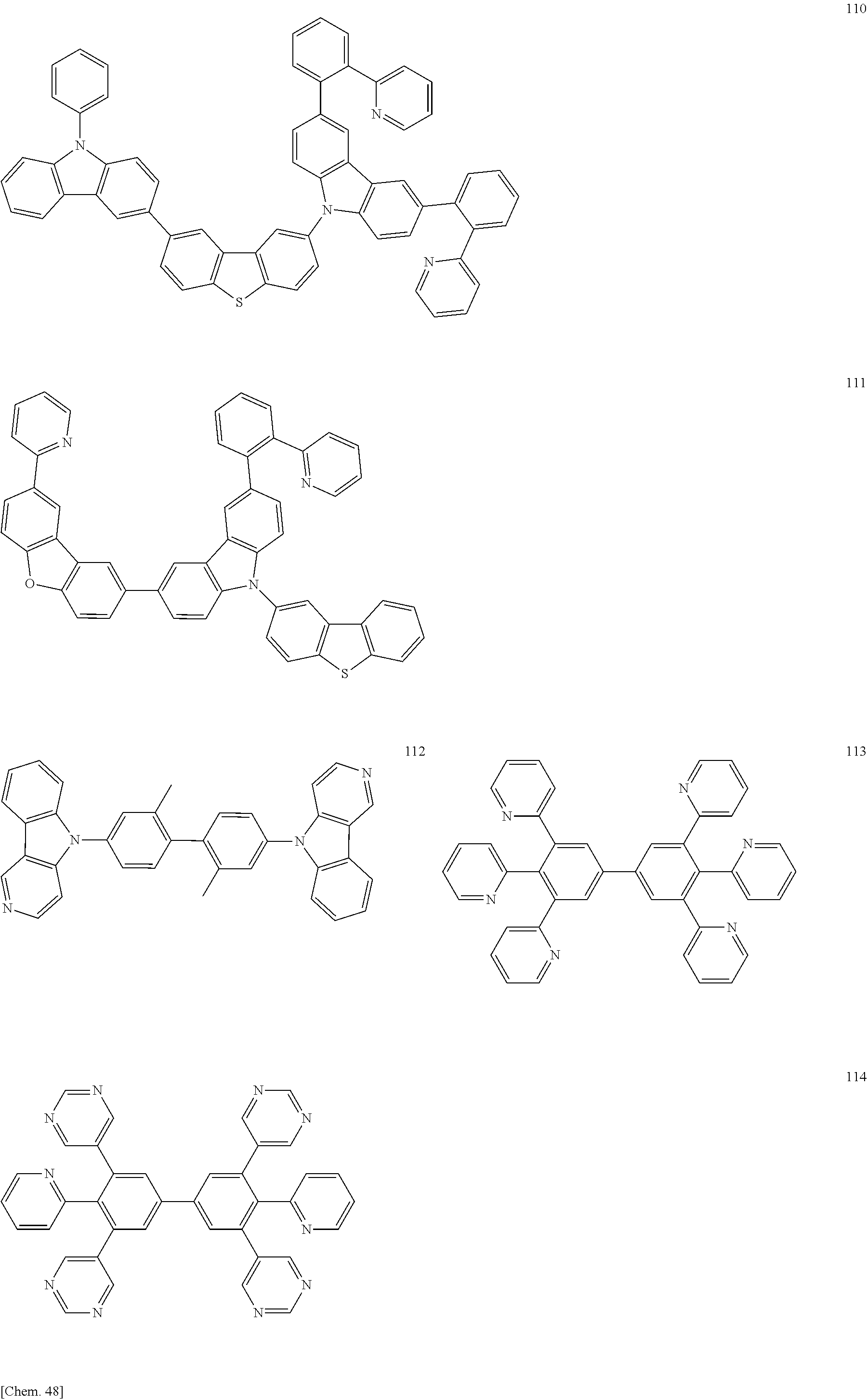

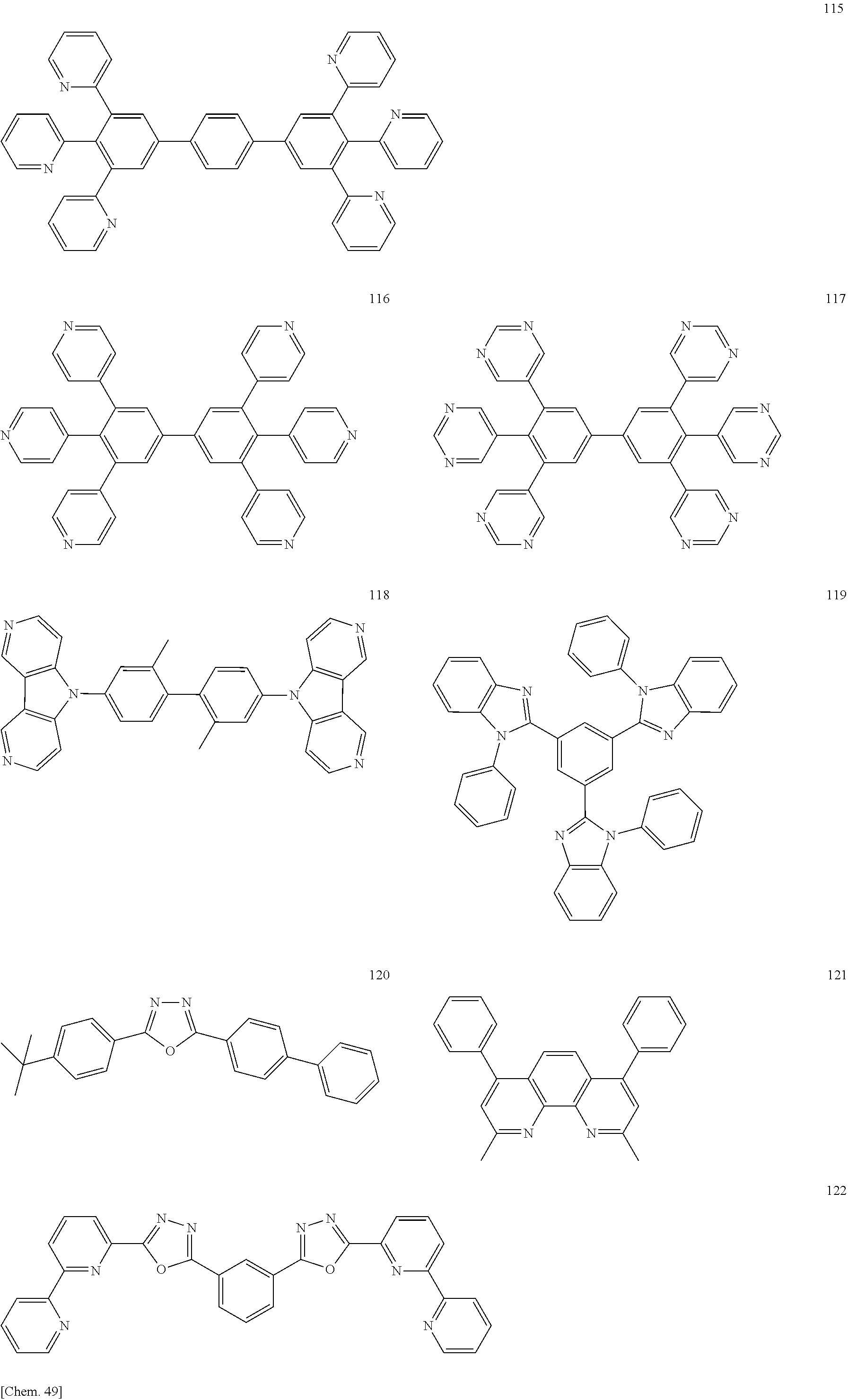

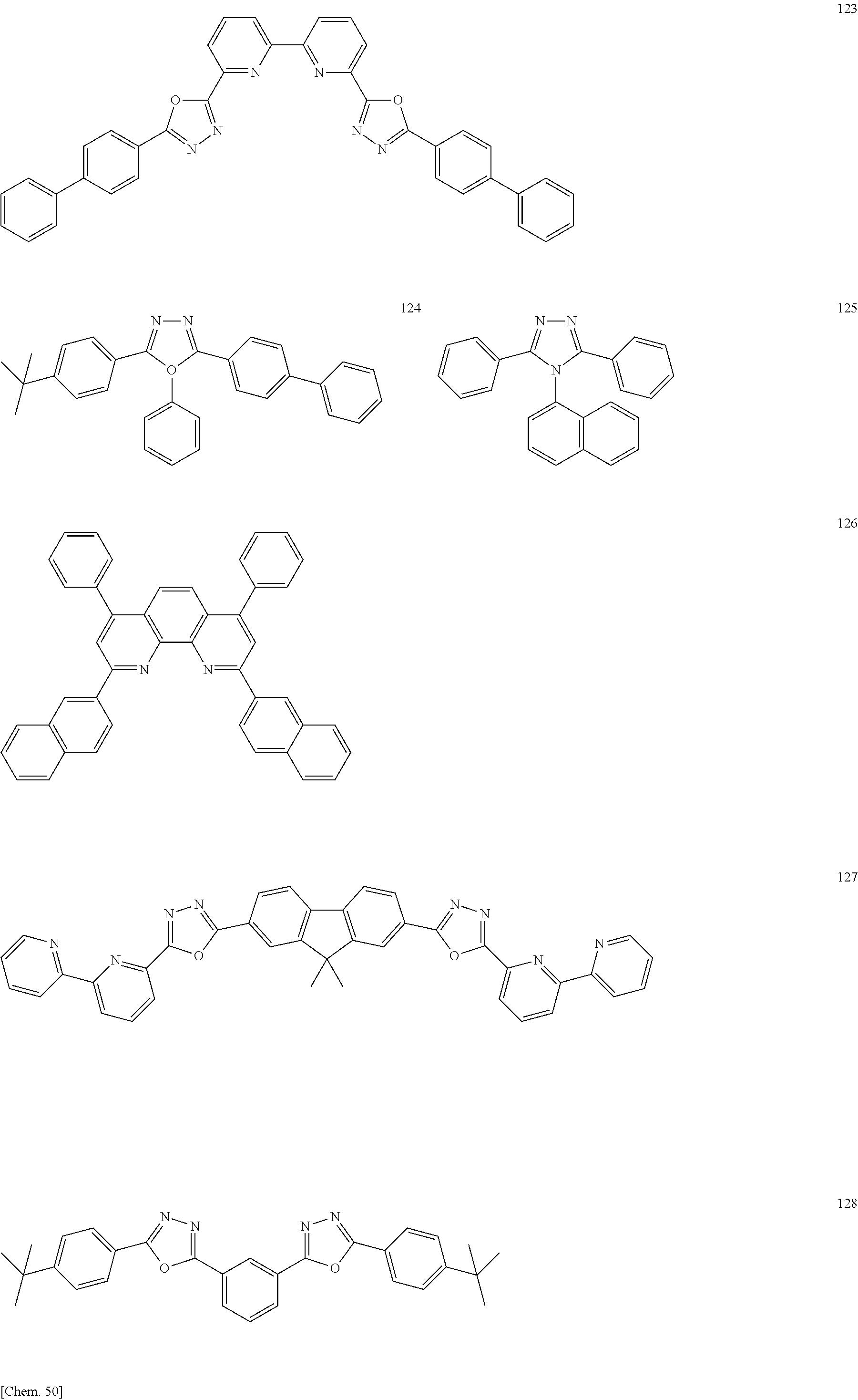

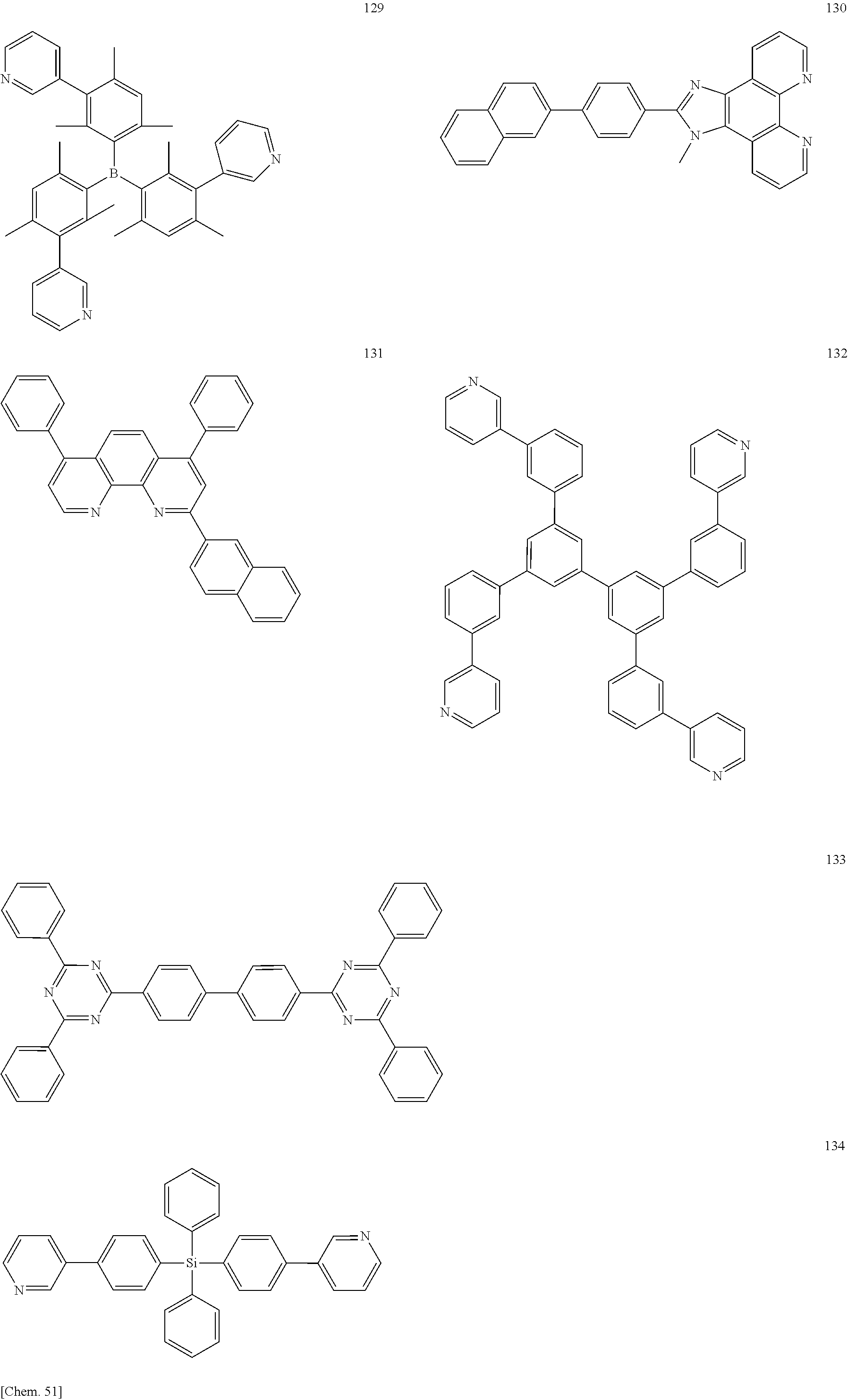

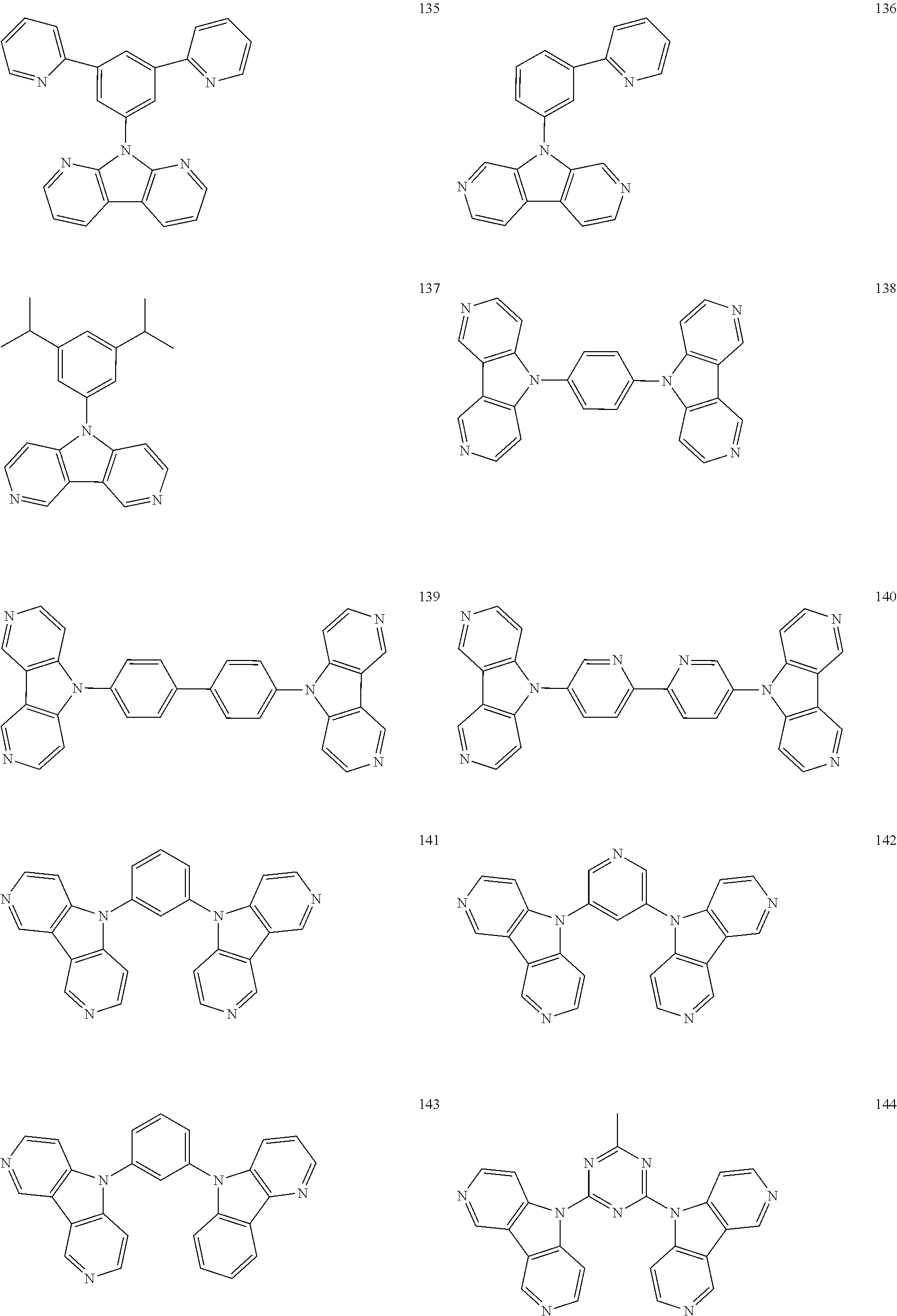

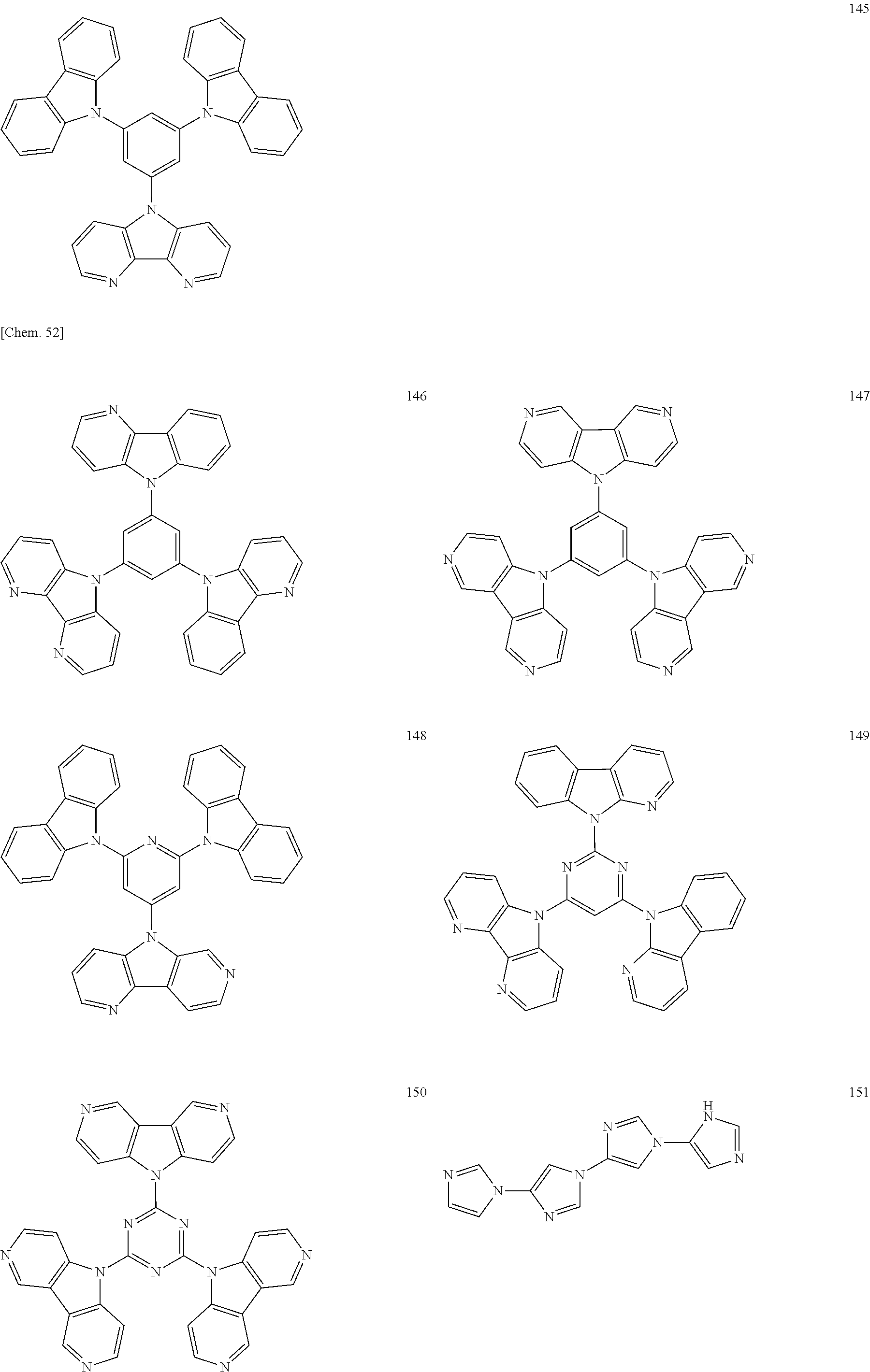

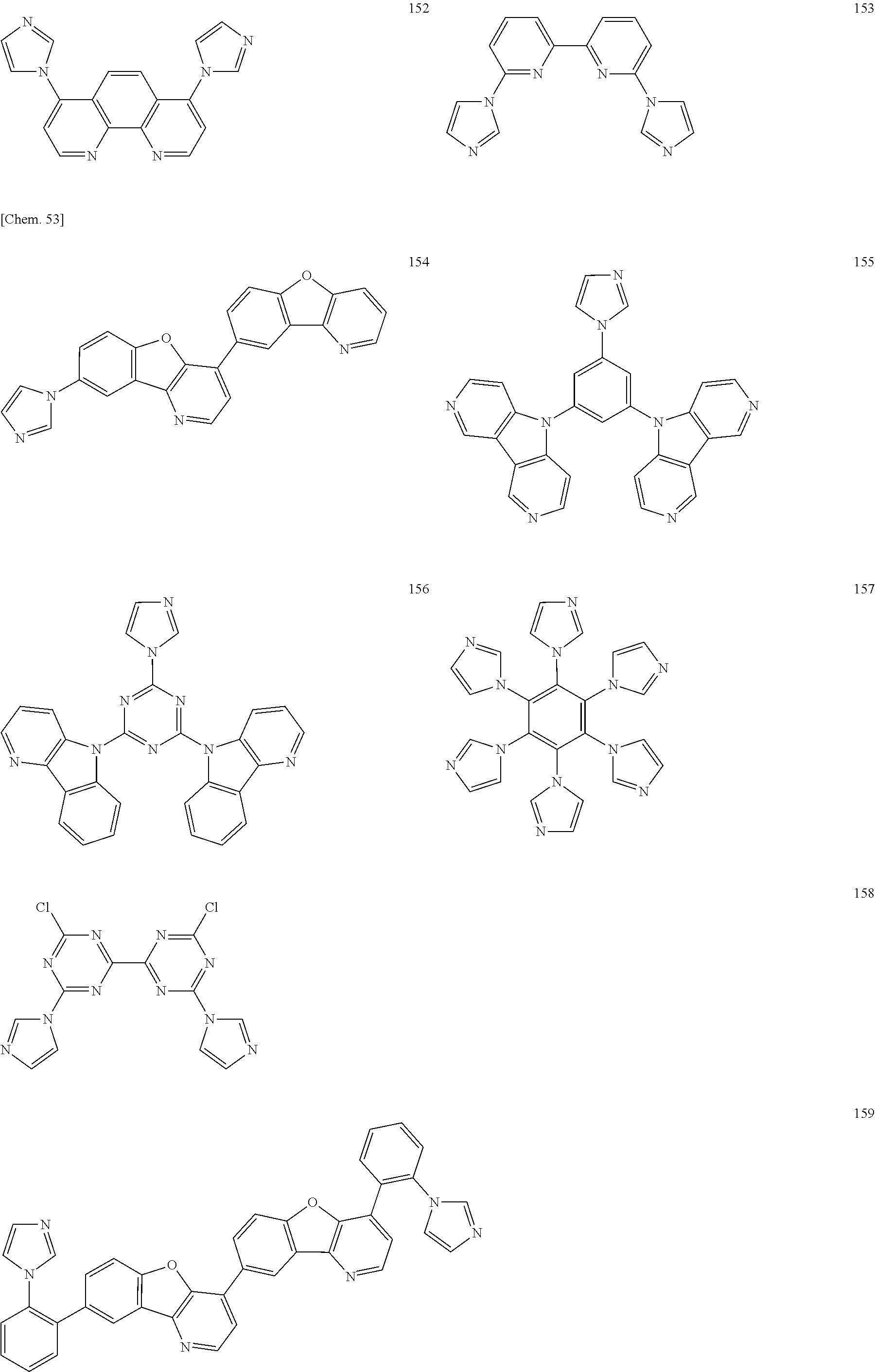

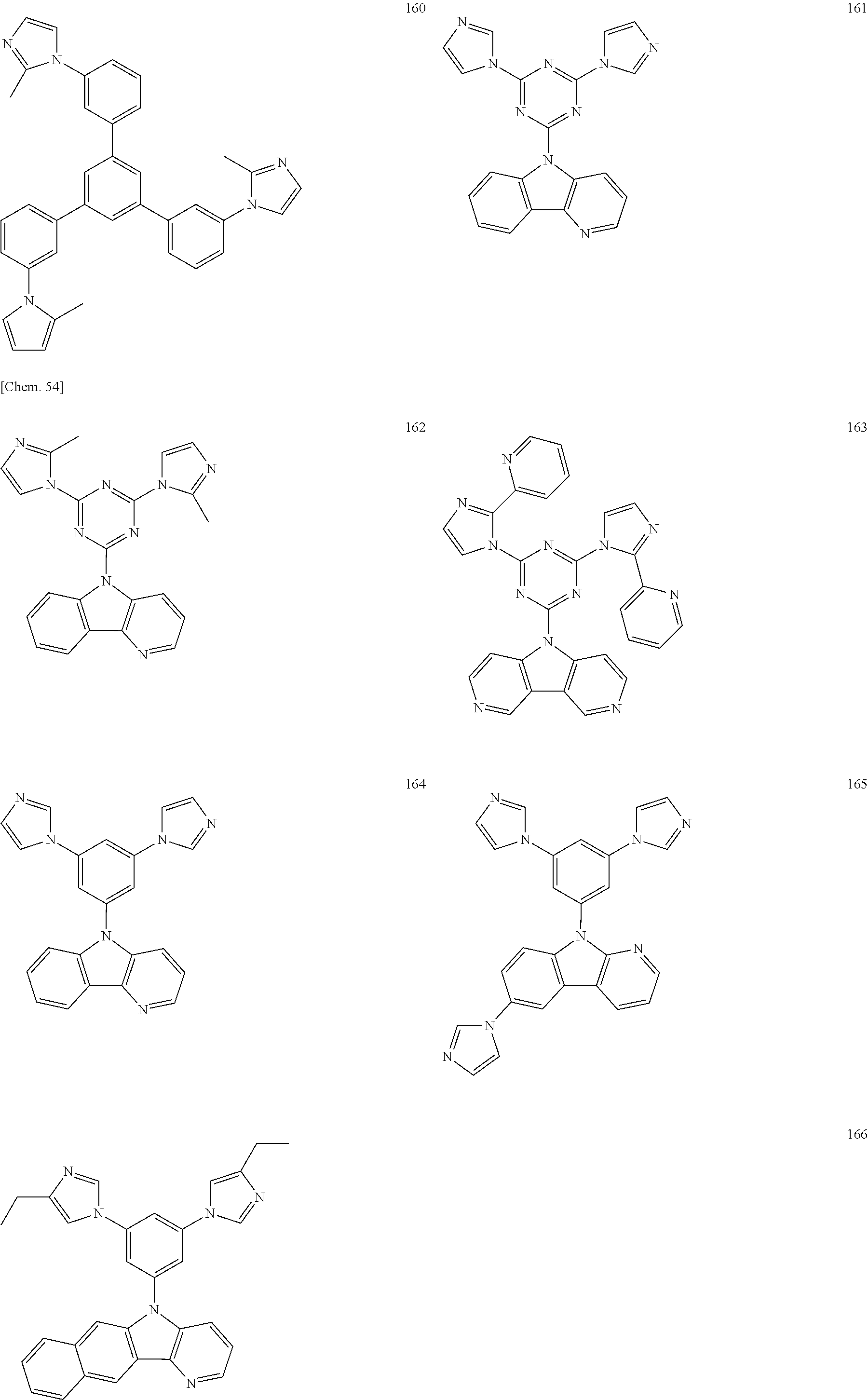

### Synthetic Example of Compound

Hereinafter, as a synthetic example of a typical compound, a specific synthetic example of Compound 5 will be described, but the present invention is not limited thereto.

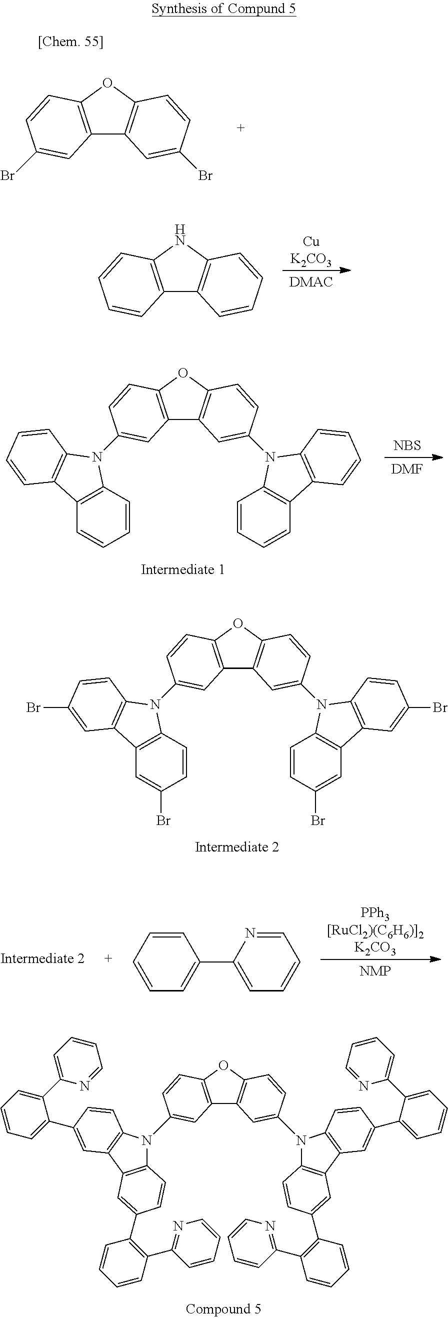

### Process 1: (Synthesis of Intermediate 1)

Under nitrogen atmosphere, 2,8-dibromodibenzofuran (1.0 mole), of carbazole (2.0 moles), copper powder (3.0 moles), potassium carbonate (1.5 moles) were mixed in 300 ml of DMAc (dimethylacetamide) and then stirred for 24 hours at 130° C. After the reaction liquid thus obtained was cooled to room temperature, 1 L of toluene was added to the liquid, the resultant liquid was washed three times with distilled water, the solvent was distilled away from the washed layer under reduced pressure, and purification of the residue with silica gel flash chromatography (n-heptane:toluene=4:1 to 3:1) gave Intermediate 1 at a yield of 85%.

### Process 2: (Synthesis of Intermediate 2)

At room temperature under atmospheric pressure, Intermediate 1 (0.5 mole) was dissolved into 100 ml of DMF (dimethylformamide), NBS (N-bromosuccinic acid imide) (2.0 moles) was added, and then stirred over one night at room temperature. The obtained precipitate was filtered and washed with methanol, and thus Intermediate 2 was obtained at a yield of 92%.

### Process 3: (Synthesis of Compound 5)

Under nitrogen atmosphere, Intermediate 2 (0.25 mole), 2-phenylpyridine (1.0 mole), ruthenium complex [(η6-C6H6)RuCl2]2 (0.05 mole), triphenylphosphine (0.2 mole), potassium carbonate (12 moles) were mixed in 3 L of NMP (N-methyl-2-pyrrolidone), and then stirred over one night at 140° C.

After the reaction liquid was cooled to room temperature, 5 L of dichloromethane was added, and then the liquid was filtered. The solvent was distilled away from the filtrate under reduced pressure (800 Pa, 80° C.), and the residue was purified with silica gel flash chromatography (CH₂Cl₂:Et₃N=20:1 to 10:1).

After the solvent was distilled away under reduced pressure, the residue was again dissolved into dichloromethane and washed three times with water. After the substance obtained by the washing was dried with anhydrous magnesium sulfate, the solvent was distilled away under reduced pressure from the dried substance and thus Compound 5 was obtained at a yield of 68%.

[Method of Film Formation of Nitrogen-Containing Layer]

In a case where the nitrogen-containing layer 12 is formed on the substrate 11 as described above, examples of the formation method include a wet process such as a coating method, an inkjet method or a dipping method, and a dry process such as a vapor deposition method (resister heating, EB method or the like), a sputtering method or a CVD method, and the like. Among them, the vapor deposition method is preferably applied.

Particularly, in a case where the nitrogen-containing layer 12 is formed by using a plurality of compounds, a co-deposition method may be employed in which a plurality of compounds is supplied at the same time from a plurality of deposition sources. In case of using a high molecular weight compound, the coating method is preferably employed. In a case, a coating solution in which the compound is dissolved in a solvent is used. The solvent to dissolve the compound is not limited. In a case in which the nitrogen-containing layer 12 is formed using a plurality of compounds, a coating solution may be produced using a solvent which can dissolve such a plurality of compounds.

[Transparent Electrode]

There is required a configuration in which the transparent electrode 13 is, as described above, formed to be thin so that the difference between the maximum value and the minimum value of element reflectance of light having a wavelength of 450 nm to 750 nm of the organic EL element 10 is 30% or less, and even if the electrode is formed to be thin, the light transmission property is not lowered.

The transparent electrode 13 is a layer constituted by silver as a main component, and is a layer constituted using silver or an alloy having silver as a main component and formed adjacent to the nitrogen-containing layer 12.

Examples of the alloy having silver (Ag) as a main component which configures the transparent electrode 13 include, for instance, silver magnesium (AgMg), silver copper (AgCu), silver palladium (AgPd), silver copper palladium (AgPdCu), silver indium (AgIn), or the like.

Examples of the formation method of the transparent electrode 13 include a wet process such as a coating method, an inkjet method or a dipping method, and a dry process such as a vapor deposition method (resister heating, EB method, or the like), a sputtering method or a CVD method, and the like. Among them, the vapor deposition method is preferably applied. Although the feature of the transparent electrode 13 is to have a sufficient electrical conductivity without a high-temperature annealing treatment after formation of the transparent electrode 13 on the nitrogen-containing layer 12, the high temperature annealing treatment may be carried out after formation, as necessary.

The transparent electrode 13 as described above may have a configuration in which layers of silver or an alloy having silver as a main component are laminated by being divided into a plurality of layers, as necessary.

Furthermore, the transparent electrode 13 preferably has a film thickness within the range of 4 to 15 nm. When the thickness is 15 nm or less, since an absorption component or a reflection component of the layer can be suppressed at a low level, the light transmittance of the transparent electrode 13 is maintained, thereby being preferable. When the thickness is 4 nm or more, the electrical conductivity of the layer is also ensured.

The layer having silver as a main component is formed on the nitrogen-containing layer 12 as the transparent electrode 13, and thus, due to interaction of the silver being a main component of the transparent electrode 13 and the compound containing nitrogen atom constituting the nitrogen-containing layer 12, a distribution distance of the silver atom on the surface of the nitrogen-containing layer is reduced, which causes suppression of aggregation of silver. As a result, generally, a thin silver layer that tends to be easily isolated in an island shape as the result of the growth by a nuclear growth-type (Volumer-Weber: VW type) is formed by the growth of a single layer growth type (Frank-van der Merwe: FM type).

Accordingly, a uniform transparent electrode 13 can be obtained even the layer is thin by forming the metal layer having silver as a main component in contact with the nitrogen-containing layer 12.

It is possible to lower the reflectance of the transparent electrode 13 and to increase the light transmission property of the transparent electrode 13, by forming the thin and uniform transparent electrode 13 having silver as a main component. Furthermore, due to the high uniformity of the layer having silver as a main component, it is possible to suppress the absorption and the wavelength dependency caused by the interference with the specific wavelength in the transparent electrode 13.

Accordingly, the wavelength dependency of the organic EL element 10 can be suppressed, and the difference between the maximum value and the minimum value of the element reflectance of 450 nm to 750 nm can be decreased.

[Light Emitting Unit]

The light emitting unit 14 is provided between the anode and the cathode, and includes one or more light emitting layers containing an organic material layer which emits light. Moreover, the light emitting unit 14 may have other layer between the light emitting layer and the electrode.

In the light emitting unit 14, it is necessary to adjust the thickness so that, as described above, the difference between the maximum value and the minimum value of element reflectance of 450 nm to 750 nm of the organic EL element 10 is 30% or less. Therefore, it is necessary to set the total thickness of the light emitting unit 14 so as to make the difference between the maximum value and the minimum value of element reflectance of 450 nm to 750 nm of the organic EL element 10 to be 30% or less, and then, to adjust the thickness of each layer constituting the light emitting unit 14 so as to be the total thickness. In addition, the thickness of each layer is adjusted so as to satisfy the set total thickness of the light emitting unit 14 and so as not to obstruct the functions to be required in each layer constituting the light emitting unit 14.

Representative element configurations used for an organic EL element 10 can include the following configurations, but the present invention is not limited thereto.

(1) Anode/light emitting layer/cathode
(2) Anode/light emitting layer/electron transport layer/cathode
(3) Anode/positive hole transport layer/light emitting layer/cathode
(4) Anode/positive hole transport layer/light emitting layer/electron transport layer/cathode
(5) Anode/positive hole transport layer/light emitting layer/electron transport layer/electron injection layer/cathode
(6) Anode/positive hole injection layer/positive hole transport layer/light emitting layer/electron transport layer/cathode
(7) Anode/positive hole injection layer/positive hole transport layer/(electron blocking layer)/light emitting layer/(positive hole blocking layer)/electron transport layer/electron injection layer/cathode

Among them, the configuration (7) is preferably used, but the present invention is not limited thereto.

In the above representative element configurations, the light emitting unit 14 which emits light is the layers other than the anode and cathode.

In the above configuration, the light emitting layer is constituted by a mono-layer or multi-layer. When the light emitting layer is plural, a non-light emitting intermediate layer may be provided between the respective light emitting layers.

Furthermore, as necessary, a positive hole blocking layer (positive hole barrier layer), an electron injection layer (cathode buffer layer) or the like may be provided between the light emitting layer and the cathode, and an electron blocking layer (electron barrier layer), a positive hole injection layer (anode buffer layer) or the like may be provided between the light emitting layer and the anode.

The electron transport layer is a layer having a function of transporting an electron. The electron transport layer includes the electron injection layer, and the positive hole blocking layer in a broad sense. Furthermore, the electron transport layer may be constituted of plural layers.

The positive hole transport layer is a layer having a function of transporting a positive hole. The positive hole transport layer includes the positive hole injection layer, and the electron blocking layer in a broad sense. Moreover, the positive hole transport layer may be constituted of plural layers.

Hereinafter, each layer constituting the light emitting unit 14 will be explained.

[Light Emitting Layer]

The light emitting layer 14 used for the light emitting unit 14 provides a place of emitting light via an exciton by recombination of electrons and positive holes injected from an electrode or an adjacent layer. In the light emitting layer, the light emitting portion may be either within the light emitting layer or at an interface between the light emitting layer and an adjacent layer thereof.

A total thickness of the light emitting layer is not particularly limited, and is determined from the viewpoint of homogeneity of the film to be formed, required voltage during light emission, stability of the light emission color to a drive electric current, and the like. The total thickness of the layers is preferably adjusted to be in the range of 2 nm to 5 μm, more preferably adjusted to be in the range of 2 nm to 500 nm, and further preferably adjusted to be in the range of 5 nm to 200 nm. The film thickness of each light emitting layer is preferably adjusted to be in the range of 2 nm to 1 μm, more preferably adjusted to be in the range of 2 nm to 200 nm, and further preferably adjusted to be in the range of 3 nm to 150 nm.

It is preferable that the light emitting layer contains a light emitting dopant (a light emitting dopant compound, a dopant compound, or simply referred as a dopant) and a host compound (a matrix material, a light emitting host compound, or simply referred as a host).

(1. Light Emitting Dopant)

A fluorescence emitting dopant (also referred to as a fluorescent dopant or a fluorescent compound) and a phosphorescence emitting dopant (also referred to as a phosphorescent dopant or a phosphorescent compound) are preferably used as the light emitting dopant to be used in the light emitting layer. Among them, it is preferable that at least one light emitting layer contains the phosphorescence emitting dopant.

A concentration of the light emitting dopant in the light emitting layer can be optionally determined on the basis of the specific dopant to be used and required conditions of the device. The light emitting dopant may be contained at a uniform concentration in a film thickness direction of the light emitting layer, or may have optional distribution of concentration.

Furthermore, in the light emitting layer, a plurality of the light emitting dopants may be contained. For example, a combination of dopants each having different construction, or a combination of the fluorescence emitting dopant and the phosphorescence emitting dopant may be used. Thereby, any required emission color can be obtained.

The color of light emitted by an organic EL element 10 is determined by a color when, in FIG. 4 0.16 on page 108 of “Shinpen Shikisai Kagaku Handbook (New Edition Color Science Handbook)” (edited by The Color Science Association of Japan, Tokyo Daigaku Shuppan Kai, 1985), results obtained by measurement by using a spectroradiometric luminance meter CS-2000 (manufactured by Konica Minolta, Inc.) are applied to the CIE chromaticity coordinate.

It is preferable that the organic EL element 10 exhibits white emission by one or a plurality of light emitting layers containing plural emission dopants having different emission colors. The combination of light emitting dopants exhibiting a white color is not specifically limited. Examples include a combination of blue and orange, a combination of blue, green and red, and the like.

It is preferable that, as to a white color in the organic EL element 10, chromaticity in the CIE 1931 Color Specification System at 1,000 cd/m² is within the region of x=0.39±0.09 and y=0.38±0.08, when measurement of 2-degree viewing angle front luminance is performed by the above-described method.

(1-1. Phosphorescence Emitting Dopant)

The phosphorescence emitting dopant is a compound in which emission is observed from an excited triplet state thereof. Specifically, the dopant is a compound which emits phosphorescence at room temperature (25° C.) and which exhibits a phosphorescence quantum yield of 0.01 or more at 25° C. In the phosphorescence emitting dopant used for the light emitting layer, the phosphorescence quantum yield is preferably 0.1 or more.

The phosphorescence quantum yield can be measured by a method described in page 398 of Bunko II of Dai 4 Han Jikken Kagaku Koza 7 (Spectroscopy II of 4th Edition Lecture of Experimental Chemistry 7) (1992, published by Maruzen Co. Ltd.). The phosphorescence quantum yield in a solution can be measured by using various solvents. In the phosphorescence emitting dopant used for the light emitting layer, the above phosphorescence quantum yield (0.01 or more) may be achieved by using any of optional solvents.

There are two kinds of principles regarding emission of a phosphorescence emitting dopant.

One is an energy transfer type in which an excited state of a host compound is produced by recombination of carriers on the host compound on which the carriers are transported, and then emission from the phosphorescence emitting dopant is realized by transfer of this energy to the phosphorescence emitting dopant. The other is a carrier trap type in which a phosphorescence emitting dopant serves as a carrier trap and then the recombination of carriers takes place on the phosphorescence emitting dopant to thereby give emission from the phosphorescence emitting dopant. In each case, the excited state energy of the phosphorescence emitting dopant is required to be lower than the excited state energy of the host compound.

A phosphorescence emitting dopant can be suitably selected and used from the known materials generally used for the light emitting layer for an organic EL element.

Specific examples of the known phosphorescence emitting dopant include compounds and the like described in the following publications.

Nature 395, 151 (1998), Appl. Phys. Lett. 78, 1622 (2001), Adv. Mater. 19, 739 (2007), Chem. Mater. 17, 3532 (2005), Adv. Mater. 17, 1059 (2005), WO 2009/100991, WO 2008/101842, WO 2003/040257, US Patent Laid-Open No. 2006/835469, US Patent Laid-Open No. 2006/0202194, US Patent Laid-Open No. 2007/0087321, US Patent Laid-Open No. 2005/0244673

Inorg. Chem. 40, 1704 (2001), Chem. Mater. 16, 2480 (2004), Adv. Mater. 16, 2003 (2004), Angew. Chem. Int. Ed. 2006, 45, 7800, Appl. Phys. Lett. 86, 153505 (2005), Chem. Lett. 34, 592 (2005), Chem. Commun. 2906 (2005), Inorg. Chem. 42, 1248 (2003), WO 2009/050290, WO 2002/015645, WO 2009/000673, US Patent Laid-Open No. 2002/0034656, U.S. Pat. No. 7,332,232, US Patent Laid-Open No. 2009/0108737, US Patent Laid-Open No. 2009/0039776, U.S. Pat. No. 6,921,915, U.S. Pat. No. 6,687,266, US Patent Laid-Open No. 2007/0190359, US Patent Laid-Open No. 2006/0008670, US Patent Laid-Open No. 2009/0165846, US Patent Laid-Open No. 2008/0015355, U.S. Pat. No. 7,250,226, U.S. Pat. No. 7,396,598, US Patent Laid-Open No. 2006/0263635, US Patent Laid-Open No. 2003/0138657, US Patent Laid-Open No. 2003/0152802, U.S. Pat. No. 7,090,928

Angew. Chem. Int. Ed. 47, 1 (2008), Chem. Mater. 18, 5119 (2006), Inorg. Chem. 46, 4308 (2007), Organometallics 23, 3745 (2004), Appl. Phys. Lett. 74, 1361 (1999), WO 2002/002714, WO 2006/009024, WO 2006/056418, WO 2005/019373, WO 2005/123873, WO 2005/123873, WO 2007/004380, WO 2006/082742, US Patent Laid-Open No. 2006/0251923, US Patent Laid-Open No. 2005/0260441, U.S. Pat. No. 7,393,599, U.S. Pat. No. 7,534,505, U.S. Pat. No. 7,445,855, US Patent Laid-Open No. 2007/0190359, US Patent Laid-Open No. 2008/0297033, U.S. Pat. No. 7,338,722, US Patent Laid-Open No. 2002/0134984, U.S. Pat. No. 7,279,704, US Patent Laid-Open No. 2006/098120, US Patent Laid-Open No. 2006/103874

WO 2005/076380, WO 2010/032663, WO 2008/140115, WO 2007/052431, WO 2011/134013, WO 2011/157339, WO 2010/086089, WO 2009/113646, WO 2012/020327, WO 2011/051404, WO 2011/004639, WO 2011/073149, US Patent Laid-Open No. 2012/228583, US Patent Laid-Open No. 2012/212126, Japanese Patent Laid-Open No. 2012-069737, Japanese Patent Laid-Open No. 2012-195554, Japanese Patent Laid-Open No. 2009-114086, Japanese Patent Laid-Open No. 2003-81988, Japanese Patent Laid-Open No. 2002-302671, Japanese Patent Laid-Open No. 2002-363552

Among them, preferable phosphorescence emitting dopants are organic metal complexes having Ir as a central metal. More preferable are complexes containing at least one coordination mode selected from a metal-carbon bond, a metal-nitrogen bond, a metal-oxygen bond and a metal-sulfur bond.

The phosphorescence emitting compounds (also referred to as phosphorescence emitting metal complexes, and the like) can be synthesized by applying the methods described in the following literatures: Organic Letters, vol. 3, No. 16 pp. 2579-2581 (2001), Inorganic Chemistry, vol. 30, No. 8, pp. 1685-1687 (1991), J. Am. Chem. Soc., vol. 123, p. 4304 (2001), Inorganic Chemistry, vol. 40, No. 7, pp. 1704-1711 (2001), Inorganic Chemistry, vol. 41, No. 12, pp. 3055-3066 (2002), New Journal of Chemistry, vol. 26, p. 1171 (2002), European Journal of Organic Chemistry, vol. 4, pp. 695-709 (2004) and further reference literatures therein.

(1-2. Fluorescence Emitting Dopant)

The fluorescence emitting dopant is a compound capable of emitting light from an excited singlet. The dopant is not specifically limited as long as an emission from an excited singlet is observed.

Examples of the fluorescence emitting dopants include an anthracene derivative, a pyrene derivative, a chrysene derivative, a fluoranthene derivative, a perylene derivative, a fluorene derivative, an arylacetylene derivative, a styrylarylene derivative, a styrylamine derivative, an arylamine derivative, a boron complex, a coumarin derivative, a pyran derivative, a cyanine derivative, a croconium derivative, a squarium derivative, an oxobenzanthracene derivative, a fluorescein derivative, a rhodamine derivative, a pyrylium derivative, a perylene derivative, a polythiophene derivative, and a rare earth complex compound, and the like.

In addition, as the fluorescence emitting dopant, a light emitting dopant where delayed fluorescence is utilized and the like may be used.

Specific examples of the light emitting dopant utilizing delayed fluorescence are compounds described in, for example, WO 2011/156793, Japanese Patent Laid-Open No. 2011-213643, and Japanese Patent Laid-Open No. 2010-93181.

(2. Host Compound)

The host compound is a compound which mainly plays a role of injecting or transporting a charge in the light emitting layer, and in the organic EL element, an emission from the host compound itself is not substantially observed.

Preferably, the host compound is a compound having a phosphorescent quantum yield of the phosphorescence emission of less than 0.1 at room temperature (25° C.), more preferably, a phosphorescent quantum yield of less than 0.01. Furthermore, among the compounds contained in the light emitting layer, a mass ratio of the host compound in the layer is preferably 20% or more.

It is preferable that an exited energy level of the host compound is higher than an exited energy level of the light emitting dopant contained in the same layer.

The host compound may be used alone or may be used in combination of a plurality of kinds. The use of a plurality of host compounds makes it possible to adjust transfer of charges, and to increase an efficiency of the organic EL element 10.

The host compound used in the light emitting layer is not particularly limited, and compounds used in known organic EL elements can be used. For example, the host compound to be used may be a low molecular weight compound, or a high molecular compound having a repeating unit, and furthermore, may be a compound having a reactive group such as vinyl group and epoxy group.

The well-known host compound preferably prevents a light-emission wavelength from becoming longer while having a positive hole transport ability and an electron transport ability and preferably has a high Tg (glass transition temperature) from the viewpoint of stability with respect to heat generation at the time of a high temperature driving and during an element driving of the organic EL element 10. Preferably, the host compound has a Tg of 90° C. or more, more preferably, 120° C. or more.

Here, a glass transition temperature (Tg) is a value obtained using DCS (Differential Scanning Colorimetry) based on the method in conformity to JIS-K-7121.

Specific examples of the known host compounds include compounds and the like described in the following literatures and the like, but are not limited thereto.

Japanese patent Laid-Open Nos. 2001-257076, 2002-308855, 2001-313179, 2002-319491, 2001-357977, 2002-334786, 2002-8860, 2002-334787, 2002-15871, 2002-334788, 2002-43056, 2002-334789, 2002-75645, 2002-338579, 2002-105445, 2002-343568, 2002-141173, 2002-352957, 2002-203683, 2002-363227, 2002-231453, 2003-3165, 2002-234888, 2003-27048, 2002-255934, 2002-260861, 2002-280183, 2002-299060, 2002-302516, 2002-305083, 2002-305084 and 2002-308837, US Patent Laid-Open No. 2003/0175553, US Patent Laid-Open No. 2006/0280965, US Patent Laid-Open No. 2005/0112407, US Patent Laid-Open No. 2009/0017330, US Patent Laid-Open No. 2009/0030202, US Patent Laid-Open No. 2005/0238919, WO 2001/039234, WO 2009/021126, WO 2008/056746, WO 2004/093207, WO 2005/089025, WO 2007/063796, WO 2007/063754, WO 2004/107822, WO 2005/030900, WO 2006/114966, WO 2009/086028, WO 2009/003898, WO 2012/023947, Japanese Patent Laid-Open No. 2008-074939, Japanese Patent Laid-Open No. 2007-254297 and EP 2034538 and the like

[Electron Transport Layer]

The electron transport layer used for the organic EL element 10 is composed of a material having a function of transporting an electron, and has a function of transmitting an injected electron from a cathode to the light emitting layer. The electron transport material may be used alone or may be used in combination of two or more kinds.

A total thickness of the electron transport layer is not particularly limited, and is usually in the range of 2 nm to 5 μm, preferably in the range of 2 nm to 500 nm, more preferably in the range of 5 nm to 200 nm.

In the organic EL element 10, it is known that there occurs interference between the light directly taken from the light emitting layer through the transparent electrode 13 and the light taken out after being reflected at the reflective electrode 15 located at the opposite side of the transparent electrode 13.

Accordingly, in the organic EL element 10, the total thickness of the light emitting unit 14 is so adjusted that the difference between the maximum value and the minimum value of element reflectance of 450 nm to 750 nm into 30% or less. It is preferable to adjust the total thickness of the light emitting unit 14 appropriately so that the total film thickness of the electron transport layer is in the range of several nm to several μm.

On the other hand, the voltage will be increased when the film thickness of the electron transport layer is made thick, and, especially when the film thickness is large, an electron mobility in the electron transport layer is preferably 10⁻⁵ cm²/Vs or more.

A material used for the electron transport layer (hereafter, it is referred as an electron transport material) may have either a property of ejection or transport of electrons, or a barrier to positive holes, and any of the conventionally known compounds may be selected and used. Examples include a nitrogen-containing aromatic heterocyclic ring derivative, an aromatic hydrocarbon ring derivative, a dibenzofuran derivative, a dibenzothiophene derivative, a silole derivative, and the like.

Examples of the nitrogen-containing aromatic heterocyclic ring derivative include a carbazole derivative, an azacarbazole derivative (a compound in which one or more carbon atoms constituting the carbazole ring are substituted with nitrogen atoms), a pyridine derivative, a pyrimidine derivative, a pyrazine derivative, a pyridazine derivative, a triazine derivative, a quinoline derivative, a quinoxaline derivative, a phenanthroline derivative, an azatriphenylene derivative, an oxazole derivative, a thiazole derivative, an oxadiazole derivative, a thiadiazole derivative, a triazole derivative, a benzimidazole derivative, a benzoxazole derivative, and a benzothiazole derivative), and the like.

Examples of the aromatic hydrocarbon ring derivative include a naphthalene derivative, an anthracene derivative and a triphenylene derivative, and the like.

Furthermore, metal complexes having a ligand of a quinolinol structure or dibenzoquinolinol structure such as tris(8-quinolinol)aluminum (Alq3), tris(5,7-dichloro-8-quinolinol)aluminum, tris(5,7-dibromo-8-quinolinol)aluminum, tris(2-methyl-8-quinolinol)aluminum, tris(5-methyl-8-quinolinol)aluminum and bis(8-quinolinol)zinc (Znq); and metal complexes in which a central metal of these metal complexes is substituted by In, Mg, Cu, Ca, Sn, Ga or Pb, can also be used as the electron transport material.

Besides, a metal-free or metal phthalocyanine, or a compound whose terminal is substituted by an alkyl group or a sulfonic acid group, can be preferably used as an electron transport material. A distyryl pyrazine derivative, which is exemplified as a material for a light emitting layer, can also be used as an electron transport material. Moreover, in the same manner as used for a positive hole injection layer and a positive hole transport layer, an inorganic semiconductor such as an n-type Si and an n-type SiC can also be used as an electron transport material.

In addition, a polymer material having incorporating any of these compound in a polymer side chain, or having any of these compound in a polymer main chain can also be used.

In the organic EL element 10, it is possible to employ an electron transport layer of a higher n-property (electron rich) which is doped with dope material as a guest material. Examples of the dope material include a metal compound such as a metal complex and a metal halide and other n-type dopant. Specific examples of electron transport layer having such a construction are those described in each of Japanese Patent Laid-Open Nos. 04-297076, 10-270172, 2000-196140, 2001-102175, as well as in J. Appl. Phys., 95, 5773 (2004) and the like.

Specific examples of the preferred known electron transport materials include compounds described in the following literatures and the like, but are not limited thereto. U.S. Pat. No. 6,528,187, U.S. Pat. No. 7,230,107, US Patent Laid-Open No. 2005/0025993, US Patent Laid-Open No. 2004/0036077, US Patent Laid-Open No. 2009/0115316, US Patent Laid-Open No. 2009/0101870, US Patent Laid-Open No. 2009/0179554, WO 2003/060956, WO 2008/132085, Appl. Phys. Lett. 75, 4 (1999), Appl. Phys. Lett. 79, 449 (2001), Appl. Phys. Lett. 81, 162 (2002), Appl. Phys. Lett. 81, 162 (2002), Appl. Phys. Lett. 79, 156 (2001), U.S. Pat. No. 7,964,293, US Patent No. Laid-Open No. 2009/030202, WO 2004/080975, WO 2004/063159, WO 2005/085387, WO 2006/067931, WO 2007/086552, WO 2008/114690, WO 2009/069442, WO 2009/066779, WO 2009/054253, WO 2011/086935, WO 2010/150593, WO 2010/047707, EP 2311826, Japanese Patent Laid-Open No. 2010-251675, Japanese Patent Laid-Open No. 2009-209133, Japanese Patent Laid-Open No. 2009-124114, Japanese Patent Laid-Open No. 2008-277810, Japanese Patent Laid-Open No. 2006-156445, Japanese Patent Laid-Open No. 2005-340122, Japanese Patent Laid-Open No. 2003-45662, Japanese Patent Laid-Open No. 2003-31367, Japanese Patent Laid-Open No. 2003-282270, and WO 2012/115034 and the like

More preferable electron transport materials are a pyridine derivative, a pyrimidine derivative, a pyrazine derivative, a triazine derivative, a dibenzofuran derivative, a dibenzothiophene derivative, a carbazole derivative, an azacarbazole derivative, and a benzimidazole derivative.

[Positive Hole Blocking Layer]

The positive hole blocking layer has a function of the electron transport layer in a broad sense. The positive hole blocking layer is formed of a positive hole blocking material having a remarkably small capability to transport positive holes while having a function of transporting electrons. The positive hole blocking layer can increase recombination probability of electrons and positive holes by blocking positive holes while transporting electrons.

Furthermore, as necessary, the configuration of an electron transport layer described later can be used as the positive hole blocking layer according to the present invention.

It is preferable that the positive hole blocking layer provided in the organic EL element 10 is provided adjacent to the cathode side of the light emitting layer.

A thickness of the positive hole blocking layer in the organic EL element 10 is preferably in the range of 3 to 100 nm, and more preferably in the range of 5 to 30 nm.

The material used in the above-described electron transport layer is preferably used as a material used for the positive hole blocking layer, and furthermore, the material used as the above-described host compound is also preferably used for the positive hole blocking layer.

[Electron Injection Layer]

The electron injection layer (also referred as “cathode buffer layer”) is a layer arranged between the cathode and the light emitting layer in order to decrease a driving voltage and to enhance an emission luminance. One example of the electron injection layer is described in volume 2, chapter 2 “Electrode materials” (pp. 123-166) of “Organic EL Elements and Industrialization Front thereof (Nov. 30, 1998, published by N.T.S. Co. Ltd.)”.

In the organic EL element 10, the electron injection layer is provided as necessary, and as described above, is provided between the cathode and the light emitting layer, or between the cathode and the electron transport layer.

The electron injection layer is preferably a very thin film, and the film thickness thereof is preferably in the range of 0.1 nm to 5 nm depending on the materials. In addition, the layer may be a non-uniform film in which the constituent material intermittently exists.

The election injection layer is described in detail in Japanese Patent Laid-Open Nos. 06-325871, 09-17574 and 10-74586. Specific examples of the material preferably used in the election injection layer include a metals such as strontium or aluminum; an alkaline metal compound such as lithium fluoride, sodium fluoride, or potassium fluoride; an alkaline earth metal compound such as magnesium fluoride or calcium fluoride; a metal oxide such as aluminum oxide; a metal complex such as lithium 8-hydroxyquinolate (Liq), and the like. In addition, it is possible to use the above-described electron transport materials.

Furthermore, the materials used for the above electron injection layer may be used alone or may be used in combination of two or more kinds.

[Positive Hole Transport Layer]

The positive hole transport layer is made of a material having a function of transporting a positive hole. The positive hole transport layer has a function of transmitting an injected positive hole from an anode to the light emitting layer.

In the organic EL element 10, a total film thickness of the positive hole transport layer is not particularly limited, and is usually in the range of 5 nm to 5 μm, preferably in the range of 2 nm to 500 nm, more preferably in the range of 5 nm to 200 nm.

A material used in the positive hole transport layer (hereafter, referred as positive hole transport material) may have any of properties of injecting or transporting a positive hole, and a barrier property to an electron. The positive hole transport material can be preferably selected and used from the conventionally known compounds. The positive hole transport material may be used alone or may be used in combination of two or more kinds.

Examples of the positive hole transport material include a porphyrin derivative, a phthalocyanine derivative, an oxazole derivative, an oxadiazole derivative, a triazole derivative, an imidazole derivative, a pyrazoline derivative, a pyrazolone derivative, a phenylenediamine derivative, a hydrazone derivative, a stilbene derivative, a polyarylalkane derivative, a triarylamine derivative, a carbazole derivative, an indolocarbazole derivative, an isoindole derivative, an acene-based derivative such as anthracene or naphthalene, a fluorene derivative, a fluorenone derivative, polyvinyl carbazole, a polymer or an oligomer containing an aromatic amine in a main chain or a side chain, polysilane, and a conductive polymer or oligomer (e.g., PEDOT: PSS, aniline-based copolymer, polyaniline and polythiophene), and the like.

Examples of the triarylamine derivative include a benzidine type represented by α-NPD, a star burst type represented by MTDATA, a compound having fluorenone or anthracene in the triarylamine-linking core part, and the like.

Furthermore, the hexaazatriphenylene derivative described in Japanese Unexamined Patent Application Publication No. 2003-519432 and Japanese Patent Laid-Open No. 2006-135145 can also be used as the positive hole transport material.

In addition, it is possible to use the positive hole transport layer of a higher p-property which is doped with impurities. For example, the configurations described in each of Japanese Patent Laid-Open No. 04-297076, Japanese Patent Laid-Open No. 2000-196140, Japanese Patent Laid-Open No. 2001-102175, J. Appl. Phys., 95, 5773 (2004) and the like can also be applied to the positive hole transport layer.

Furthermore, it is possible to employ so-called p-type positive hole transport materials, and inorganic compounds such as p-type Si and p-type SiC, as described in Japanese Patent Laid-Open No. 11-251067, and J. Huang et. al. reference (Applied Physics Letters 80 (2002), p. 139). Moreover, the orthometal organic metal complexes having Ir or Pt as a central metal represented by Ir(ppy)₃ are also preferably used.

The above compounds may be used as the positive hole transport material, and preferable examples include are a triarylamine derivative, a carbazole derivative, an indolocarbazole derivative, an azatriphenylene derivative, an organic metal complex, a polymer or an oligomer obtained by introducing an aromatic amine in a main chain or in a side chain, and the like.

Specific examples of the positive hole transport material include compounds or the like described in the following literatures, other than the above-described literatures, but are not limited thereto.

Appl. Phys. Lett. 69, 2160(1996), J. Lumin. 72-74, 985(1997), Appl. Phys. Lett. 78, 673(2001), Appl. Phys. Lett. 90, 183503(2007), Appl. Phys. Lett. 51, 913(1987), Synth. Met. 87, 171(1997), Synth. Met. 91, 209(1997), Synth. Met. 111, 421 (2000), SID Symposium Digest, 37, 923 (2006), J. Mater. Chem. 3, 319(1993), Adv. Mater. 6, 677(1994), Chem. Mater. 15, 3148(2003), US Patent Laid-Open No. 2003/0162053, US Patent Laid-Open No. 2002/0158242, US Patent Laid-Open No. 2006/0240279, US Patent Laid-Open No. 2008/0220265, U.S. Pat. No. 5,061,569, WO 2007/002683, WO 2009/018009, EP 650955, US Patent Laid-Open No. 2008/0124572, US Patent Laid-Open No. 2007/0278938, US Patent Laid-Open No. 2008/0106190, US Patent Laid-Open No. 2008/0018221, WO 2012/115034, Japanese Unexamined Patent Application Publication No. 2003-519432, Japanese Patent Laid-Open No. 2006-135145, and U.S. patent application Ser. No. 13/585,981.

### [Electron Blocking Layer]

The electron blocking layer is a layer with a function of the positive hole transport layer in a broad meaning. Preferably, it contains a material having a function of transporting a positive hole, and having very small ability of transporting an electron. By blocking an electron while transporting a positive hole, recombination probability of a positive hole and an electron can be improved.

Further, the construction of the above positive hole transport layer may be employed as the electron blocking layer of the organic EL element 10 as necessary. The electron blocking layer placed in the organic EL element 10 is preferably arranged adjacent to the anode side of the light emitting layer.

A thickness of the electron blocking layer is preferably in the range of 3 to 100 nm, and more preferably in the range of 5 to 30 nm.

With respect to a material used for the electron blocking layer, the material used in the above-described positive hole transport layer is preferably used, and further, the material used as the above-described host compound is also preferably used for the electron blocking layer.

[Positive Hole Injection Layer]

The positive hole injection layer (also referred as “anode buffer layer”) is a layer provided between the anode and the light emitting layer to decrease a driving voltage and to enhance an emission luminance. One example of the electron injection layer is described in volume 2, chapter 2 “Electrode materials” (pp. 123-166) of “Organic EL Elements and Industrialization Front thereof (Nov. 30, 1998, published by N.T.S. Co. Ltd.)”.

The positive hole injection layer is provided as necessary, and as described above, is provided between the anode and the light emitting layer, or between the anode and the positive hole transport layer.

The positive hole injection layer is also described in detail in Japanese Patent Laid-Open Nos. 09-45479, 09-260062 and 08-288069.

Materials used in the positive hole injection layer include, for example, materials used in the above-described positive hole transport layer and the like. Among them, preferable examples include a phthalocyanine derivative represented by copper phthalocyanine, a hexaazatriphenylene derivative described in Japanese Unexamined Patent Application Publication No. 2003-519432 and Japanese Patent Laid-Open No. 2006-135145, a metal oxide represented by vanadium oxide, a conductive polymer such as amorphous carbon, polyaniline (or referred as emeraldine) and polythiophene, an orthometalated complex represented by tris(2-phenylpyridine) iridium complex; and a triarylamine derivative, and the like. The material used for the above positive hole injection layer may be used alone or may be used in combination of two or more kinds.

[Inclusions]

The light emitting unit 14 constituting the organic EL element 10 may further contain other inclusions.

Examples of the inclusion are halogen elements or halogenated compounds such as bromine, iodine and chlorine; a compound, complex and salt of an alkali metal or an alkaline earth metal such as Pd, Ca or Na and of a transition metal; and the like.

A content of the inclusion can be optionally determined, and is preferably 1,000 ppm or less relative to the total mass % of the layer containing the inclusion, more preferably 500 ppm or less, and further preferably 50 ppm or less.

However, the content of the inclusion is not within the above range for the purpose or the like of enhancing the transport property of electrons or positive holes, or advantageously performing energy transfer of exciton.

[Forming Method of Light Emitting Unit]

Hereinafter, the forming method of the light emitting unit 14 of the organic EL element 10 (positive hole injection layer, positive hole transport layer, light emitting layer, positive hole blocking layer, electron transport layer, and electron injection layer and the like) will be explained.

Forming methods of the light emitting unit 14 are not particularly limited, and the light emitting unit 14 can be formed by known methods such as a vacuum vapor deposition method and a wet method (wet process).

Examples of the wet process include a spin coating method, a cast method, an inkjet method, a printing method, a die coating method, a blade coating method, a roll coating method, a spray coating method, a curtain coating method, and an LB method (Langmuir Blodgett method), and the like. From the viewpoint of obtaining a uniform thin film and of high productivity, preferable are methods highly appropriate to a roll-to-roll method such as a die coating method, a roll coating method, an inkjet method, and a spray coating method.

Examples of a liquid medium to dissolve or to disperse a material of the light emitting unit 14 include ketones such as methyl ethyl ketone and cyclohexanone, aliphatic esters such as ethyl acetate, halogenated hydrocarbons such as dichlorobenzene, aromatic hydrocarbons such as toluene, xylene, mesitylene, and cyclohexylbenzene, aliphatic hydrocarbons such as cyclohexane, decalin, and dodecane, organic solvents such as DMF and DMSO. These will be dispersed with dispersion methods such as an ultrasonic dispersion method, a high shearing dispersion method and a media dispersion method.

When the vapor deposition method is adopted for forming each layer constituting the light emitting unit 14, the vapor deposition conditions will change depending on the compounds used, and generally, the following ranges are desirably selected for the conditions, heating temperature of boat: 50° C. to 450° C., level of vacuum: 10⁻⁶ Pa to 10⁻² Pa, vapor deposition rate: 0.01 nm/sec to 50 nm/sec, temperature of substrate: −50° C. to 300° C., and film thickness: 0.1 nm to 5 μm, preferably 5 nm to 200 nm.

Although formation of the organic EL element 10 is preferably continuously carried out from the light emitting unit 14 to the reflective electrode 15 with one-time vacuuming, a different film forming method may be employed by extraction on the way. In such a case, the operation is preferably carried out under a dry inert gas atmosphere. In addition, a different formation may be applied to each layer.

[Reflective Electrode]

In the reflective electrode 15, as described above, it is necessary to use a material having a high reflectance so that the difference between the maximum value and the minimum value of element reflectance of light having a wavelength of 450 nm to 750 nm of the organic EL element 10 is 30% or less. It is further necessary to have a high uniformity and flatness of the surface without interfering with the specific wavelength of the reflected light.

As to the reflective electrode 15, a metal having a small work function (4 eV or less) (referred as an electron injective metal), an alloy, a conductive compound, and an electrode material including a mixture thereof are used as an electrode substance. Specific examples of such an electrode substance include sodium, sodium-potassium alloy, magnesium, lithium, a magnesium/copper mixture, a magnesium/silver mixture, a magnesium/aluminum mixture, a magnesium/indium mixture, an aluminum/aluminum oxide (Al₂O₃) mixture, indium, a lithium/aluminum mixture, aluminum, and a rare earth metal, and the like.

The reflective electrode 15 preferably has a configuration of containing aluminum or silver on the surface of the light emitting unit 14 side because of its particularly high reflectance. As to the reflective electrode 15, it is also possible to form an aluminum layer of approximately 1 nm thickness between the silver and the light emitting unit and to adopt a lamination structure of silver and aluminum. when increasing the reflectance of the reflective electrode 15, it is possible to suppress the wavelength dependency of the organic EL element 10 and to decrease the difference between the maximum value and the minimum value of the element reflectance at light of 450 nm to 750 nm.

The reflective electrode 15 can be produced from the above electrode material by a vapor deposition method, a spattering method, and the like. Furthermore, the sheet resistance of the reflective electrode 15 is preferably several hundred Q/sq. or less. Moreover, the thickness of the reflective electrode 15 is selected in the range of usually 10 nm to 5 μm, preferably 50 nm to 200 nm.

In a case where the layer made of silver or an alloy containing silver as a main component is formed on the surface of the light emitting unit 14 side as the reflective electrode 15, it is preferable to form, as the electron transport layer, the nitrogen-containing layer which contains the above compound having an effective unshared electron pair content [n/M] of 2.0×10⁻³ [n/M], on the layer provided at closest side to the reflective electrode 15 of the light emitting unit 14. When forming the layer containing silver as a main component on the above nitrogen-containing layer, it is possible to enhance the uniformity and flatness of the surface of the reflective electrode 15 on the light emitting unit side. It is possible, by enhancing the uniformity and flatness of the surface of the reflective electrode 15, to suppress the surface absorption at the reflective electrode 15 and the wavelength dependency due to the interference with the specific wavelength. Therefore, the wavelength dependency of the organic EL element 10 can be suppressed and thus the difference between the maximum value and the minimum value of the element reflectance at light of 450 nm to 750 nm can be decreased.

[Other Configurations]

(Light Scattering Layer)

The light scattering layer is preferably a layer having a high refractive index, in which a refractive index at a wavelength of 550 nm is within the range of at least 1.7 or more and less than 2.5. Since the wavelength mode light trapped in the light emitting layer of the organic light emitting element and the plasmon mode light reflected from the reflective electrode are lights of the specific optical modes, it is necessary to have a refractive index of 1.7 or more in order to extract such lights. On the other hand, in the highest order mode of the plazmon mode, there exists almost no light in the area of a refractive index of 2.5 or more, and thus the amount of light to be extracted is not increased even using light having a higher refractive index than that.

In the light scattering layer, a film may be formed by using a sole material or a film having a refractive index of 1.7 or more and less than 2.5 may be formed by mixing two or more kinds of compounds. In the case of the mixed system, the refractive index of the light scattering layer can be substituted by a calculated refractive index calculated from a sum value by multiplying the inherent refractive index of each material by its mixing ratio. Furthermore, in this case, the refractive index of each material may be less than 1.7 or not less than 2.5, and the resulting refractive index of the mixed film may satisfy the range of 1.7 or more and less than 2.5.

Note that the refractive index can be measured by a multiwavelength Abbe refractometer, a prism coupler, a Mickelson interferometer, a spectroscopic ellipsometer, and the like.

Furthermore, the light scattering layer may be a mixed scattering layer (scattering film) by utilizing a refractive index difference of a mixture of a resin and a particle, or may be a shape-controlled scattering layer formed by shape-controlling of a concave and convex structure and the like.

The light scattering layer is a layer that enhances light extraction efficiency, and preferably has light transmittance of 50% or more, more preferably 55% or more, and particularly preferably 60% or more.

### 2. Second Embodiment of Organic Electroluminescent Element

Next, the second embodiment of the organic electroluminescent element will be explained.

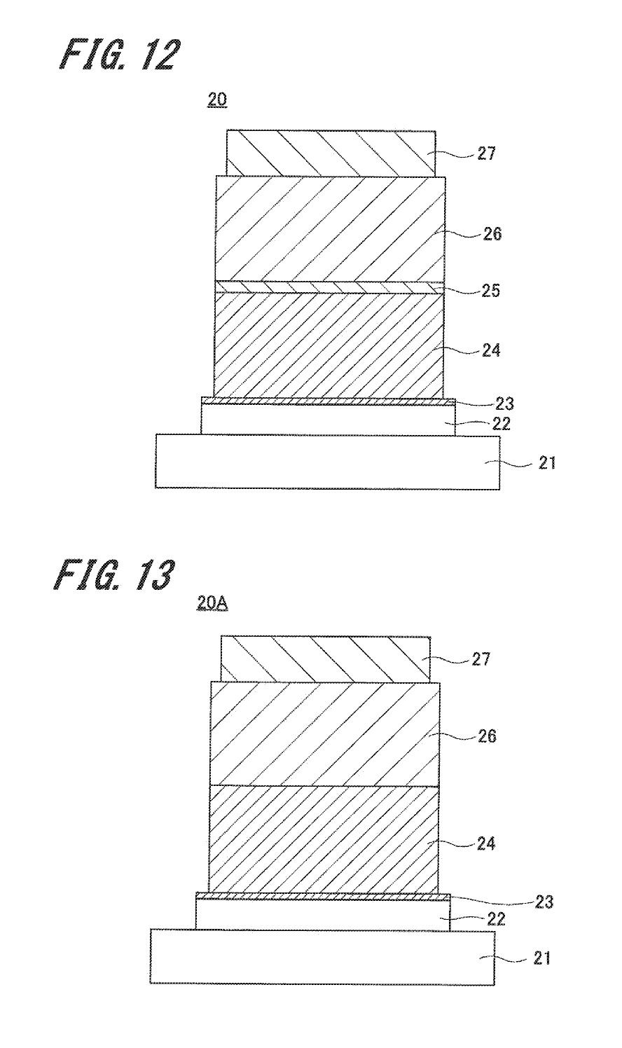

FIG. 12 shows the cross-sectional view of the organic electroluminescent element (organic EL element) of the present embodiment. As shown in FIG. 12, the organic EL element 20 has a so-called tandem structure in which light emitting layers are laminated.

The organic EL element 20 includes a substrate 21, a nitrogen-containing layer 22 provided on the substrate 21, a transparent electrode 23 formed in contact with the nitrogen-containing layer 22, a first light emitting unit 24 provided on the transparent electrode 23, an intermediate layer 25 provided on the first light emitting unit 24, a second light emitting unit 26 provided on the first light emitting unit 24 via the intermediate layer 25, and a reflective electrode 27 provided on the second light emitting unit 26.

In the organic EL element 20, the substrate 21, the nitrogen-containing layer 22, the transparent electrode 23, and the reflective electrode 27 have the same configurations as those in the first embodiment.

In addition, in the organic EL element 20, the total thickness of the first light emitting unit 24, the intermediate layer 25 and the second light emitting unit 26 which are formed between the transparent electrode 23 and the reflective electrode 27 corresponds to the thickness of the light emitting unit in the organic EL element of the above-described first embodiment.

Accordingly, in the organic EL element 20, it is necessary to perform optimization as in the first embodiment in order to decrease the total thickness of the transparent electrode 23, the reflective electrode 27, and the first light emitting unit 24, the intermediate layer 25, and the second light emitting unit 26 to be in the range in which the difference between the maximum value and the minimum value of the element reflectance at light having a wavelength of 450 nm to 750 nm is 30% or less. Since the method for optimizing the configuration is the same as in the first embodiment, explanation is omitted.

The total thickness of the first light emitting unit 24 and the second light emitting unit 26 may be optimized so that the element reflectance difference at light having a wavelength of 450 nm to 750 nm is 30% or less, and the thickness of each layer is not particularly limited. However, considering that the reflection by the intermediate layer 25 exerts influence on the element reflectance, it is preferable that the total thickness of the first light emitting unit 24 and the second light emitting unit 26 is optimized so that the element reflectance difference at light having a wavelength of 450 nm to 750 nm is 30% or less, and that the thickness of the first light emitting unit 24 and the thickness of the second light emitting unit 26 are also optimized respectively according to the simulation. In each case, it is necessary to set the total thickness of the first light emitting unit 24 and the second light emitting unit 26 and the material of the intermediate layer 25, so as to make the difference between the maximum value and the minimum value of element reflectance of light having a wavelength of 450 nm to 750 nm of the organic EL element 20 to be 30% or less.

[Tandem Structure]

Typical element configurations of a tandem structure include the following configurations.

(1) Anode/first light emitting unit/intermediate layer/second light emitting unit/cathode
(2) Anode/first light emitting unit/intermediate layer/second light emitting unit/intermediate layer/third light emitting unit/cathode

Here, the above first light emitting unit, second light emitting unit, and third light emitting unit may be all the same or different from one another. It may be possible that two light emitting units are the same and the remaining one light emitting unit is different. Each light emitting unit can have the same configuration as that in the above first embodiment.

Furthermore, each light emitting unit may be laminated directly or may be laminated via the intermediate layer. For example, the intermediate layer is constituted of an intermediate electrode, an intermediate conductive layer, a charge generating layer, an electron extraction layer, a connecting layer, an intermediate insulating layer, or the like, and a known material configuration can be used as long as the intermediate layer has a function of supplying an electron to an adjacent layer on the anode side, and a positive hole to an adjacent layer on the cathode side.

Specific examples of the tandem type organic EL element include element configuration, configuration materials and the like described in U.S. Pat. No. 6,337,492, U.S. Pat. No. 7,420,203, U.S. Pat. No. 7,473,923, U.S. Pat. No. 6,872,472, U.S. Pat. No. 6,107,734, U.S. Pat. No. 6,337,492, WO 2005/009087, Japanese Patent Laid-Open No. 2006-228712, Japanese Patent Laid-Open No. 2006-24791, Japanese Patent Laid-Open No. 2006-49393, Japanese Patent Laid-Open No. 2006-49394, Japanese Patent Laid-Open No. 2006-49396, Japanese Patent Laid-Open No. 2011-96679, Japanese Patent Laid-Open No. 2005-340187, JP Patent No. 4711424, JP Patent No. 3496681, JP Patent No. 3884564, JP Patent No. 4213169, Japanese Patent Laid-Open No. 2010-192719, Japanese Patent Laid-Open No. 2009-076929, Japanese Patent Laid-Open No. 2008-078414, Japanese Patent Laid-Open No. 2007-059848, Japanese Patent Laid-Open No. 2003-272860, Japanese Patent Laid-Open No. 2003-045676, WO 2005/094130 and the like, but are not limited thereto.

[Intermediate Layer]

In the organic EL element 20 having the tandem structure, it is preferable that the intermediate layer 25 is a layer having a low reflectance and excellent light transmission property as with the transparent electrode 23. The reflectance is low and the transmission property is high, and thus the multiple reflection between the intermediate layer 25 and the reflective electrode 27 and between the intermediate layer 25 and the transparent electrode 23 can be suppressed, and the wavelength dependency and the view angle dependency of the light extracted from the organic EL element 20 can be suppressed.

Examples of materials generally used in the intermediate layer 25 having the tandem structure include conductive inorganic compound layers such as ITO (indium tin oxide), IZO (indium zinc oxide), ZnO₂, TiN, ZrN, HfN, TiOₓ, VO_{X}, CuI, InN, GaN, CuAlO₂, CuGaO₂, SrCu₂O₂, LaB₆, RuO₂, and Al; a two-layer film such as Au/Bi₂O₃; multi-layer films such as SnO₂/Ag/SnO₂, ZnO/Ag/ZnO, Bi₂O₃/Au/Bi₂O₃, TiO₂/TiN/TiO₂, and TiO₂/ZrN/TiO₂; fullerenes such as C60; a conductive organic layer such as oligothiophene; conductive organic compound layers such as metal phthalocyanines, metal-free phthalocyanines, metal porphyrins, and metal-free porphyrins; and the like.

In order to realize the organic EL element 20 in which the element reflectance difference at light having a wavelength of 450 nm to 750 nm is 30% or less, it is preferable that the intermediate layer 25 is formed by using, for example, aluminum, calcium, lithium, or the like to have a thickness of approximately 1 nm. When the intermediate layer 25 is formed to be thin by using these materials, it becomes possible to decrease the reflectance and to enhance the light transmission property. Particularly, it becomes possible to decrease the reflectance and to enhance the light transmission property, by using calcium, lithium or the like.

### Modification

Next, the modification of the organic electroluminescent element of the second embodiment will be explained.

FIG. 13 shows a schematic cross-sectional view of the organic electroluminescent element (organic EL element) of the modification. As shown in FIG. 13, the organic EL element 20A has a configuration in which the intermediate layer is omitted from the tandem structure of the organic EL element of the above second embodiment. Since the organic EL element 20A has the same configuration as the organic EL element 20 of the second embodiment shown in FIG. 12 except for not having the intermediate layer. Therefore, explanation of each layer constituting the organic EL element 20A is omitted.

When employing the configuration of the tandem structure without providing the intermediate layer, the multiple reflection in the organic EL element 20A can be suppressed. For example, the configuration without providing the intermediate layer can be employed by providing a layer that generates an electric charge, obtained by laminating an n-type electron transport layer and a p-type positive hole transport layer between the plurality of laminated light emitting layers. With this configuration, the multiple reflection between the intermediate layer and the reflective electrode 27 or the transparent electrode 23 can be eliminated, and thus the wavelength dependency and the view angle dependency of the light extracted from the organic EL element 20A can be suppressed.

In the organic EL element 20A having the configuration without the intermediate layer, due to the above reason, the element reflectance difference at light having a wavelength of 450 nm to 750 nm becomes easily smaller than that of the organic EL element having the intermediate layer of the second embodiment. Therefore, it is possible to further improve the wavelength dependency and the view angle dependency of the light extracted from the organic EL element 20A.

When not providing an intermediate layer in the tandem structure, since the reflection by the intermediate layer is not required to be considered, the total thickness of the first light emitting unit 24 and the second light emitting unit 26 may be optimized so that the element reflectance difference at light of 450 nm to 750 nm is 30% or less, and the thickness of each layer is not particularly limited.

Furthermore, when not providing an intermediate layer in the tandem structure, it is necessary to employ a configuration in which a layer constituting the interface of the first light emitting unit 24 and the second light emitting unit 26 generates an electric charge. Namely, it is necessary that the layer of the first light emitting unit 24 (uppermost layer) in contact with the second light emitting unit 26 and the layer of the second light emitting unit 26 (lowermost layer) in contact with the first light emitting unit 24 have a configuration that generates an electric charge.

For example, a configuration is such that the generation of the electric charge becomes possible at the interface of the first light emitting unit 24 and the second light emitting unit 26, by forming the n-type electron transport layer on the uppermost layer of the first light emitting unit 24, and forming the p-type positive hole transport layer on the lowermost layer of the second light emitting unit 26.

The n-type electron transport layer includes, for example, an electrode transport layer having a high n-property (electron rich) obtained by doping an n-type impurities as a guest material, capable of being used. Examples of the doping material include metal compounds such as a metal complex and metal halide, and other n-type dopants.

The p-type positive hole transport layer includes, for example, a positive hole transport layer having a high p-property (positive hole rich) obtained by doping a p-type impurities as a guest material, capable of being used. In addition, there can also be used p-type positive hole transport materials, and inorganic compounds such as a p-type-Si and a p-type-SiC.

### Example 1

### Organic EL Element—Cathode Reflectance

Respective organic EL elements of Samples 101 to 112 were produced in the following procedures, and then evaluated.

[Production Procedures of Organic EL Element of Sample 101]

(Substrate)

At first, a transparent supporting glass substrate of 50 mm×50 mm and 0.7 mm thick was subjected to ultrasonic washing with isopropyl alcohol, was dried by a dry nitrogen gas, and was then subjected to UV ozone washing for 5 minutes.

(Anode)

Next, the above transparent support substrate was fixed to a substrate holder of a commercially available vacuum vapor deposition apparatus. Then, each of crucibles for vapor deposition in the vacuum vapor deposition apparatus was filled with a constituent material of each layer of the organic EL element, in a suitable amount for producing each element. The crucible for vapor deposition used was made of a material for resistance heating such as molybdenum or tungsten.

After reducing the pressure to a degree of vacuum of 1×10⁻⁴ Pa, electricity was fed to the crucible for vapor deposition containing Compound U-1 to heat the compound, and was then deposited on the transparent support substrate at a vapor deposition rate of 0.1 nm/sec, with the result that an underlayer having a film thickness of 75 nm was formed.

Subsequently, an anode was formed by vapor deposition of silver on the thus formed underlayer at 0.3 nm/sec in a thickness of 8 nm.

(Light Emitting Unit)

Then, electricity was fed to the crucible for vapor deposition containing Compound M-2 on the thus formed anode to heat the compound, and was then deposited on the transparent support substrate at a vapor deposition rate of 0.1 nm/sec, with the result that a positive hole injection transport layer having a film thickness of 120 nm was formed.

Next, Compound BD-1 and Compound H-1 were co-deposited at a vapor deposition rate of 0.1 nm/sec so that a concentration of Compound BD-1 became 5%, with the result that a fluorescent light emitting layer having a film thickness of 30 nm and exhibiting the emission of light having a blue color was formed.

Furthermore, Compound GD-1, RD-1 and Compound H-2 were co-deposited at a vapor deposition rate of 0.1 nm/sec so that a concentration of Compound GD-1 became 17% and a concentration of Compound RD-1 became 0.8%, with the result that a phosphorescent light emitting layer having a film thickness of 15 nm and exhibiting the emission of light having a yellow color was formed.

Subsequently, a positive hole blocking layer having a film thickness of 5 nm was formed by vapor deposition of Compound E-0 at a vapor deposition rate of 0.1 nm/sec.

After that, Compound E-1 was co-deposited at a vapor deposition rate of 0.1 nm/sec, and potassium fluoride (KF) was co-deposited at a vapor deposition rate of 0.01 nm/sec, with the result that an electron transport layer having a film thickness of 80 nm was formed.

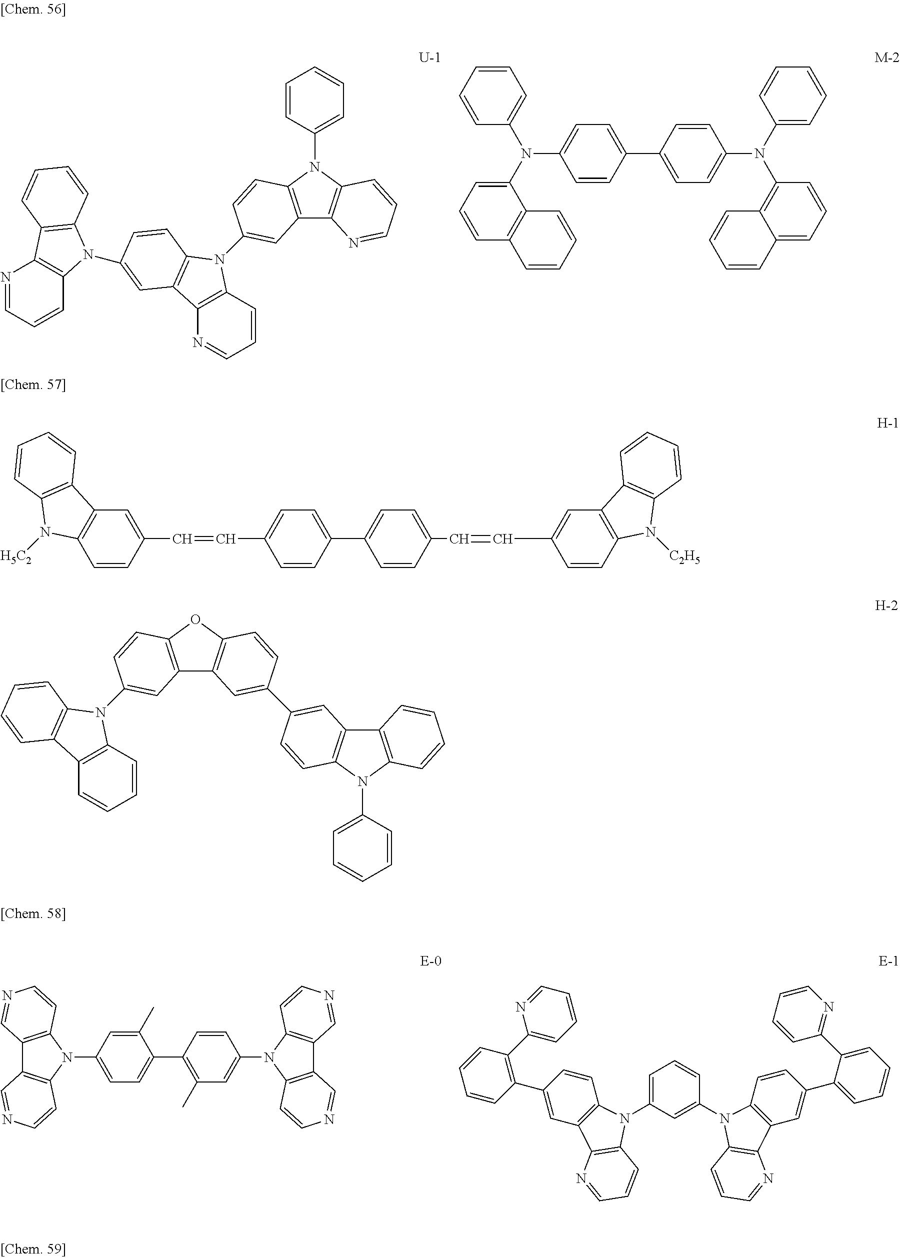

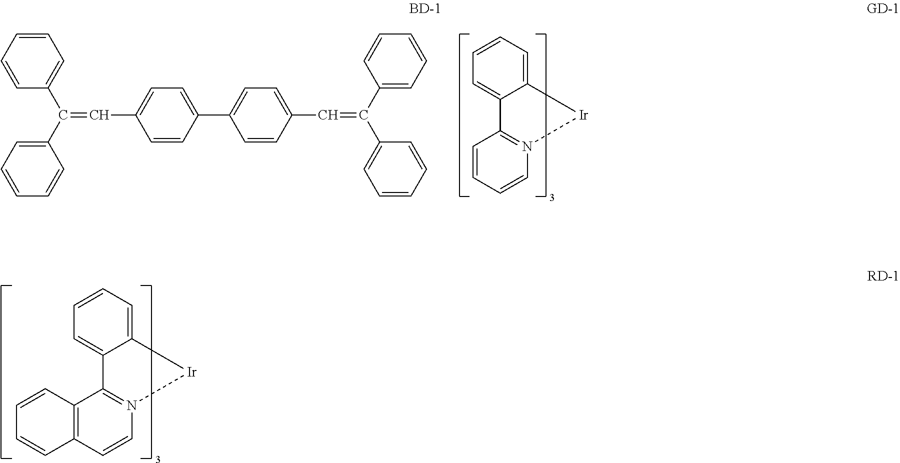

(Cathode)

Next, a cathode having a film thickness of 100 nm was formed by vapor deposition of aluminum on the thus formed electron transport layer of the light emitting unit.

(Sealing)

Finally, an organic EL element of Sample 101 was produced by covering, with a glass case, the non-emitting surface of the organic EL element obtained by forming layers up to the cathode. Note that the light emitting size of the organic EL element was 20×20 mm.

[Production Procedures of Organic EL Elements of Samples 102 to 109]

The organic EL elements of Samples 102 to 109 were produced by using the same procedures as in above-described Sample 101 except that the thickness of the anode was changed to the thickness shown in Table 2 (8 nm, 10 nm, 12 nm), and further that the material of the cathode was changed to the material shown in Table 2 (Al, Ag, Ca).

[Production Procedures of Organic EL Elements of Samples 110 to 112]

The organic EL elements of Samples 110 to 112 were produced by forming a silver film having a thickness of 100 nm, after the thickness of the anode was changed to the thickness shown in Table 2 (8 nm, 10 nm, 12 nm) and furthermore, an aluminum film having a thickness of 1 nm was formed as the cathode by using the vapor deposition method. The organic EL elements of Samples 110 to 112 were produced by using the same procedures as in Sample 101 except for the above changes.

[Measurement]

(Element Reflectance Difference)

The reflectance difference of the element reflectance was obtained by measuring the element reflectance at each wavelength of 450 nm to 750 nm by the method shown in the above FIG. 1, and then by measuring the difference between the maximum value and the minimum value in the element reflectance of the each wavelength (Maximum reflectance %−Minimum reflectance %=Element reflectance difference %).

(Element Efficiency)

An electric current of 30 A/m² was made to flow by using a direct voltage/current generator 6243 manufactured by ADC to the element, and then element efficiency was measured by using CS-2000 manufactured by KONICA MINOLTA.

(View Angle Dependency)

The view angle dependency was obtained, as a difference between the color at the front position and the color at the most different angle, in the following manner.

While rotating the element by 0 degree to 80 degrees at an interval of 5 degrees, the brightness and the chromaticity at each angle were measured. At this time, the shift from the chromaticity of the front position at each angle was obtained from CIEₓ and CIE_{y}. Among the ΔE_{xy}s of respective angles, the largest value was the value of view angle dependency.

ΔE_{xy}=[(x(each angle)−x(0 degree))²+(y(each angle)−y(0 degree))]^{(1/2)}

The configurations of Samples 101 to 112, and the measurement results of the element reflectance difference, the element efficiency, and the view angle dependency are shown in the following Table 2. The results of the quantum efficiency and the view angle dependency are shown as a relative value to those of Sample 101.

TABLE 2

| | Anode | | Cathode | | | | Element | | |
|---|---|---|---|---|---|---|---|---|---|
| | | Film | | Film | Thickness of | Reflectance | efficiency | View angle | |
| | | thickness | | thickness | light emitting | difference | (quantum | dependency | |
| No | Material | nm | Material | nm | unit nm | MAX − MIN | efficiency) | [symbol] Exy | Note |
| 101 | Ag | 8 | Al | 100 | 250 | 28 | 100 | 100 | Present |
| | | | | | | | | | invention |
| 102 | Ag | 10 | Al | 100 | 250 | 33 | 80 | 120 | Comparative |
| | | | | | | | | | example |
| 103 | Ag | 12 | Al | 100 | 250 | 38 | 75 | 125 | Comparative |
| | | | | | | | | | example |
| 104 | Ag | 8 | Ag | 100 | 250 | 13 | 130 | 70 | Present |
| | | | | | | | | | invention |
| 105 | Ag | 10 | Ag | 100 | 250 | 15 | 125 | 75 | Present |
| | | | | | | | | | invention |
| 106 | Ag | 12 | Ag | 100 | 250 | 17 | 120 | 80 | Present |
| | | | | | | | | | invention |
| 107 | Ag | 8 | Ca | 100 | 250 | 34 | 79 | 121 | Comparative |
| | | | | | | | | | example |
| 108 | Ag | 10 | Ca | 100 | 250 | 39 | 74 | 126 | Comparative |
| | | | | | | | | | example |
| 109 | Ag | 12 | Ca | 100 | 250 | 44 | 70 | 130 | Comparative |
| | | | | | | | | | example |
| 110 | Ag | 8 | Al | 1 | 250 | 16 | 123 | 77 | Present |
| | | | Ag | 100 | | | | | invention |
| 111 | Ag | 10 | Al | 1 | 250 | 19 | 118 | 82 | Present |
| | | | Ag | 100 | | | | | invention |
| 112 | Ag | 12 | Al | 1 | 250 | 24 | 105 | 95 | Present |
| | | | Ag | 100 | | | | | invention |

(Evaluation)

From the results shown in Table 2, when the samples having the element reflectance difference is 30% or less, there are obtained the results that the element efficiency is high and further the view angle dependency is small. In contrast to this, when the samples having the element reflectance difference is more than 30%, there are obtained the results that the element efficiency is lowered and the view angle dependency is increased.

Therefore, these results show that the organic EL element having excellent element efficiency and view angle dependency can be realized by setting the difference between the maximum value and the minimum value of element reflectance at light having a wavelength of 450 nm to 750 nm to be 30% or less.

In addition, from the results shown in Table 2, in comparison with the samples having the same cathode configuration, the element reflectance difference becomes large when the thickness of the anode becomes large. It is found from the results show that the light transmission property of the anode exerts influence on the element reflectance difference, and as the light transmission property of the anode becomes higher, the element reflectance becomes lower.

Furthermore, as to the samples having the configuration in which the cathode is made of Ca, the element reflectance difference becomes larger than the samples in which the cathode is made of Al, or Ag. It is found from the results that the reflectance of the cathode exerts influence on the element reflectance difference, and as the reflectance of the cathode becomes higher, the element reflectance difference becomes lower.

### Example 2

### Organic EL Element—Thickness of Light Emitting Unit

Respective organic EL elements of Samples 201 to 212 were produced and evaluated.

Respective organic EL elements of Samples 201 to 212 were produced in the same procedures as in Sample 102 or Sample 105 of the above-described Example 1 except that the thickness of the light emitting unit was changed by adjusting the film thickness of the positive hole injection transport layer as shown in Table 3.

In addition, the element reflectance difference, the element efficiency, and the view angle dependency were measured in the same procedures as in the above-described Example 1. The results of the quantum efficiency and the view angle dependency are obtained as a relative value to those of Sample 101.

The configurations of Samples 201 to 212, and the measured results of the element reflectance difference, the element efficiency, and the view angle dependency are shown in the following Table 3.

TABLE 3

| | Anode | | Cathode | | | | Element | | | |
|---|---|---|---|---|---|---|---|---|---|---|
| | | Film | | Film | Thickness of | Reflectance | efficiency | View angle | | |
| | | thickness | | thickness | light emitting | difference | (quantum | dependency | | |
| No | Material | nm | Material | nm | unit nm | MAX − MIN | efficiency) | [symbol] Exy | Note | Note |
| 201 | Ag | 10 | Al | 100 | 230 | 35 | 78 | 122 | Comparative | |
| | | | | | | | | | example | |
| 202 | Ag | 10 | Al | 100 | 250 | 33 | 80 | 120 | Comparative | Same as |
| | | | | | | | | | example | No. 102 |
| 203 | Ag | 10 | Al | 100 | 270 | 29 | 98 | 101 | Present | |
| | | | | | | | | | invention | |
| 204 | Ag | 10 | Al | 100 | 290 | 27 | 101 | 99 | Present | |
| | | | | | | | | | invention | |
| 205 | Ag | 10 | Al | 100 | 310 | 29 | 98 | 101 | Present | |
| | | | | | | | | | invention | |
| 206 | Ag | 10 | Al | 100 | 330 | 36 | 77 | 123 | Comparative | |
| | | | | | | | | | example | |
| 207 | Ag | 10 | Ag | 100 | 230 | 16 | 120 | 80 | Present | |
| | | | | | | | | | invention | |
| 208 | Ag | 10 | Ag | 100 | 250 | 15 | 125 | 75 | Present | Same as |
| | | | | | | | | | invention | No. 105 |
| 209 | Ag | 10 | Ag | 100 | 270 | 17 | 120 | 80 | Present | |
| | | | | | | | | | invention | |
| 210 | Ag | 10 | Ag | 100 | 290 | 19 | 117 | 93 | Present | |
| | | | | | | | | | invention | |
| 211 | Ag | 10 | Ag | 100 | 310 | 27 | 101 | 99 | Present | |
| | | | | | | | | | invention | |
| 212 | Ag | 10 | Ag | 100 | 330 | 22 | 108 | 90 | Present | |
| | | | | | | | | | invention | |

(Evaluation)

From the results shown in Table 3, when the samples having the element reflectance difference is 30% or less, there are obtained the results that the element efficiency is high and further the view angle dependency is small. In contrast to this, when the samples having the element reflectance difference is more than 30%, there are obtained the results that the element efficiency is lowered and the view angle dependency is increased.

Further from the results shown in Table 3, in comparison with the samples having the configuration in which the same cathode and the anode were used, it is found that the element reflectance difference is increased and decreased depending on the thickness of the light emitting unit even if the configurations other than the thickness of the light emitting unit are the same. This is considered to be caused by the wavelength dependency of the element reflectance difference at the same thickness of the light emitting unit, and the dependency of the element reflectance difference on the thickness of the light emitting unit, in the same simulation as in the above-described FIG. 6.

Therefore, from the results shown in Table 3, it is found that the thickness of the light emitting unit exerts influences on the element reflectance at each wavelength.

Moreover, also when the thickness of the light emitting unit exerts influences on the element reflectance difference at each wavelength, the organic EL element having excellent element efficiency and view angle dependency can be realized by setting the difference between the maximum value and the minimum value of element reflectance at light having a wavelength of 450 nm to 750 nm to be 30% or less.

### Example 3

### Organic EL Element—Light Scattering Layer

Respective organic EL elements of Samples 301 to 322 were produced and evaluated.

Samples 301 to 322 were produced in the same procedures as in the above Samples 101 to 112 of Example 1 and Samples 201, 203 to 207, 209 to 212 of Example 2 except that the following light scattering layer was formed on the substrate and the anode was formed on the light scattering layer.

In Table 4, the respective sample numbers of Example 1 and Example 2 corresponding to the configurations of the organic EL elements of Samples 301 to 322 are shown.

(Light Scattering Layer)

After spin-coating (500 rpm, 30 seconds) a dispersion for constituting the light scattering layer on the above transparent support substrate, the resulting film was simply dried (80° C., 2 minutes), and then baked (120° C., 60 minutes), with the result that the light scattering layer having a film thickness of 700 nm was formed.

(Production Method of Dispersion)

The dispersion was prescription-designed, as a solution for the light scattering layer, in an amount of 10 ml so that the solid ratio of: TiO₂ particles having a refractive index of 2.4 and an average particle size of 0.25 μm (JR600A, manufactured by Tayca); to a resin solution (ED230AL (organic inorganic hybrid resin) manufactured by APM corporation) is 70 volume %/30 volume %, the solvent ratio of n-propyl acetate to cyclohexanone is 10 wt %/90 wt %, and a solid content is 15 wt %.

Specifically, the TiO₂ dispersion was produced by mixing the above TiO₂ particles and the solvents, and by performing dispersion for 10 minutes in the ultrasonic dispersing apparatus (UH-50 manufactured by SMT corporation) under standard conditions of the micro tip step (MS-3 3 mmφ manufactured by SMT corporation), while cooling at normal temperature.

Next, the resin was mixed/added little by little to the TiO2 dispersion while stirring at 100 rpm, and after completing the addition, the stirring rate was raised up to 500 rpm, and stirring was performed for 10 minutes, with the result that a light scattering layer coating solution was obtained.

Thereafter, the desired dispersion was obtained by filtrating with a hydrophobic PVDF 0.45 μm filter (manufactured by Whatman).

As to the thus produced Samples 301 to 322, the element reflectance difference, the improving rate of the element efficiency, and the view angle dependency were measured in the same way as in the above Example 1. Note that the improving rate of efficiency was obtained by a relative value of samples 301 to 322 in which the light scattering layer was formed, to the corresponding samples of Example 1 or Example 2 having configurations in which the light scattering layer was not formed, i.e. [Improving rate of efficiency=(Device with light scattering layer/Corresponding device without light scattering layer)×100]. In addition, the results of the view angle dependency are obtained as a relative value to that of Sample 101.

The configurations of Samples 301 to 322, and the measured results of the element reflectance difference, the improving rate of the element efficiency, and the view angle dependency are shown in the following Table 4.

TABLE 4

| | Corresponding | Anode | | Cathode | | | | | | |
|---|---|---|---|---|---|---|---|---|---|---|
| | device (no | | Film | | Film | Thickness of | Reflectance | Improving | View angle | |
| | light scattering | | thickness | | thickness | light emitting | difference | rate of | dependency | |
| No | layer) | Material | nm | Material | nm | unit nm | MAX − MIN | efficiency | [symbol] Exy | Note |
| 301 | No101 | Ag | 8 | Al | 100 | 250 nm | 28 | 150 | 25 | Present |
| | | | | | | | | | | invention |
| 302 | No102 | Ag | 10 | Al | 100 | 250 nm | 33 | 120 | 40 | Comparative |
| | | | | | | | | | | example |
| 303 | No103 | Ag | 12 | Al | 100 | 250 nm | 38 | 112 | 42 | Comparative |
| | | | | | | | | | | example |
| 304 | No104 | Ag | 8 | Ag | 100 | 250 nm | 13 | 200 | 18 | Present |
| | | | | | | | | | | invention |
| 305 | No105 | Ag | 10 | Ag | 100 | 250 nm | 15 | 190 | 19 | Present |
| | | | | | | | | | | invention |
| 306 | No106 | Ag | 12 | Ag | 100 | 250 nm | 17 | 180 | 20 | Present |
| | | | | | | | | | | invention |
| 307 | No107 | Ag | 8 | Ca | 100 | 250 nm | 34 | 119 | 40 | Comparative |
| | | | | | | | | | | example |
| 308 | No108 | Ag | 10 | Ca | 100 | 250 nm | 39 | 112 | 42 | Comparative |
| | | | | | | | | | | example |
| 309 | No109 | Ag | 12 | Ca | 100 | 250 nm | 44 | 110 | 43 | Comparative |
| | | | | | | | | | | example |
| 310 | No110 | Ag | 8 | Al | 1 | 250 nm | 16 | 185 | 19 | Present |
| | | | | Ag | 100 | | | | | invention |
| 311 | No111 | Ag | 10 | Al | 1 | 250 nm | 19 | 170 | 20 | Present |
| | | | | Ag | 100 | | | | | invention |
| 312 | No112 | Ag | 12 | Al | 1 | 250 nm | 24 | 160 | 23 | Present |
| | | | | Ag | 100 | | | | | invention |
| 313 | No201 | Ag | 10 | Al | 100 | 230 nm | 35 | 118 | 41 | Comparative |
| | | | | | | | | | | example |
| 314 | No203 | Ag | 10 | Al | 100 | 270 nm | 29 | 148 | 25 | Present |
| | | | | | | | | | | invention |
| 315 | No204 | Ag | 10 | Al | 100 | 290 nm | 27 | 152 | 25 | Present |
| | | | | | | | | | | invention |
| 316 | No205 | Ag | 10 | Al | 100 | 310 nm | 29 | 148 | 25 | Present |
| | | | | | | | | | | invention |
| 317 | No206 | Ag | 10 | Al | 100 | 330 nm | 36 | 115 | 41 | Comparative |
| | | | | | | | | | | example |
| 318 | No207 | Ag | 10 | Ag | 100 | 230 nm | 16 | 185 | 20 | Present |
| | | | | | | | | | | invention |
| 319 | No209 | Ag | 10 | Ag | 100 | 270 nm | 17 | 180 | 20 | Present |
| | | | | | | | | | | invention |
| 320 | No210 | Ag | 10 | Ag | 100 | 290 nm | 19 | 170 | 23 | Present |
| | | | | | | | | | | invention |
| 321 | No211 | Ag | 10 | Ag | 100 | 310 nm | 27 | 152 | 24 | Present |
| | | | | | | | | | | invention |
| 322 | No212 | Ag | 10 | Ag | 100 | 330 nm | 22 | 163 | 22 | Present |
| | | | | | | | | | | invention |

(Evaluation)

From the results shown in Table 4, when the samples having the element reflectance difference is 30% or less, there are obtained the results that the improving rate of the element efficiency is high and furthermore, the view angle dependency is small. In contrast to this, when the samples having the element reflectance difference is more than 30%, there are obtained the results that the improving rate of the element efficiency is lowered and the view angle dependency is increased.

Therefore, these results show that the organic EL element having excellent element efficiency and view angle dependency can be realized by setting the difference between the maximum value and the minimum value of element reflectance at light having a wavelength of 450 nm to 750 nm to be 30% or less.

Particularly, it is found that the view angle dependency was divided into the samples of 25 or less and into the samples of 40 or more, with the boundary of the element reflectance difference being set to 30%. Specifically, the samples having an element reflectance difference of 30% or less have a view angle dependency of 18 to 25, whereas the samples having an element reflectance difference of more than 30% have a view angle dependency of 40 to 43. Remarkably, Sample 304 having an element reflectance difference of 13% has a view angle dependency of 18, Sample 311 having an element reflectance difference of 19% has a view angle dependency of 20, and Sample 314 having an element reflectance difference of 29% has a view angle dependency of 25, whereas a view angle dependency of Sample 302 having an element reflectance difference of 33% is increased to 40. Namely, even the element reflectance difference is increased from 13% to 29% by 16 points, the view angle dependency is increased only from 18 to 25. On the other hand, when the element reflectance difference is increased across 30%, i.e. when the element reflectance difference is increased from 29% to 33% by only 4 points, the view angle dependency is increased from 25 to 40.

It is found from these results that, when the element reflectance difference exceeds 30%, the view angle dependency of the organic EL element becomes drastically worse. Therefore, from the results shown in Table 4, the organic EL element having excellent view angle dependency can be realized by setting the difference between the maximum value and the minimum value of element reflectance at light having a wavelength of 450 nm to 750 nm to be 30% or less.

### Example 4

### Organic EL Element—Intermediate Layer (Tandem)

Respective organic EL elements of Samples 401 to 412 were produced and evaluated in the following procedures.

[Production Procedures of Organic EL Element of Samples 401 to 412]

(Substrate to Anode)

The anode was formed on the transparent support substrate in the same way as in Sample 102 of the above Example 1.

(First Light Emitting Unit)

First, electricity was fed to the crucible for vapor deposition containing Compound M-2 on the thus formed anode to heat the compound, and was then deposited on the transparent support substrate at a vapor deposition rate of 0.1 nm/sec, with the result that a positive hole injection transport layer having a film thickness of 120 nm was formed.

Next, Compound BD-1 and Compound H-1 were co-deposited at a vapor deposition rate of 0.1 nm/sec so that a concentration of Compound BD-1 became 5%, with the result that a fluorescent light emitting layer having a film thickness of 30 nm which emitted blue light was formed.

Then, a positive hole blocking layer having a film thickness of 5 nm was formed by vapor deposition of Compound E-0 at a vapor deposition rate of 0.1 nm/sec.

Furthermore, Compound E-1 was co-deposited at a vapor deposition rate of 0.1 nm/sec, and potassium fluoride (KF) was co-deposited at a vapor deposition rate of 0.01 nm/sec, with the result that an electron transport layer having a film thickness of 45 nm was formed.

(Intermediate Layer)

Next, the intermediate layer having a thickness of 1 to 4 nm was formed using aluminum, lithium or calcium, at 0.05 nm/sec.

However, an intermediate layer was not formed in Sample 412.

(Second Light Emitting Unit)

A positive hole injection layer having a film thickness of 15 nm was formed on the intermediate layer by vapor deposition of Compound M-1 at a vapor deposition rate of 0.1 nm/sec.

Furthermore, electricity was fed to the crucible for vapor deposition containing Compound M-2 to heat the compound, and was then deposited on the transparent support substrate at a vapor deposition rate of 0.1 nm/sec, with the result that a positive hole injection transport layer having a film thickness of 120 nm was formed.

Next, Compound GD-1, RD-1 and Compound H-2 were co-deposited at a vapor deposition rate of 0.1 nm/sec so that a concentration of Compound GD-1 was 17% and a concentration of Compound RD-1 was 0.8%, with the result that a phosphorescent light emitting layer having a film thickness of 15 nm emitting a yellow light was formed.

Next, a positive hole blocking layer having a film thickness of 5 nm was formed by vapor deposition of Compound E-0 at a vapor deposition rate of 0.1 nm/sec.

After that, Compound E-1 was co-deposited at a vapor deposition rate of 0.1 nm/sec, and potassium fluoride (KF) was co-deposited at a vapor deposition rate of 0.01 nm/sec, with the result that an electron transport layer having a film thickness of 45 nm was formed.

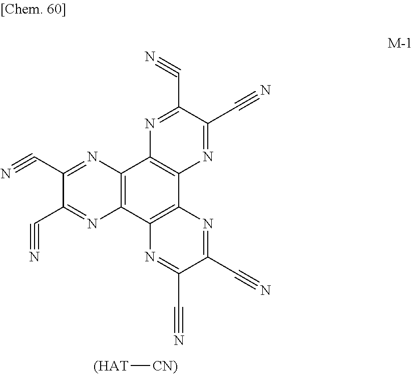

(Cathode)

Next, a cathode having a film thickness of 100 nm was formed by vapor deposition of silver on the thus formed electron transport layer of the light emitting unit.

(Sealing)

Finally, the non-emitting surface of the organic EL element obtained by forming the layers up to the cathode was covered with a glass case, with the result that organic EL elements of Samples 401 to 412 were produced. The light emitting size of each of the organic EL elements was 20×20 mm.

As to the thus produced Samples 401 to 412, the element reflectance difference, the element efficiency, and the view angle dependency were measured in the same procedures as in above-described Example 1. The results of the quantum efficiency and the view angle dependency are obtained as a relative value to those of Sample 401.

The configurations of Samples 401 to 412, and the measured results of the element reflectance difference, the element efficiency, and the view angle dependency are shown in the following Table 5.

TABLE 5

| | | | | | Thickness | | | Thickness | | | | |
|---|---|---|---|---|---|---|---|---|---|---|---|---|
| | Anode | | Cathode | | of first | Material | | of second | Reflectance | Element | | |
| | | Film | | Film | light | of inter- | Film | light | difference | efficiency | View angle | |
| | | thickness | | thickness | emitting | mediate | thickness | emitting | MAX − | (quantum | dependency | |
| No | Material | nm | Material | nm | unit nm | layer | nm | unit nm | MIN | efficiency) | [symbol] Exy | Note |
| 401 | Ag | 10 | Ag | 100 | 200 | Al | 1 | 200 | 51 | 100 | 100 | Comparative |
| | | | | | | | | | | | | example |
| 402 | Ag | 10 | Ag | 100 | 200 | Al | 2 | 200 | 70 | 70 | 130 | Comparative |
| | | | | | | | | | | | | example |
| 403 | Ag | 10 | Ag | 100 | 200 | Al | 3 | 200 | 79 | 65 | 135 | Comparative |
| | | | | | | | | | | | | example |
| 404 | Ag | 10 | Ag | 100 | 200 | Li | 1 | 200 | 17 | 165 | 35 | Present |
| | | | | | | | | | | | | invention |
| 405 | Ag | 10 | Ag | 100 | 200 | Li | 2 | 200 | 22 | 160 | 40 | Present |
| | | | | | | | | | | | | invention |
| 406 | Ag | 10 | Ag | 100 | 200 | Li | 3 | 200 | 27 | 155 | 45 | Present |
| | | | | | | | | | | | | invention |
| 407 | Ag | 10 | Ag | 100 | 200 | Li | 4 | 200 | 31 | 130 | 70 | Comparative |
| | | | | | | | | | | | | example |
| 408 | Ag | 10 | Ag | 100 | 200 | Ca | 1 | 200 | 18 | 162 | 37 | Present |
| | | | | | | | | | | | | invention |
| 409 | Ag | 10 | Ag | 100 | 200 | Ca | 2 | 200 | 24 | 157 | 43 | Present |
| | | | | | | | | | | | | invention |
| 410 | Ag | 10 | Ag | 100 | 200 | Ca | 3 | 200 | 30 | 150 | 50 | Present |
| | | | | | | | | | | | | invention |
| 411 | Ag | 10 | Ag | 100 | 200 | Ca | 4 | 200 | 35 | 120 | 80 | Comparative |
| | | | | | | | | | | | | example |
| 412 | Ag | 10 | Ag | 100 | 200 | None | — | 200 | 13 | 170 | 30 | Present |
| | | | | | | | | | | | | invention |

(Evaluation)

From the results shown in Table 5, when the samples having the element reflectance difference is 30% or less, there are obtained the results that the element efficiency is high and further the view angle dependency is small. In contrast to this, when the samples having the element reflectance difference is more than 30%, there are obtained the results that the element efficiency is lowered and the view angle dependency is increased.

Therefore, these results show that the organic EL element having excellent element efficiency and view angle dependency can be realized by setting the difference between the maximum value and the minimum value of element reflectance at light having a wavelength of 450 nm to 750 nm to be 30% or less.

As to the sample obtained by using Al for the intermediate layer, the element reflectance difference is large, and thus the element efficiency and the view angle dependency are greatly lowered. This is considered to have been caused by the fact that the multiple reflection via the intermediate layer was generated and the view angle dependency became worse, since Al has a high reflectance and a low light transmission property.

Furthermore, as to the samples obtained by forming Li or Ca for the intermediate layer, it can be seen that the sample having a small film thickness tends to have a small element reflectance difference, and the sample having a large film thickness tends to have a large element reflectance difference. This is considered to be caused by the fact that the light transmission property of the intermediate layer is improved by the small film thickness of the intermediate layer, and the generation of the multiple reflection via the intermediate layer can be suppressed.

Particularly, Sample 412 without provision of the intermediate layer has the smallest element reflectance difference, and gives the best results of the element efficiency and the view angle dependency. From the results, it is considered that the configuration is such that the organic EL element has an intermediate layer having a low reflectance and a high light transmission property, especially no intermediate layer, and thus the multiple reflection via the intermediate layer in the organic EL element can be suppressed, and the view angle dependency of the organic EL element can be enhanced.

### Example 5

### Organic EL Element—Thickness of Light Emitting Unit (Tandem)

Respective organic EL elements of Samples 501 to 518 were produced and evaluated.

Respective organic EL element of Samples 501 to 518 were produced in the same procedures as in Sample 406 or Sample 412 of Example 4 except that the thicknesses of the first light emitting unit and the second light emitting unit were varied by adjusting the thickness of the positive hole injection transport layer, as shown in Table 6.

Then, the element reflectance difference, the element efficiency, and the view angle dependency were measured in the same procedures as in Example 1. Note that the results of the quantum efficiency and the view angle dependency are obtained as a relative value to those of Sample 401.

The configurations of Samples 501 to 518, and the measurement results of the element reflectance difference, the element efficiency, and the view angle dependency are shown in the following Table 6.

TABLE 6

| | Anode | | Cathode | | Thickness | | | Thickness | | | | | |
|---|---|---|---|---|---|---|---|---|---|---|---|---|---|
| | | Film | | Film | of first | Material | Film | of second | Reflectance | Element | | | |
| | | thick- | | thick- | light | of inter- | thick- | light | difference | efficiency | View angle | | |
| | Mate- | ness | Mate- | ness | emitting | mediate | ness | emitting | MAX − | (quantum | dependency | | |
| No | rial | nm | rial | nm | unit nm | layer | nm | unit nm | MIN | efficiency) | [symbol] Exy | Note | Note |
| 501 | Ag | 10 | Ag | 100 | 160 | Li | 3 nm | 200 | 29 | 152 | 48 | Comparative | |
| | | | | | | | | | | | | example | |
| 502 | Ag | 10 | Ag | 100 | 180 | Li | 3 nm | 200 | 31 | 130 | 70 | Present | |
| | | | | | | | | | | | | invention | |
| 503 | Ag | 10 | Ag | 100 | 200 | Li | 3 nm | 200 | 27 | 155 | 45 | Comparative | Same as |
| | | | | | | | | | | | | example | No. 406 |
| 504 | Ag | 10 | Ag | 100 | 220 | Li | 3 nm | 200 | 27 | 155 | 45 | Comparative | |
| | | | | | | | | | | | | example | |
| 505 | Ag | 10 | Ag | 100 | 240 | Li | 3 nm | 200 | 27 | 155 | 45 | Comparative | |
| | | | | | | | | | | | | example | |
| 506 | Ag | 10 | Ag | 100 | 200 | Li | 3 nm | 160 | 28 | 153 | 57 | Comparative | |
| | | | | | | | | | | | | example | |
| 507 | Ag | 10 | Ag | 100 | 200 | Li | 3 nm | 180 | 31 | 130 | 70 | Present | |
| | | | | | | | | | | | | invention | |
| 508 | Ag | 10 | Ag | 100 | 200 | Li | 3 nm | 220 | 26 | 157 | 53 | Comparative | |
| | | | | | | | | | | | | example | |
| 509 | Ag | 10 | Ag | 100 | 200 | Li | 3 nm | 240 | 24 | 157 | 53 | Comparative | |
| | | | | | | | | | | | | example | |
| 510 | Ag | 10 | Ag | 100 | 160 | None | — | 200 | 17 | 165 | 35 | Comparative | |
| | | | | | | | | | | | | example | |
| 511 | Ag | 10 | Ag | 100 | 180 | None | — | 200 | 16 | 167 | 33 | Comparative | |
| | | | | | | | | | | | | example | |
| 512 | Ag | 10 | Ag | 100 | 200 | None | — | 200 | 13 | 170 | 30 | Comparative | Same as |
| | | | | | | | | | | | | example | No. 412 |
| 513 | Ag | 10 | Ag | 100 | 220 | None | — | 200 | 27 | 155 | 45 | Comparative | |
| | | | | | | | | | | | | example | |
| 514 | Ag | 10 | Ag | 100 | 240 | None | — | 200 | 25 | 157 | 53 | Comparative | |
| | | | | | | | | | | | | example | |
| 515 | Ag | 10 | Ag | 100 | 200 | None | — | 160 | 17 | 165 | 35 | Comparative | |
| | | | | | | | | | | | | example | |
| 516 | Ag | 10 | Ag | 100 | 200 | None | — | 180 | 16 | 167 | 33 | Comparative | |
| | | | | | | | | | | | | example | |
| 517 | Ag | 10 | Ag | 100 | 200 | None | — | 220 | 27 | 165 | 35 | Comparative | |
| | | | | | | | | | | | | example | |
| 518 | Ag | 10 | Ag | 100 | 200 | None | — | 240 | 25 | 157 | 53 | Comparative | |
| | | | | | | | | | | | | example | |

(Evaluation)

From the results shown in Table 6, when the samples having the element reflectance difference is 30% or less, there are obtained the results that the element efficiency is high and further the view angle dependency is small. In contrast to this, when the samples having the element reflectance difference is more than 30%, there are obtained the results that the element efficiency is lowered and the view angle dependency is increased.

Furthermore, from the results shown in Table 6, in comparison with the samples having the configuration obtained by using the same cathode, the anode and the intermediate layer, even if the configurations other than the thickness of the light emitting unit are the same, it is found that the element reflectance difference is increased and decreased depending on the thickness of the light emitting unit.

Moreover, in each sample, even if the thickness of the first light emitting unit and the thickness of the second light emitting unit are varied, when the total thickness of the emitting unit of each sample is the same, the same results are obtained. Namely, from the results shown in Table 6, it is found that the element reflectance difference depends on the total thickness of the light emitting unit.

Therefore, from the results shown in Table 6, the thickness of the light emitting unit exerts influence on the element reflectance at each wavelength.

In addition, also when the thickness of the light emitting unit exerts influence on the element reflectance difference at each wavelength, the organic EL element having excellent element efficiency and view angle dependency can be realized by setting the difference between the maximum value and the minimum value of element reflectance at light having a wavelength of 450 nm to 750 nm to be 30% or less.

### Example 6

### Organic EL Element—Light Scattering Layer (Tandem)

Respective organic EL elements of Samples 601 to 628 were produced and evaluated.

Samples 601 to 628 were produced in the same procedures as in the above Samples 401 to 412 of Example 4 and Samples 501, 502, 504 to 511, and 513 to 518 of Example 5 except that the following light scattering layer was formed on the substrate and the anode was formed on the light scattering layer.

The light scattering layer was produced in the same procedures in Sample 301 of the above Example 3.

In Table 7, the respective sample numbers of Example 4 and Example 5 corresponding to the configurations of the organic EL elements of Samples 601 to 628 are shown.

As to the thus produced Samples 601 to 628, the element reflectance difference, the improving rate of the element efficiency, and the view angle dependency were measured in the same way as in the above Example 1 and Example 3. Note that the improving rate of efficiency was obtained by a relative value of samples 601 to 628 in which the light scattering layer was formed, to the corresponding samples of Example 4 or Example 5 having configurations in which the light scattering layer was not formed, i.e. [Improving rate of efficiency=(Device with light scattering layer/Corresponding device without light scattering layer)×100]. In addition, the results of the view angle dependency are obtained as a relative value to that of Sample 401.

The configurations of Samples 601 to 628, and the measured results of the element reflectance difference, the improving rate of the element efficiency, and the view angle dependency are shown in the following Table 7.

TABLE 7

| | Corre- | | | | | | | | | | | | |
|---|---|---|---|---|---|---|---|---|---|---|---|---|---|
| | sponding | Anode | | Cathode | | Thickness | Mate- | | Thickness | | | | |
| | device | | Film | | Film | of first | rial of | Film | of second | Reflectance | | | |
| | (no light | | thick- | | thick- | light | inter- | thick- | light | difference | Improving | View angle | |
| | scattering | Mate- | ness | Mate- | ness | emitting | mediate | ness | emitting | MAX − | rate of | dependency | |
| No | layer) | rial | nm | rial | nm | unit nm | layer | nm | unit nm | MIN | efficiency | [symbol] Exy | Note |
| 601 | No 401 | Ag | 10 | Ag | 100 | 200 | Al | 1 | 200 | 51 | 103 | 33 | Comparative |
| | | | | | | | | | | | | | example |
| 602 | No 402 | Ag | 10 | Ag | 100 | 200 | Al | 2 | 200 | 70 | 100 | 43 | Comparative |
| | | | | | | | | | | | | | example |
| 603 | No 403 | Ag | 10 | Ag | 100 | 200 | Al | 3 | 200 | 79 | 100 | 45 | Comparative |
| | | | | | | | | | | | | | example |
| 604 | No 404 | Ag | 10 | Ag | 100 | 200 | Li | 1 | 200 | 17 | 180 | 9 | Present |
| | | | | | | | | | | | | | invention |
| 605 | No 405 | Ag | 10 | Ag | 100 | 200 | Li | 2 | 200 | 22 | 165 | 10 | Present |
| | | | | | | | | | | | | | invention |
| 606 | No 406 | Ag | 10 | Ag | 100 | 200 | Li | 3 | 200 | 27 | 151 | 15 | Present |
| | | | | | | | | | | | | | invention |
| 607 | No 407 | Ag | 10 | Ag | 100 | 200 | Li | 4 | 200 | 31 | 121 | 26 | Comparative |
| | | | | | | | | | | | | | example |
| 608 | No 408 | Ag | 10 | Ag | 100 | 200 | Ca | 1 | 200 | 18 | 178 | 11 | Present |
| | | | | | | | | | | | | | invention |
| 609 | No 409 | Ag | 10 | Ag | 100 | 200 | Ca | 2 | 200 | 24 | 160 | 12 | Present |
| | | | | | | | | | | | | | invention |
| 610 | No 410 | Ag | 10 | Ag | 100 | 200 | Ca | 3 | 200 | 30 | 142 | 20 | Present |
| | | | | | | | | | | | | | invention |
| 611 | No 411 | Ag | 10 | Ag | 100 | 200 | Ca | 4 | 200 | 35 | 117 | 27 | Comparative |
| | | | | | | | | | | | | | example |
| 612 | No 412 | Ag | 10 | Ag | 100 | 200 | None | — | 200 | 13 | 193 | 8 | Present |
| | | | | | | | | | | | | | invention |
| 613 | No501 | Ag | 10 | Ag | 100 | 160 | Li | 3 | 200 | 29 | 145 | 12 | Present |
| | | | | | | | | | | | | | invention |
| 614 | No502 | Ag | 10 | Ag | 100 | 180 | Li | 3 | 200 | 31 | 121 | 23 | Comparative |
| | | | | | | | | | | | | | example |
| 615 | No504 | Ag | 10 | Ag | 100 | 220 | Li | 3 | 200 | 27 | 151 | 12 | Present |
| | | | | | | | | | | | | | invention |
| 616 | No505 | Ag | 10 | Ag | 100 | 240 | Li | 3 | 200 | 27 | 151 | 12 | Present |
| | | | | | | | | | | | | | invention |
| 617 | No506 | Ag | 10 | Ag | 100 | 200 | Li | 3 | 160 | 28 | 149 | 14 | Present |
| | | | | | | | | | | | | | invention |
| 618 | No507 | Ag | 10 | Ag | 100 | 200 | Li | 3 | 180 | 31 | 121 | 23 | Comparative |
| | | | | | | | | | | | | | example |
| 619 | No508 | Ag | 10 | Ag | 100 | 200 | Li | 3 | 220 | 26 | 154 | 13 | Present |
| | | | | | | | | | | | | | invention |
| 620 | No509 | Ag | 10 | Ag | 100 | 200 | Li | 3 | 240 | 24 | 160 | 13 | Present |
| | | | | | | | | | | | | | invention |
| 621 | No510 | Ag | 10 | Ag | 100 | 160 | None | — | 200 | 17 | 181 | 8 | Present |
| | | | | | | | | | | | | | invention |
| 622 | No511 | Ag | 10 | Ag | 100 | 180 | None | — | 200 | 16 | 184 | 8 | Present |
| | | | | | | | | | | | | | invention |
| 623 | No513 | Ag | 10 | Ag | 100 | 220 | None | — | 200 | 27 | 152 | 11 | Present |
| | | | | | | | | | | | | | invention |
| 624 | No514 | Ag | 10 | Ag | 100 | 240 | None | — | 200 | 25 | 158 | 13 | Present |
| | | | | | | | | | | | | | invention |
| 625 | No515 | Ag | 10 | Ag | 100 | 200 | None | — | 160 | 17 | 181 | 8 | Present |
| | | | | | | | | | | | | | invention |
| 626 | No516 | Ag | 10 | Ag | 100 | 200 | None | — | 180 | 16 | 184 | 8 | Present |
| | | | | | | | | | | | | | invention |
| 627 | No517 | Ag | 10 | Ag | 100 | 200 | None | — | 220 | 27 | 151 | 8 | Present |
| | | | | | | | | | | | | | invention |
| 628 | No518 | Ag | 10 | Ag | 100 | 200 | None | — | 240 | 25 | 158 | 13 | Present |
| | | | | | | | | | | | | | invention |

(Evaluation)

From the results shown in Table 7, when the samples having the element reflectance difference is 30% or less, there are obtained the results that the improving rate of the element efficiency is high and furthermore, the view angle dependency is small. In contrast to this, when the samples having the element reflectance difference is more than 30%, there are obtained the results that the improving rate of the element efficiency is lowered and the view angle dependency is increased.

Therefore, these results show that the organic EL element having excellent element efficiency and view angle dependency can be realized by setting the difference between the maximum value and the minimum value of element reflectance at light having a wavelength of 450 nm to 750 nm to be 30% or less.

Furthermore, in comparison with the samples having similar configurations, the element reflectance difference was greatly changed, with the boundary of the element reflectance difference being set to 30%. For example, although the element reflectance difference of Sample 606 is 27% and the element reflectance difference of Sample 607 is 31%, the view angle dependency of Sample 606 is 15, whereas that of Sample 607 becomes worse up to 26.

Furthermore, although the element reflectance difference of Sample 610 is 30% and the element reflectance difference of Sample 611 is 35%, the view angle dependency of Sample 610 is 12, whereas that of Sample 611 becomes worse up to 27.

Although the element reflectance difference of Sample 613 is 29% and the element reflectance difference of Sample 614 is 31%, the view angle dependency of Sample 613 is 12, whereas that of Sample 614 becomes worse up to 23.

Although the element reflectance difference of Sample 617 is 28% and the element reflectance difference of Sample 618 is 31%, the view angle dependency of Sample 617 is 14, whereas that of Sample 618 becomes worse up to 23.

As described above, it is found that, when the element reflectance difference exceeds 30%, the view angle dependency of the organic EL element becomes drastically worse. Therefore, the organic EL element having excellent view angle dependency can be realized by setting the difference between the maximum value and the minimum value of element reflectance at light having a wavelength of 450 nm to 750 nm to be 30% or less.

Note that the present invention is not limited to the configurations explained in the above embodiments, and other various modifications and changes are possible within the scope not departing from the configurations other than those described above of the present invention.

### REFERENCE SIGNS LIST

10, 20, 20A Organic EL element, 11, 21 Substrate, 12, 22 Nitrogen-containing layer, 13, 23 Transparent electrode, 14 Light emitting unit, 15, 27 Reflective electrode, 24 First light emitting unit, 25 Intermediate layer, 26 Second light emitting unit

1. An organic electroluminescent element comprising a transparent electrode that is mainly composed of silver (Ag), a reflective electrode that is formed of a metal, and at least one light emitting layer that is provided between the transparent electrode and the reflective electrode, wherein
a difference between the maximum value and the minimum value of element reflectance at light having a wavelength of 450 nm to 750 nm is 30% or less.

2. The organic electroluminescent element according to claim 1, wherein a thickness of the transparent electrode is 4 nm or more and 15 nm or less.

3. The organic electroluminescent element according to claim 1, wherein a reflectance of the reflective electrode is 90% or more.

4. The organic electroluminescent element according to claim 1, wherein a total thickness of layers formed between the transparent electrode and the reflective electrode is set so that a difference between the maximum value and the minimum value of element reflectance at light having a wavelength of 450 nm to 750 nm is 30% or less.

5. The organic electroluminescent element according to claim 1, wherein the transparent electrode is configured in contact with a nitrogen-containing layer which is configured by using a compound containing nitrogen atom (N), and an effective unshared electron pair content [n/M] satisfies 2.0×10⁻³≦[n/M], where n is the number of unshared electron pairs that are not involved in aromaticity and that are not coordinated with a metal in the unshared electron pairs of the nitrogen atoms (N) contained in the compound, and M is a molecular weight.

6. The organic electroluminescent element according to claim 1, wherein two or more of the light emitting layers are laminated between the transparent electrode and the reflective electrode.

7. The organic electroluminescent element according to claim 6, wherein two or more of the light emitting layers are laminated via an intermediate layer.

8. The organic electroluminescent element according to claim 1, wherein a light scattering layer is provided on a side in the light emitting direction from the light emitting layer.
